(19) United States
(12) Patent Application Publication
(10) Pub. No.: US 2025/0204249 A1
(43) Pub. Date: Jun. 19, 2025

(54) ORGANIC LIGHT EMITTING DIODE AND ORGANIC LIGHT EMITTING DEVICE

(71) Applicant: LG Display Co., Ltd., Seoul (KR)

(72) Inventors: Gyeong-Woo KIM, Paju-si (KR); Joon-Beom IM, Paju-si (KR); Eun-A YOU, Paju-si (KR); Han-Jin AHN, Paju-si (KR); Jun-Yun KIM, Paju-si (KR)

(21) Appl. No.: 18/979,063

(22) Filed: Dec. 12, 2024

(30) Foreign Application Priority Data
Dec. 15, 2023 (KR) 10-2023-0183106

(51) Int. Cl. H10K 85/60; H10K 50/12; H10K 50/19; H10K 85/30; H10K 85/40; H10K 101/00; H10K 101/10; H10K 101/25; H10K 101/30

(52) U.S. Cl. CPC H10K 85/6572; H10K 50/121; H10K 85/346; H10K 85/40; H10K 85/622; H10K 85/654; H10K 85/656; H10K 85/658; H10K 50/19; H10K 2101/10; H10K 2101/25; H10K 2101/30; H10K 2101/90

(57) ABSTRACT

An organic light emitting diode (OLED) comprises at least one exciton generation layer that can generate exciplex disposed adjacently to an emitting material layer. While emissive zone is extended to the exciton generation layer as well as the emitting material layer, exciton recombination zone is limited to the emitting material layer. The luminous lifespan of the OLED can be improved by preventing materials degradations within the emissive layer. The driving voltage of the OLED can be lowered as holes and electrons can be injected rapidly into the emitting material layer.

### CROSS-REFERENCE TO RELATED APPLICATIONS

This application claims priority under 35 U.S.C. § 119(a) to Republic of Korea Patent Application No. 10-2023-0183106, filed in the Republic of Korea on Dec. 15, 2023, the entire contents of which are hereby expressly incorporated by reference into the present application.

### BACKGROUND

### Technical Field

The present disclosure relates to organic light emitting diodes (OLEDs), and more particularly to, OLEDs with reduced driving voltage and beneficial luminous lifespans as well as organic light emitting devices (e.g., display devices or lighting devices) containing the OLEDs.

### Description of the Related Art

Flat display devices comprising an organic light emitting diode (OLED) have been investigated as display devices that can replace a liquid crystal display device (LCD). The electrode configurations in the OLED can implement unidirectional or bidirectional images. Also, the OLED can be formed even on a flexible transparent substrate such as a plastic substrate so that a flexible or a foldable display device can be realized with ease using the OLED. In addition, the OLED can be driven at a lower voltage and the OLED has advantageous high color purity compared to the LCD.

However, there remains a need to develop OLEDs and devices comprising the OLEDs that have improved luminous efficiency and luminous lifespan. Since fluorescent materials use only singlet excitons in the luminous process, the related art fluorescent material shows low luminous efficiency. Meanwhile, phosphorescent materials can show high luminous efficiency since they use triplet exciton as well as singlet excitons in the luminous process. But such phosphorescent materials comprise metal complexes, which can have a luminous lifespan that is too short for commercial use. As such, there remains a need to develop an OLED with sufficient luminous efficiency and luminous lifespan.

### BRIEF SUMMARY

Accordingly, some embodiments of the present disclosure are directed to organic light emitting diodes and an organic light emitting devices that substantially obviate one or more of the problems due to the limitations and disadvantages of the related art.

An aspect of the present disclosure is to provide an organic light emitting diode and an organic light emitting device (e.g., display device or lighting device) with lowered driving voltage as well as beneficial luminous lifespan.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides an organic light emitting diode that comprises a first electrode; a second electrode facing the first electrode; and an emissive layer disposed between the first electrode and the second electrode, wherein the emissive layer comprises an emitting material layer; and a first exciton generation layer disposed between the first layer and the emitting material layer or between the emitting material layer and the second electrode, wherein the first exciton generation layer comprise a first compound and a second compound, wherein the emitting material layer comprise a first host, a second host and an emitter, wherein each of the first compound and the first host independently comprises an organic compound having the following structure of Chemical Formula 1 or Chemical Formula 3, wherein the second compound comprise an organic compound having the following structure of Chemical Formula 5, and wherein the second host comprise an organic compound having the following structure of Chemical Formula 7:

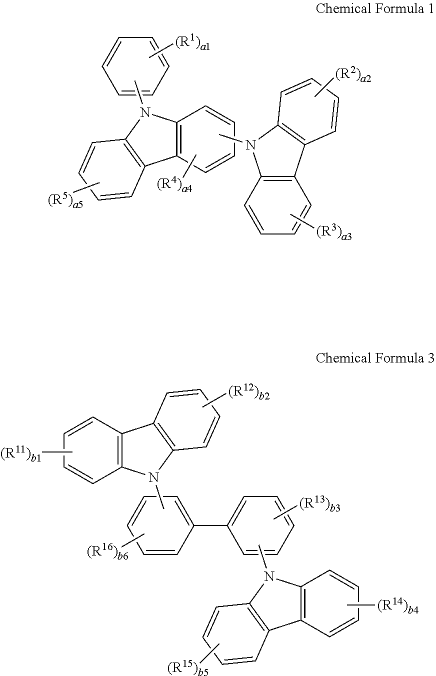

wherein, in Chemical Formulae 1 and 3,
each of R¹ to R⁵ and R¹¹ to R¹⁶ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group or an unsubstituted or substituted C₂-C₃₀ tri-hetero aryl methyl group, where each R¹ is identical to or different from each other when a1 is 2, 3, 4 or 5, each R² is identical to or different from each other when a2 is 2, 3 or 4, each R³ is identical to or different from each other when a3 is 2, 3 or 4, each R⁴ is identical to or different from each other when a4 is 2 or 3, each R⁵ is identical to different from each other when a5 is 2, 3 or 4, each R¹¹ is identical to or different from each other when b1 is 2, 3 or 4, each R¹² is identical to or different from each other when b2 is 2, 3 or 4, each R¹³ is identical to or different from each other when b3 is 2, 3 or 4, each R¹⁴ is identical to or different from each other when b4 is 2, 3 or 4, each R¹⁵ is identical to different from each other when b5 is 2, 3 or 4, and each R¹⁶ is identical to different from each other when b6 is 2, 3 or 4;
a1 is 0, 1, 2, 3, 4 or 5;
each of a2, a3, a5, b1, b2, b3, b4, b5 and b6 is independently 0, 1, 2, 3 or 4; and
a4 is 0, 1, 2 or 3,

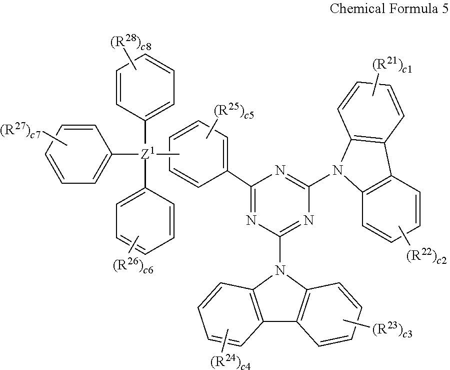

wherein, in Chemical Formula 5,
Z¹ is C, Si or Ge;
each of R²¹ to R²⁸ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, an unsubstituted or substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group or an unsubstituted or substituted C₂-C₃₀ tri-hetero aryl methyl group, where each R²¹ is identical to or different from each other when c1 is 2, 3 or 4, each R²² is identical to or different from each other when c2 is 2, 3 or 4, each R²³ is identical to or different from each other when c3 is 2, 3 or 4, each R²⁴ is identical to or different from each other when c4 is 2, 3 or 4, each R²⁵ is identical to different from each other when c5 is 2, 3 or 4, each R²⁶ is identical to or different from each other when c6 is 2, 3, 4 or 5, each R²⁷ is identical to or different from each other when c7 is 2, 3, 4 or 5, and each R²⁸ is identical to or different from each other when c8 is 2, 3, 4 or 5;
each of c1, c2, c3, c4 and c5 is independently 0, 1, 2, 3 or 4; and
each of c6, c7 and c8 is independently 0, 1, 2, 3, 4 or 5,

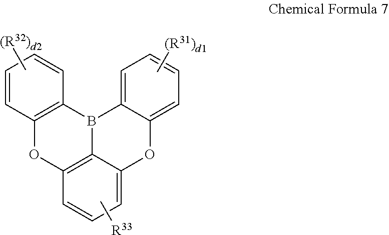

wherein, in Chemical Formula 7,
each of R³¹ to R³³ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, an unsubstituted or substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, an unsubstituted or substituted C₂-C₃₀ tri-hetero aryl methyl group, or has the following structure of Chemical Formula 8, where each R³¹ is identical to or different from each other when d1 is 2, 3 or 4, and each R³² is identical to or different from each other when d2 is 2, 3 or 4, where a polycyclic ring comprising boron and oxygen has at least one hetero aryl group having the following structure of Chemical Formula 9:

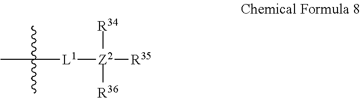

wherein, in Chemical Formula 8,
Z² is C, Si or Ge;
Each of R³⁴ to R³⁶ is independently an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group or an unsubstituted or substituted C₂-C₃₀ hetero aryloxy group;
L¹ is an unsubstituted or substituted C₆-C₃₀ arylene group or an unsubstituted or substituted C₂-C₃₀ hetero arylene group; and
wavy line indicates a link position,

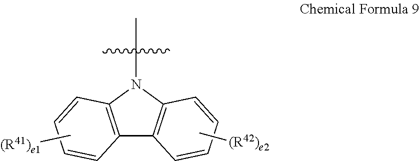

wherein, in Chemical Formula 9,
each of R⁴¹ and R⁴² is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, or an unsubstituted or substituted C₂-C₃₀ tri-hetero aryl methyl group, where each R⁴¹ is identical to or different from each other when e1 is 2, 3 or 4, and each R⁴² is identical to or different from each other when e2 is 2, 3 or 4, or
optionally,
two adjacent R⁴¹ and/or two adjacent R⁴² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring; and
wavy line indicates a link position.

In another embodiment, the emissive layer can further comprise a second exciton generation layer disposed oppositely to the first exciton generation layer with respect to the emitting material layer.

As an example, the second exciton generation layer can comprise a third compound and a fourth compound, the third compound can comprise the organic compound having the structure of Chemical Formula 1 or Chemical Formula 3, and the fourth compound can comprise the organic compound having the structure of Chemical Formula 5.

In one embodiment, a difference or an energy bandgap between a highest occupied molecular orbital (HOMO) energy level of the first compound and a HOMO energy level of the second compound can be about 0.2 eV or more and about 0.8 eV or less.

In another embodiment, a difference or an energy bandgap between a highest occupied molecular orbital (HOMO) energy level of the first compound, and a higher HOMO energy level among a HOMO energy level of the first host and a HOMO energy level of the second host can be about 0.3 eV or less.

In another embodiment, a difference or an energy bandgap between a lowest unoccupied molecular orbital (LUMO) energy level of the first compound and a LUMO energy level of the second compound can be about 0.2 eV or more and about 0.8 eV or less.

In another embodiment, a difference or an energy bandgap between a lowest unoccupied molecular orbital (LUMO) energy level of the second compound, and a higher LUMO energy level among a LUMO energy level of the first host and a LUMO energy level of the second host can be about 0.3 eV or less.

In another embodiment, a lowest excited state triplet energy level of the first compound can be higher than a lowest excited state triplet energy level of the second compound, and the lowest excited state triplet energy level of the second compound can be higher than a lowest excited state triplet energy level of the second host.

For example, the emitter can comprise an organometallic compound having the following structure of Chemical Formula 11:

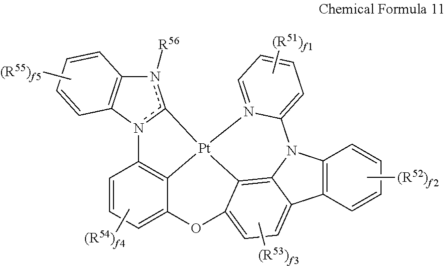

wherein, in Chemical Formula 11,
each of R⁵¹ and R⁵⁶ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, or an unsubstituted or substituted C₂-C₃₀ tri-hetero aryl methyl group, where each R⁵¹ is identical to or different from each other when f1 is 2, 3 or 4, and each R⁵² is identical to or different from each other when f2 is 2, 3 or 4, each R⁵³ is identical to or different from each other when f3 is 2, each R⁵⁴ is identical to or different from each other when f4 is 2 or 3, and each R⁵⁵ is identical to or different from each other when f5 is 2, 3 or 4;
each of f1, f2 and f5 is independently 0, 1, 2, 3 or 4;
f3 is 0, 1 or 2; and
f4 is 0, 1, 2 or 3.

In one embodiment, the first compound and the second compound in the first exciton generation layer can be mixed with a weight ratio between about 4:1 and about 1:4.

The emissive layer can comprise a single emitting part or multiple emitting parts to form a tandem structure.

For example, the emissive layer can comprises a first emitting part disposed between the first electrode and the second electrode, and comprising a first emitting material layer; a second emitting part disposed between the first emitting part and the second electrode, and comprising a second emitting material layer; and a first charge generation layer disposed between the first emitting part and the second emitting part, and at least one of the first emitting material layer and the second emitting material layer can comprises the first host, the second host and the emitter.

As an example, the first emitting material layer can comprise the first host, the second host and the emitter, and the first exciton generation layer can be disposed between the first electrode and the first emitting material layer or between the first emitting material layer and the first charge generation layer.

The first emitting part can further comprise a second exciton generation layer disposed oppositely to the first exciton generation layer with respect to the first emitting material layer.

In another embodiment, the emissive layer can further comprise a third emitting part disposed between the second emitting part and the second electrode, and comprising a third emitting material layer; and a second charge generation layer disposed between the second emitting part and the third emitting part.

In yet another aspect, the present disclosure provides an organic light emitting device, for example, an organic light emitting display device or an organic light emitting illumination device, comprises a substrate and the organic light emitting diode over the substrate.

In one or more embodiment, an organic light emitting diode (OLED) and an organic light emitting device comprise at least one exciton generation layer disposed adjacently to an emitting material layer and comprising a first compound and a second compound that can generate exciplex.

Exciton recombination zone or area in the OLED can be extended to the exciton generating layer adjacently to the emitting material layer. The concentration or level of excitons in the emitting material layer is reduced as the exciton recombination zone is extended. The degradation of luminous materials, charge transporting materials and charge blocking materials caused by non-emissive quenching excitons can be prevented. As the reduction of luminous lifespan owing to the material degradation is suppressed, the luminous lifespan of the OLED can be improved.

Emission zone or area is limited to the emitting material layer with beneficial out-coupling efficiency. The external quantum efficiency of the OLED can be improved as the out-coupling efficiency increases. In addition, material cost can be reduced as amount of emitter can be reduced.

The emitting material layer comprises a host with delayed fluorescent property. As the host with delayed fluorescent property has a very small difference between an excited state singlet energy level and an excited state triplet energy level, energy for exciton recombination in the host can be reduced. In addition, energy for exciton recombination in the exciton generation layer can be reduced as exciplex with delayed fluorescent property can be generated in the exciton generation layer. As a difference or energy bandgap in the exciplex and the host with delayed fluorescent property can be lowered, voltage for injecting charges into the emitting material layer can be reduced.

The OLED with lowered driving voltage and beneficial luminous lifespan can be implemented by applying the emitting material layer comprising the host with delayed fluorescent property and at least one exciton generation layer that can generate exciplex disposed adjacently to the emitting material layer. It is possible to fabricate an environmentally friendly OLED and an organic light emitting device with lowered poser consumption and that can implement ESG (environmental, social and Governance) idea.

It is to be understood that both the foregoing general description and the following detailed description are exemplary and explanatory, and are intended to provide further explanation of the inventive concepts as claimed.

### BRIEF DESCRIPTION OF THE SEVERAL VIEWS OF THE DRAWINGS

The accompanying drawings, which are comprised to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with one or more embodiments of the present disclosure.

FIG. 2 illustrates a cross-sectional view of an organic light emitting display device as an example of an organic light emitting device in accordance with an embodiment of the present disclosure.

FIG. 3 illustrates a cross-sectional view of an organic light emitting diode having a single emitting part in accordance with an embodiment of the present disclosure.

FIG. 4 illustrates a cross-sectional view of an organic light emitting diode having a single emitting part in accordance with another embodiment of the present disclosure.

FIG. 5 illustrates a cross-sectional view of an organic light emitting diode having a single emitting part in accordance with another embodiment of the present disclosure.

FIG. 6 is a schematic diagram of luminous mechanism in case an exciton generation layer is formed adjacently to an emitting material layer in accordance with an embodiment of the present disclosure.

FIG. 7 is a schematic diagram of HOMO energy levels and LUMO energy levels of a first compound and a second compound in an exciton generation layer as well as a first host and a second host in an emitting material layer.

FIG. 8 is a schematic diagram of charge injection into an emitting material layer in case an exciton generation layer generates exciplex in accordance with an embodiment of the present disclosure.

FIG. 9 is a schematic diagram of non-efficient charge injection into an emitting material layer owing to barrier voltage incase an organic layer disposed adjacently to an emitting material layer cannot generate exciplex.

FIG. 10 is a schematic diagram of emission zone and recombination zone in case exciton generation layer is not formed adjacently to an emitting material layer.

FIG. 11 is a schematic diagram of emission zone and recombination zone in case exciton generation layer is formed adjacently to an emitting material layer in accordance with one embodiment of the present disclosure.

FIG. 12 illustrates a cross-sectional view of an organic light emitting display device in accordance with another embodiment of the present disclosure.

FIG. 13 illustrates a cross-sectional view of an organic light emitting diode having a tandem structure of two emitting parts in accordance with another embodiment of the present disclosure.

FIG. 14 illustrates a cross-sectional view of an organic light emitting diode having a tandem structure of three emitting parts in accordance with another embodiment of the present disclosure.

Each of FIGS. 15 to 17 is a graph illustrating Absorbance spectra and photoluminescence spectra for materials used in Examples and Comparative Examples. “Abs” indicates Absorbance spectra and “PL” indicates photoluminescence spectra.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts.

All the components of each organic light emitting display device according to all embodiments of the present disclosure are operatively coupled and configured.

The emissive layer of an organic light emitting diode includes at least one exciton generation layer with materials that can generate exciplex disposed adjacently an emitting material layer with a host with delayed fluorescent property. The driving voltage of the organic light emitting diode can be lowered and the luminous lifespan of the organic light emitting diode can be improved by applying the emissive layer comprising the emitting material layer and the exciton generation layer. As an example, the emissive layer comprising the emitting material layer and the exciton generation layer can be applied to an organic light emitting diode with a single emitting part in a red pixel region, a green pixel region and/or a blue pixel region. Alternatively, the emissive layer comprising the emitting material layer and the exciton generation layer can be applied to an organic light emitting diode of having a tandem structure where at least two emitting parts are stacked.

As an example, in one or more embodiments of the present disclosure, the organic light emitting diode can be applied to an organic light emitting device such as an organic light emitting display device or an organic light emitting illumination device. As an example, an organic light emitting display device will be described.

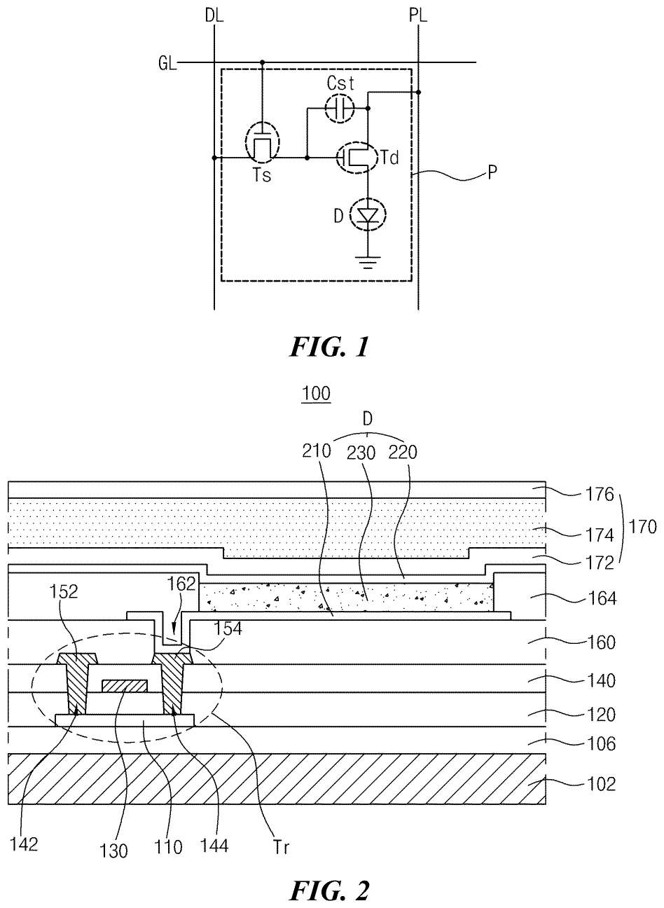

FIG. 1 illustrates a schematic circuit diagram of an organic light emitting display device in accordance with one or more embodiments of the present disclosure. As illustrated in FIG. 1, a gate line GL, a data line DL and power line PL, each of which crosses each other to define a pixel region P, are provided in an organic light emitting display device 100. A switching thin film transistor Ts, a driving thin film transistor Td, a storage capacitor Cst and an organic light emitting diode D are disposed within the pixel region P. The pixel region P can comprise a first pixel region, a second pixel region and a third pixel region. However, embodiments of the present disclosure are not limited to such examples. The organic light emitting display device 100 can comprise a plurality of such pixel regions P which can be arranged in a matrix configuration or other configurations.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

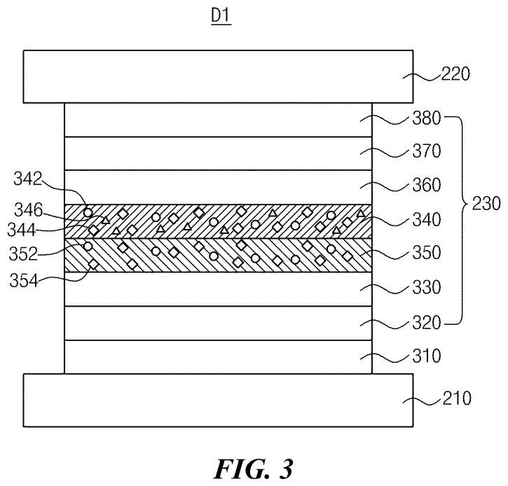

The driving thin film transistor Td is turned on by the data signal applied to a gate electrode 130 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an embodiment of the present disclosure. The pixel circuit configuration of FIG. 1 can be used in the display device of FIG. 2 or other figures of the present application.

As illustrated in FIG. 2, the organic light emitting display device 100 comprises a substrate 102, a thin-film transistor Tr on the substrate 102, and an organic light emitting diode D connected to the thin film transistor Tr.

As an example, the substrate 102 can comprise a red pixel region, a green pixel region and a blue pixel region and an organic light emitting diode D can be located in each pixel region. Each of the organic light emitting diodes D emitting red, green and blue light, respectively, is located correspondingly in the red pixel region, the green pixel region and the blue pixel region.

The substrate 102 can comprise, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 can be disposed on the substrate 102. The thin film transistor Tr can be disposed on the buffer layer 106. In certain embodiments, the buffer layer 106 can be omitted.

A semiconductor layer 110 is disposed on the buffer layer 106. In one embodiment, the semiconductor layer 110 can comprise, but is not limited to, oxide semiconductor materials. In this case, a light-shield pattern can be disposed under the semiconductor layer 110, and the light-shield pattern can prevent light from being incident toward the semiconductor layer 110, thereby, preventing or reducing the semiconductor layer 110 from being degraded by the light. Alternatively, the semiconductor layer 110 can comprise polycrystalline silicon. In this case, opposite edges of the semiconductor layer 110 can be doped with impurities.

A gate insulating layer 120 comprising an insulating material is disposed on the semiconductor layer 110. The gate insulating layer 120 can comprise, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the substrate 102 as shown in FIG. 2, the gate insulating layer 120 can be patterned identically as the gate electrode 130.

An interlayer insulating layer 140 comprising an insulating material is disposed on the gate electrode 130 and covers an entire surface of the substrate 102. The interlayer insulating layer 140 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has first and second semiconductor layer contact holes 142 and 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 and the interlayer insulating layer 140 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can comprise amorphous silicon.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr can further comprise a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the entire substrate 102. The passivation layer 160 has a flat top surface and a drain contact hole (or a contact hole) 162 that exposes or does not cover the drain electrode 154 of the thin film transistor Tr. While the drain contact hole 162 is disposed on the second semiconductor layer contact hole 144, it can be spaced apart from the second semiconductor layer contact hole 144.

The organic light emitting diode D (OLED D) comprises a first electrode 210 that is disposed on the passivation layer 160 and connected to the drain electrode 154 of the thin film transistor Tr. The OLED D further comprises an emissive layer 230 and a second electrode 220 each of which is disposed sequentially on the first electrode 210.

One of the first electrode 210 and the second electrode 220 can be an anode, and the other of the first electrode 210 and the second electrode 220 can be a cathode. One of the first electrode 210 and the second electrode 220 can be a reflective electrode, and the other of the first electrode 210 and the second electrode 220 can be a transmissive electrode.

The first electrode 210 is disposed separately in each pixel region P. In one embodiment, the first electrode 210 can be an anode and comprise conductive material having relatively high work function value. For example, the first electrode 210 can comprise a transparent conductive oxide (TCO).

In one embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer can be disposed under the first electrode 210. For example, the reflective electrode or the reflective layer can comprise, but is not limited to, silver (Ag) or aluminum-palladium-copper (APC) alloy. As an example, in the OLED D of the top-emission type, the first electrode 210 can have, but is not limited to, a triple-layered structure of ITO/Ag/ITO or ITO/APC/ITO.

In addition, a bank layer 164 is disposed on the passivation layer 160 in order to cover edges of the first electrode 210. The bank layer 164 exposes or does not cover a center of the first electrode 210 corresponding to each pixel region. In certain embodiments, the bank layer 164 can be omitted.

An emissive layer 230 is disposed on the first electrode 210. In one embodiment, the emissive layer 230 can include an emitting material layer (EML) and at least one exciton generation layer (EGL). Alternatively, the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL), an EGL and/or a charge generation layer (CGL).

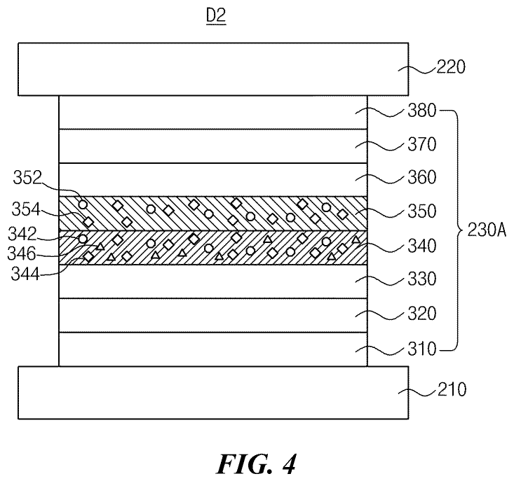

In one embodiment, the emissive layer 230 can have a single emitting part (FIGS. 3 to 5). Alternatively, the emissive layer 230 can have multiple emitting parts to form a tandem structure. For example, the emissive layer 230 can be applied to an OLED with a single emitting part located each of the red pixel region, the green pixel region and the blue pixel region. Alternatively, the emissive layer 230 can be applied to a tandem-type OLED where at least two emitting parts are stacked.

The emissive layer 230 can comprise an EML with a delayed fluorescent property host and at least one EGL that can generate exciplex disposed adjacently to the EML so that the driving voltage of the OLED can be lowered and the luminous lifespan of the OLED D can be improved.

The second electrode 220 is disposed on the substrate 102 above which the emissive layer 230 is disposed. The second electrode 220 can be disposed on the entire display area. The second electrode 220 can comprise a conductive material with a relatively low work function value compared to the first electrode 210. The second electrode 230 can be a cathode providing electrons. When the organic light emitting display device 100 is a top-emission type, the second electrode 220 is thin so as to have light-transmissive (semi-transmissive) property.

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film 172, an organic insulating film 174 and a second inorganic insulating film 176. In certain embodiments, the encapsulation film 170 can be omitted.

A polarizing plate can be attached onto the encapsulation film 170 to reduce reflection of external light. For example, the polarizing plate can be a circular polarizing plate. When the organic light emitting display device 100 is a bottom-emission type, the polarizing plate can be disposed under the substrate 102. Alternatively, when the organic light emitting display device 100 is a top-emission type, the polarizing plate can be disposed on the encapsulation film 170. In addition, a cover window can be attached to the encapsulation film 170 or the polarizing plate. In this case, the substrate 102 and the cover window can have a flexible property, thus the organic light emitting display device 100 can be a flexible display device.

The OLED D is described in more detail. FIG. 3 illustrates a schematic cross-sectional view of an organic light emitting diode having a single emitting part in accordance with an embodiment of the present disclosure. For instance, FIG. 3 shows an example (OLED D1) of the OLED D in FIGS. 1 and 2.

As illustrated in FIG. 3, the OLED D1 in accordance with an example of the present disclosure comprises first and second electrodes 210 and 220 facing each other and an emissive layer 230 disposed between the first and second electrodes 210 and 220. The organic light emitting display device 100 comprises a red pixel region, a green pixel region and a blue pixel region, and the OLED D1 can be disposed in the red pixel region, the green pixel region and/or the blue pixel region. As an example, the OLED D1 can be disposed in the blue pixel region.

In one embodiment, the emissive layer 230 comprises an emitting material layer (EML) 340 disposed between the first and second electrodes 210 and 220, and an exciton generation layer (EGL) disposed between the first electrode 210 and the EML 340, for example, between a hole transport layer 320 or an electron blocking layer 330 and the EML. The emissive layer 230 can comprise at least one of a hole transport layer (HTL) 320 disposed between the first electrode 210 and the EML 340 and an electron transport layer (ETL) 370 disposed between the second electrode 230 and the EML 340. In certain embodiments, the emissive layer 230 can further comprise at least one of a hole injection layer (HIL) 310 disposed between the first electrode 210 and the HTL 320 and an electron injection layer (EIL) 380 disposed between the second electrode 230 and the ETL 370. Alternatively or additionally, the emissive layer 230 can further comprise a first exciton blocking layer, i.e., an electron blocking layer (EBL) 330 disposed between the HTL 320 and the EML 340, for example, the HTL 320 and the EGL 350 and/or a second exciton blocking layer, i.e., a hole blocking layer (HBL) 360 disposed between the EML 340 and the ETL 370.

The first electrode 210 can be an anode that provides holes into the EML 340. The first electrode 210 can comprise a conductive material having a relatively high work function value, for example, a transparent conductive oxide (TCO). As an example, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or the like.

The second electrode 220 can be a cathode that provides electrons into the EML 340. The second electrode 220 can comprise a conductive material having a relatively low work function values, i.e., a highly reflective material. As an example, the second electrode 220 can comprise, but is not limited to, aluminum (Al), magnesium (Mg), calcium (Ca), silver (Ag), alloy thereof and/or combinations thereof such as aluminum-magnesium alloy (Al—Mg).

The EGL 350 comprises a first compound 352 and a second compound 354 that are recombined to generate excitons. The first compound 352 can be a P-type (or hole-type) compound with relatively beneficial hole affinity property and/or hole transporting property. The second compound 354 can be an N-type (or electron-type) compound with relatively beneficial electron affinity property and/or electron transporting property.

The first compound 352 can be a carbazole-containing organic compound. The first compound 352 comprise an organic compound having the following structure of Chemical Formula 1 or Chemical Formula 3:

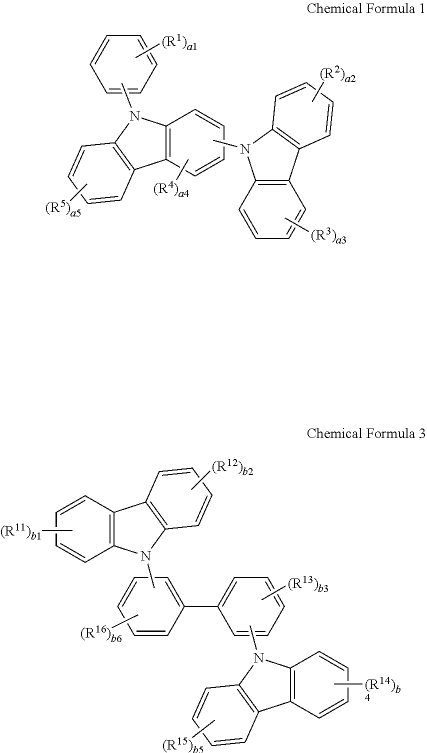

wherein, in Chemical Formulae 1 and 3,
each of R¹ to R⁵ and R¹¹ to R¹⁶ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, an unsubstituted or substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group or an unsubstituted or substituted C₂-C₃₀ tri-hetero aryl methyl group, where each R¹ is identical to or different from each other when a1 is 2, 3, 4 or 5, each R² is identical to or different from each other when a2 is 2, 3 or 4, each R³ is identical to or different from each other when a3 is 2, 3 or 4, each R⁴ is identical to or different from each other when a4 is 2 or 3, each R⁵ is identical to different from each other when a5 is 2, 3 or 4, each R¹¹ is identical to or different from each other when b1 is 2, 3 or 4, each R¹² is identical to or different from each other when b2 is 2, 3 or 4, each R¹³ is identical to or different from each other when b3 is 2, 3 or 4, each R¹⁴ is identical to or different from each other when b4 is 2, 3 or 4, each R¹⁵ is identical to different from each other when b5 is 2, 3 or 4, and each R¹⁶ is identical to different from each other when b6 is 2, 3 or 4;
a1 is 0, 1, 2, 3, 4 or 5;
each of a2, a3, a5, b1, b2, b3, b4, b5 and b6 is independently 0, 1, 2, 3 or 4; and
a4 is 0, 1, 2 or 3.

As used herein, the term “unsubstituted” means that hydrogen is directly linked to a carbon atom. “Hydrogen,” as used herein, can refer to protium and/or deuterium.

As used herein, “substituted” means that the hydrogen is replaced with a substituent. The substituent can comprise, but is not limited to, an unsubstituted or substituted C₁-C₂₀ alkyl group, an unsubstituted or substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, an unsubstituted or substituted C₁-C₁₀ alkyl silyl group, an unsubstituted or substituted C₁-C₁₀ alkoxy silyl group, an unsubstituted or substituted C₃-C₂₀ cyclo alkyl silyl group, an unsubstituted or substituted C₆-C₃₀ aryl silyl group, an unsubstituted or substituted C₃-C₃₀ hetero aryl silyl group, an unsubstituted or substituted C₆-C₃₀ aryl group, an unsubstituted or substituted C₃-C₃₀ hetero aryl group, or any combination of these groups.

As used herein, the term “hetero” in terms such as “a hetero alicyclic ring,” “a hetero cycloalkyl group,” “a hetero aryl group,” “a hetero aralkyl group,” “a hetero aryloxy group,” “a hetero aryl amino group,” “a hetero aryl silyl group,” “a hetero aryl germanyl group,” “a hetero arylene group,” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

For example, the substituent of the C₆-C₃₀ aryl group, the C₃-C₃₀ hetero aryl group, the C₆-C₃₀ aryl amino group, the C₃-C₃₀ hetero aryl amino group, the C₆-C₃₀ aromatic ring and the C₃-C₃₀ heteroaromatic ring can comprise at least one of a C₁-C₂₀ alkyl group, a C₆-C₃₀ aryl group, a C₃-C₃₀ hetero aryl group, a C₆-C₃₀ aryl amino group and a C₃-C₃₀ hetero aryl amino group.

As used herein, the C₆-C₃₀ aryl group can comprise, but is not limited to, an unfused or fused aryl group such as phenyl, biphenylyl, terphenylyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

As used herein, the C₂-C₃₀ hetero aryl group can comprise, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As used herein, the C₆-C₃₀ arylene group can comprise, but is not limited to, any bivalent linking group corresponding to the above aryl group, and the C₂-C₃₀ hetero arylene group can comprise, but is not limited to, any bivalent linking group corresponding to the hetero above aryl group.

For example, the C₆-C₃₀ arylene group can comprise, but is not limited to, phenylene, biphenylene, terphenylene, tetraphenylene, indenylene, naphthylene, azulenylene, indacenylene, acenaphthylene, fluorenylene, spiro-fluorenylene, phenalenylene, phenanthrenylene, anthracenylene, fluoranthrenylene, triphenylenylene, pyrenylene, chrysenylene, naphthacenylene, picenylene, perylenylene, pentaphenylene and/or hexacenylene.

In another embodiment, the C₂-C₃₀ hetero arylene can comprise, but is not limited to, pyrrolylene, imidazolylene, pyrazolylene, pyridinylene, pyrazinylene, pyrimidinylene, pyridazinylene, isoindolylene, indolylene, indazolylene, purinylene, quinolinylene, isoquinolinylene, benzoquinolinylene, phthalazinylene, naphthyridinylene, quinoxalinylene, quinazolinylene, benzoisoquinolinylene, benzoquinazolinylene, benzoquinoxalinylene, cinnolinylene, phenanthridinylene, acridinylene, phenanthrolinylene, phenazinylene, benzoxazolylene, benzimidazolylene, furanylene, benzofuranylene, thiophenylene, benzothiophenylene, thiazolylene, isothiazolylene, benzothiazolylene, isoxazolylene, oxazolylene, triazolylene, tetrazolylene, oxadiazolylene, triazinylene, dibenzofuranylene, dibenzothiophenylene, carbazolylene, benzocarbazolylene, dibenzocarbazolylene, indolocarbazolylene, indenocarbazolylene, imidazopyrimidinylene and/or imidazopyridinylene.

As an example, each of the aryl group or aromatic group, the hetero aryl group or hetero aromatic group, the aralkyl group, the hetero aralkyl group, the aryloxy group, the hetero aryloxy group, the aryl amino group and/or the hetero aryl amino group in Chemical Formulae 1 and 4 can consist of one to three aromatic and/or hetero aromatic rings. When the number of the aromatic and/or hetero aromatic rings becomes large, conjugated structure within the whole molecule becomes too long, thus, the organic compound can have too narrow energy bandgap between highest occupied molecular orbital (HOMO) energy level and lowest unoccupied molecular orbital (LUMO) energy level.

For example, each of the aryl group or the hetero aryl group can comprise independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

In one embodiment, at least one of R¹ to R⁵ in Chemical Formula 1 can be phenyl, carbazolyl, tri-aryl methyl (e.g., tri-phenyl methyl), tri-aryl silyl (e.g., tri-phenyl silyl) and/or tri-aryl germanyl (e.g., tri-phenyl germanyl), each of which can be independently unsubstituted or substituted. As an example, the first compound 352 having the structure of Chemical Formula 1 can be at least one of or selected from, but is not limited to, the following organic compounds of Chemical Formula 2:

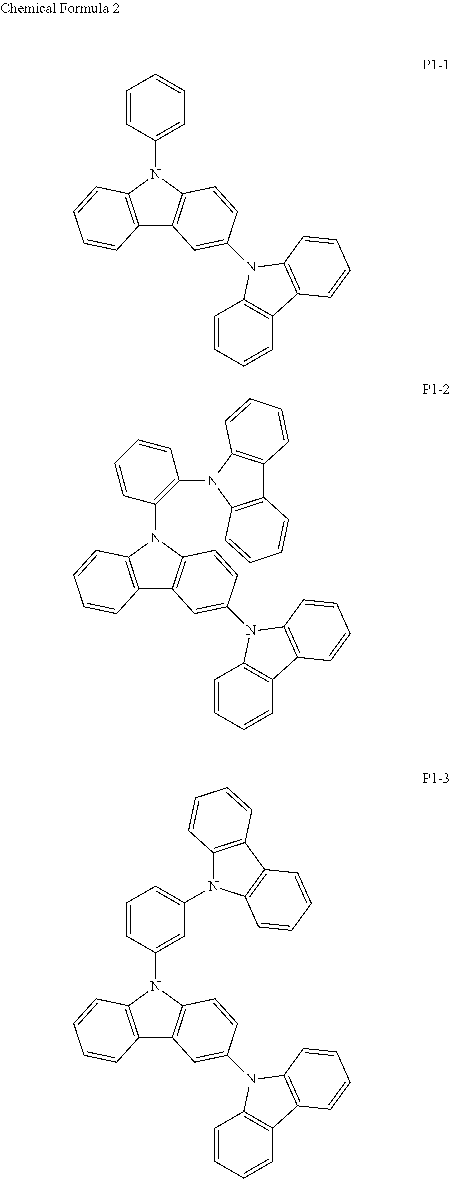

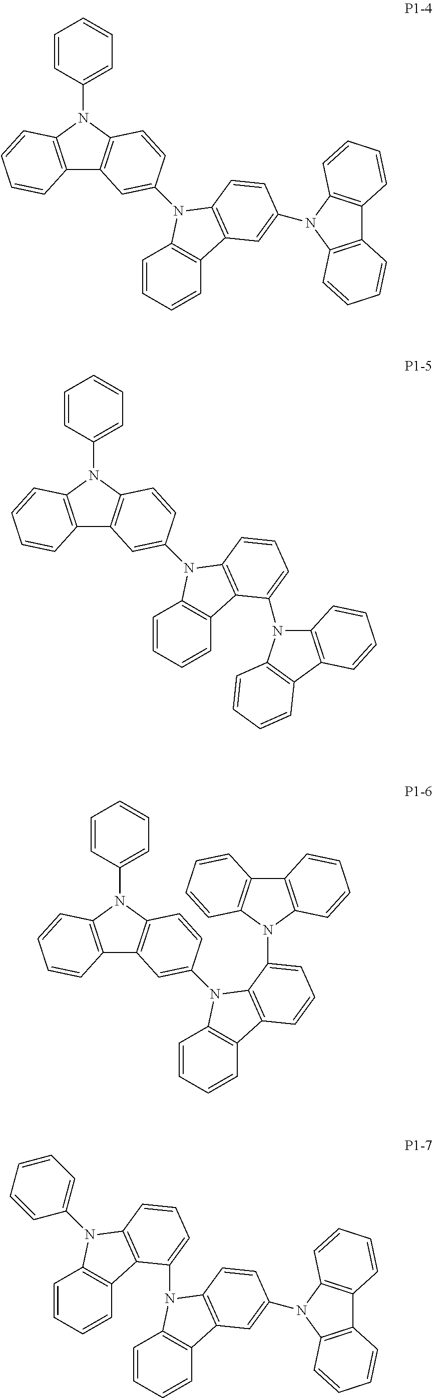 [SMILES: c1ccc(-n2c3ccccc3c3cc(-n4c5ccccc5c5cc(-n6c7ccccc7c7ccccc76)ccc54)ccc32)cc1 ; c1ccc(-n2c3ccccc3c3cc(-n4c5ccccc5c5c(-n6c7ccccc7c7ccccc76)cccc54)ccc32)cc1 ; c1ccc(-n2c3ccccc3c3cc(-n4c5ccccc5c5cccc(-n6c7ccccc7c7ccccc76)c54)ccc32)cc1 ; c1ccc(-n2c3ccccc3c3c(-n4c5ccccc5c5cc(-n6c7ccccc7c7ccccc76)ccc54)cccc32)cc1]

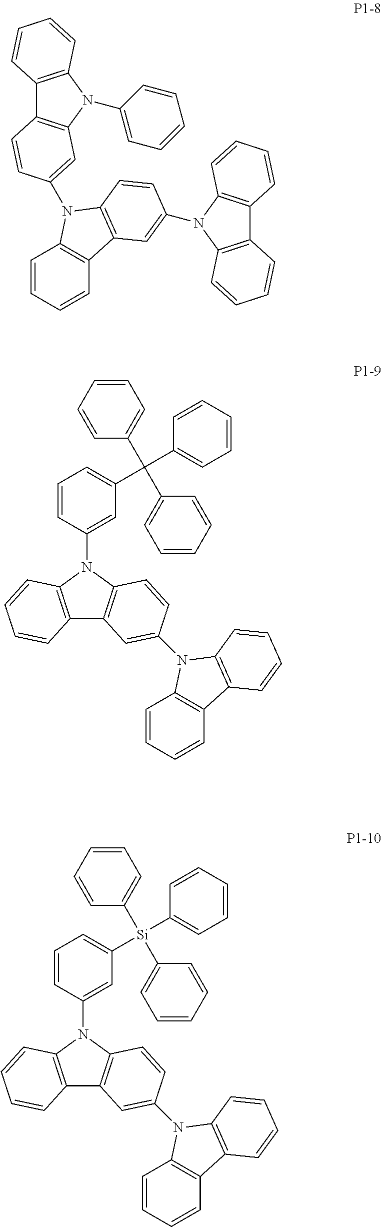 [SMILES: c1ccc(-n2c3ccccc3c3ccc(-n4c5ccccc5c5cc(-n6c7ccccc7c7ccccc76)ccc54)cc32)cc1 ; c1ccc(C(c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-n3c4ccccc4c4cc(-n5c6ccccc6c6ccccc65)ccc43)c2)cc1]

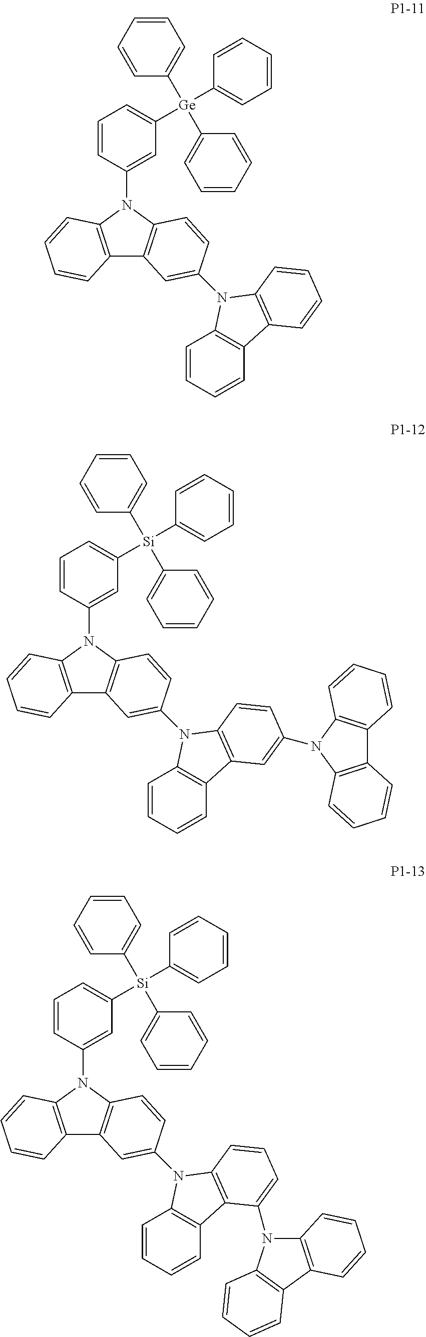

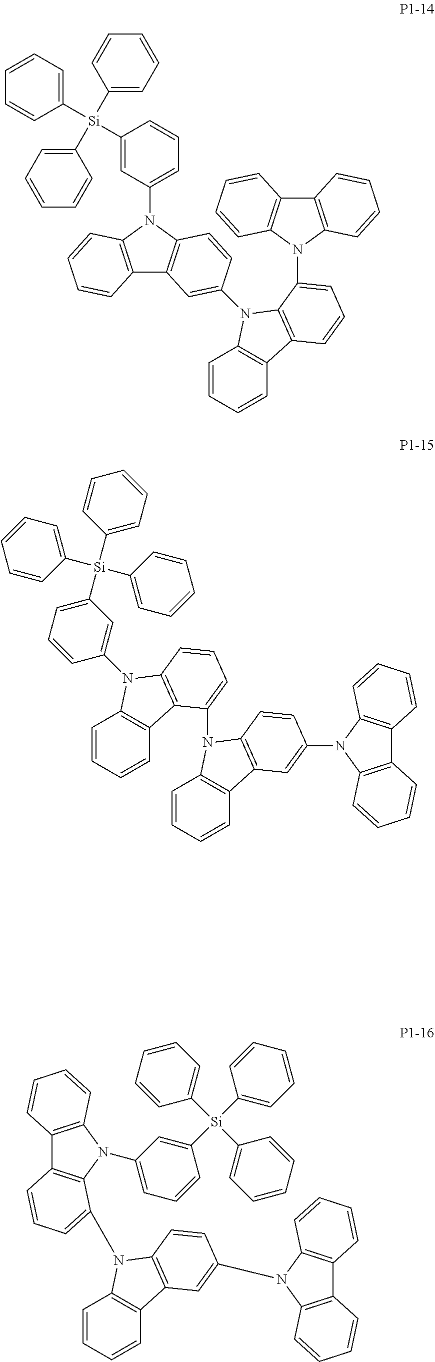 [SMILES: c1ccc([Si](c2ccccc2)(c2ccccc2)c2cccc(-n3c4ccccc4c4cc(-n5c6ccccc6c6cccc(-n7c8ccccc8c8ccccc87)c65)ccc43)c2)cc1 ; c1ccc([Si](c2ccccc2)(c2ccccc2)c2cccc(-n3c4ccccc4c4c(-n5c6ccccc6c6cc(-n7c8ccccc8c8ccccc87)ccc65)cccc43)c2)cc1 ; c1ccc([Si](c2ccccc2)(c2ccccc2)c2cccc(-n3c4ccccc4c4cccc(-n5c6ccccc6c6cc(-n7c8ccccc8c8ccccc87)ccc65)c43)c2)cc1]

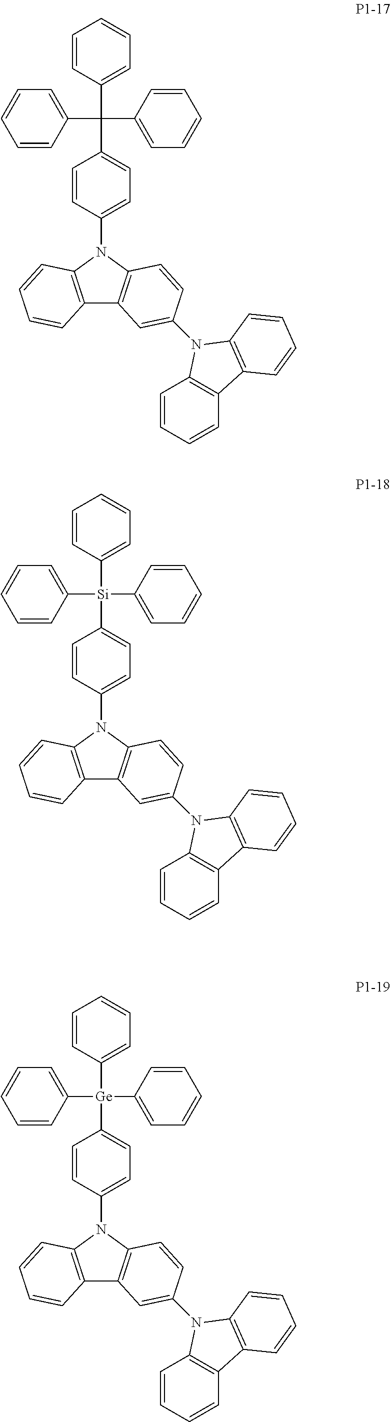

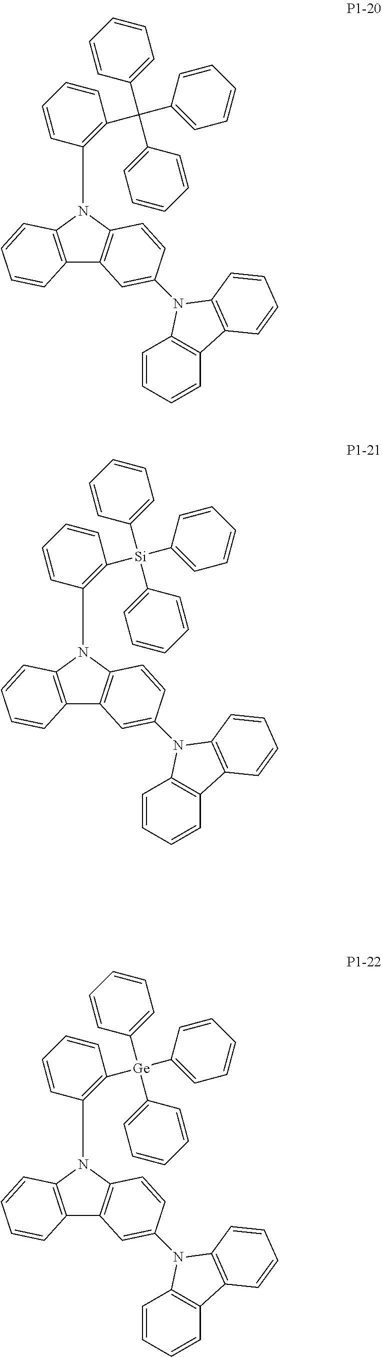

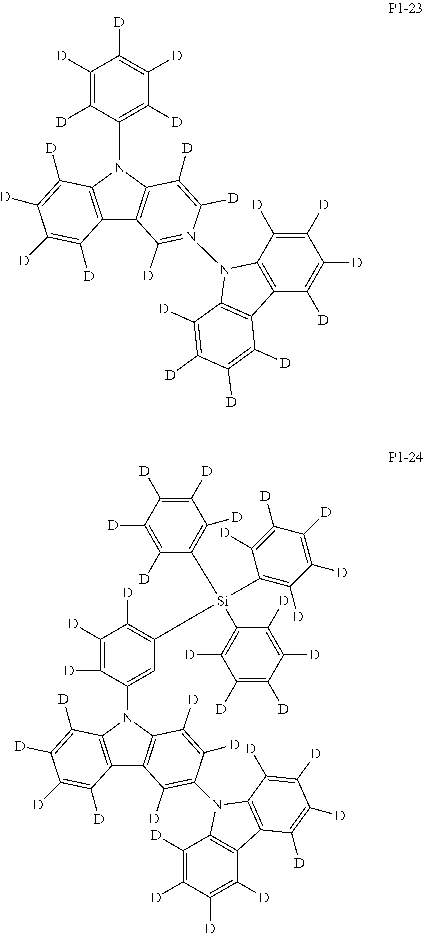

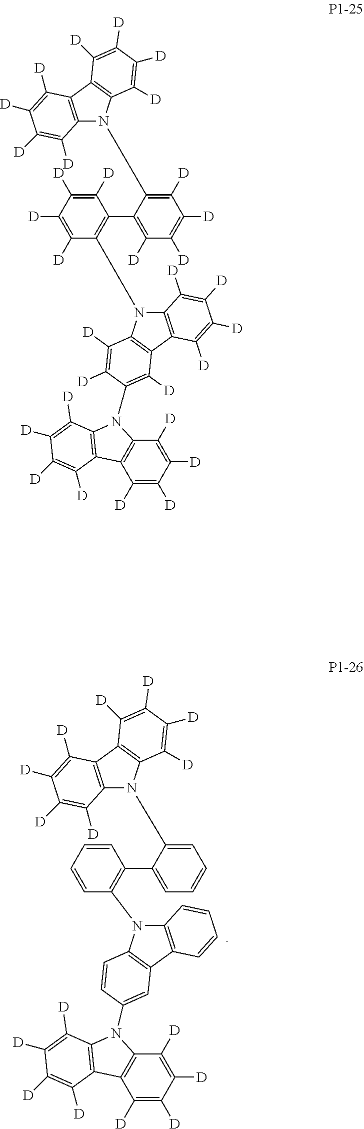 [SMILES: [2H]c1c([2H])c([2H])c(-n2c3c([2H])c([2H])c([2H])c([2H])c3c3c([2H])c([2H])c([2H])c([2H])c32)c(-c2c([2H])c([2H])c([2H])c([2H])c2-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c1[2H] ; [2H]c1c([2H])c([2H])c2c(c1[2H])c1c([2H])c([2H])c([2H])c([2H])c1n2-c1ccc2c(c1)c1ccccc1n2-c1ccccc1-c1ccccc1-n1c2c([2H])c([2H])c([2H])c([2H])c2c2c([2H])c([2H])c([2H])c([2H])c21]

In another embodiment, at least one of R¹¹ to R¹⁶ in Chemical Formula 3 can comprise unsubstituted or substituted carbazolyl. As an example, the first compound 352 having the structure of Chemical Formula 3 can be at least one of or selected from, but is not limited to, the following organic compounds of Chemical Formula 4:

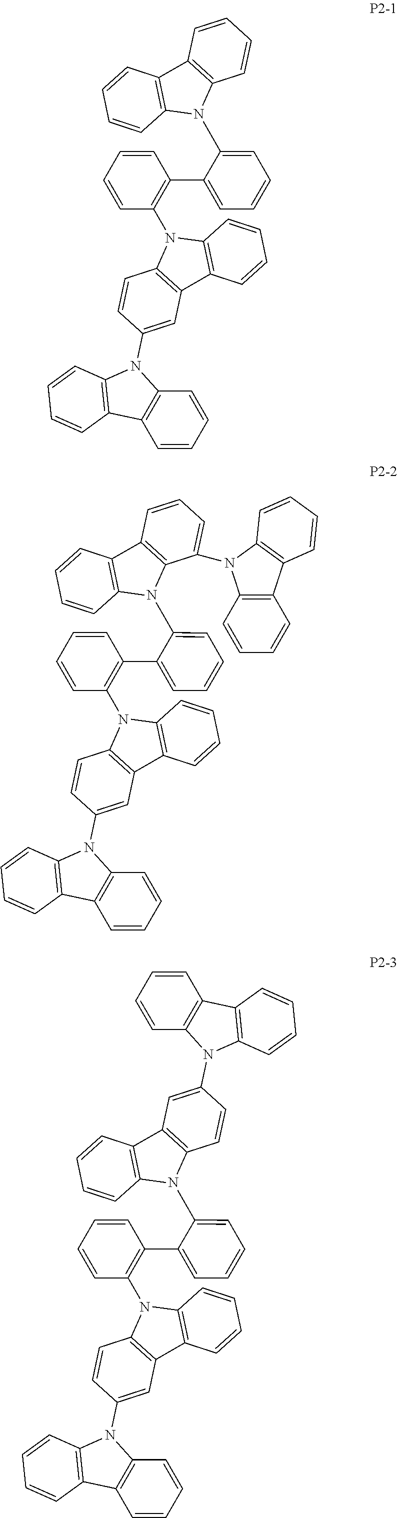

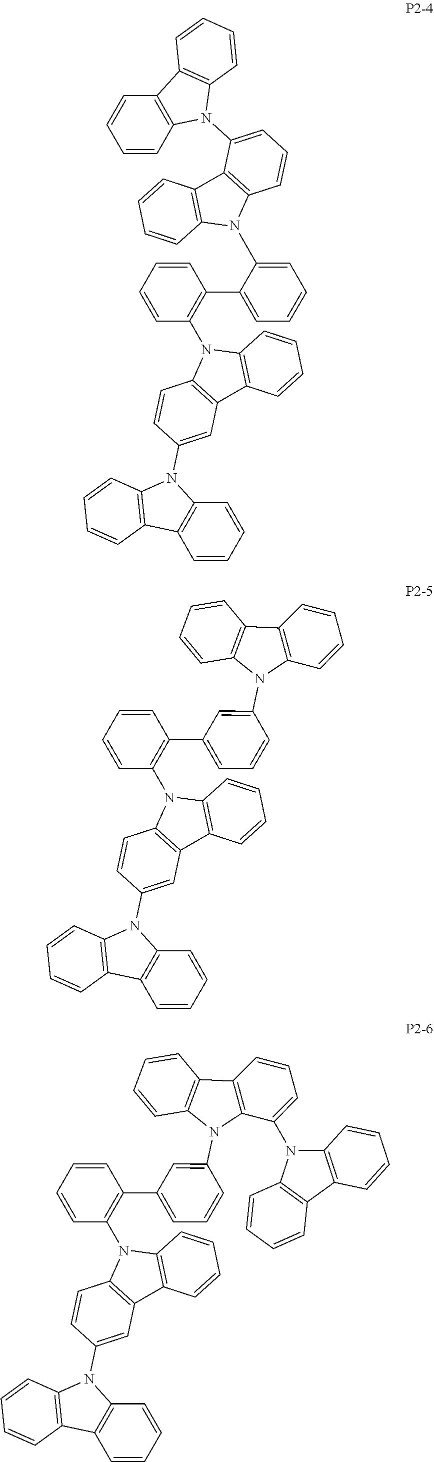

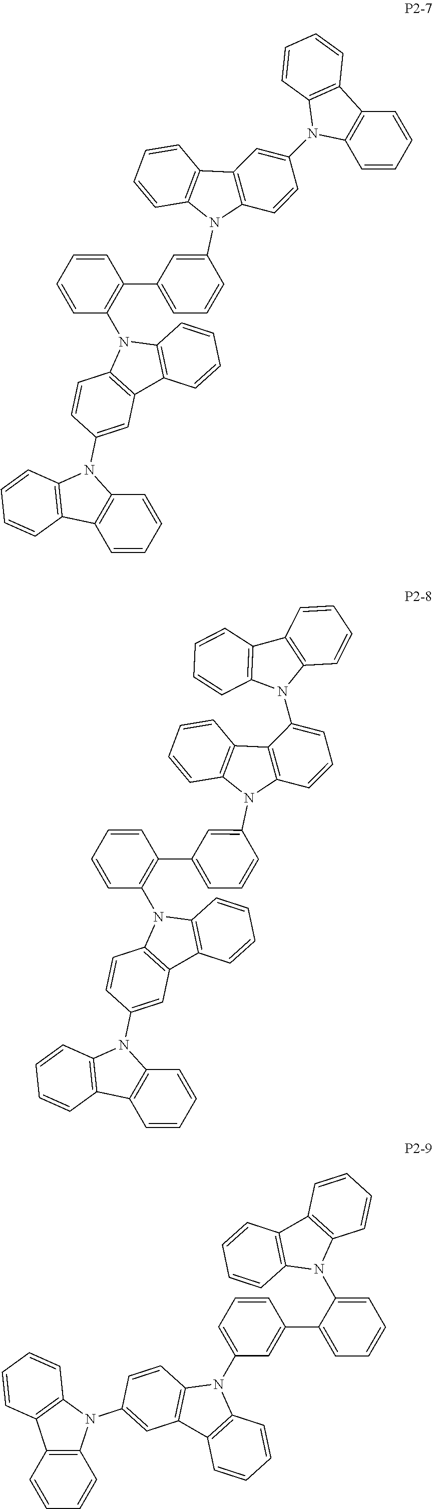 [SMILES: c1cc(-c2ccccc2-n2c3ccccc3c3cc(-n4c5ccccc5c5ccccc54)ccc32)cc(-n2c3ccccc3c3cc(-n4c5ccccc5c5ccccc54)ccc32)c1 ; c1cc(-c2ccccc2-n2c3ccccc3c3cc(-n4c5ccccc5c5ccccc54)ccc32)cc(-n2c3ccccc3c3c(-n4c5ccccc5c5ccccc54)cccc32)c1 ; c1cc(-c2ccccc2-n2c3ccccc3c3ccccc32)cc(-n2c3ccccc3c3cc(-n4c5ccccc5c5ccccc54)ccc32)c1]

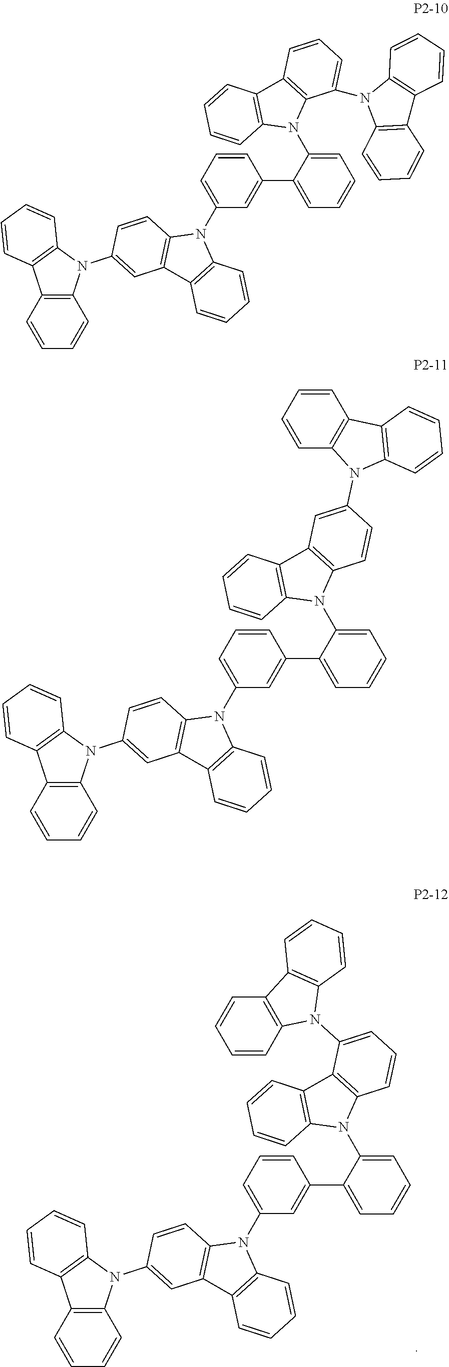 [SMILES: c1cc(-c2ccccc2-n2c3ccccc3c3cccc(-n4c5ccccc5c5ccccc54)c32)cc(-n2c3ccccc3c3cc(-n4c5ccccc5c5ccccc54)ccc32)c1 ; c1cc(-c2ccccc2-n2c3ccccc3c3cc(-n4c5ccccc5c5ccccc54)ccc32)cc(-n2c3ccccc3c3cc(-n4c5ccccc5c5ccccc54)ccc32)c1 ; c1cc(-c2ccccc2-n2c3ccccc3c3c(-n4c5ccccc5c5ccccc54)cccc32)cc(-n2c3ccccc3c3cc(-n4c5ccccc5c5ccccc54)ccc32)c1]

The second compound 354 can comprise a triazine-containing organic compound. The second compound 354 comprise an organic compound having the following structure of Chemical Formula 5:

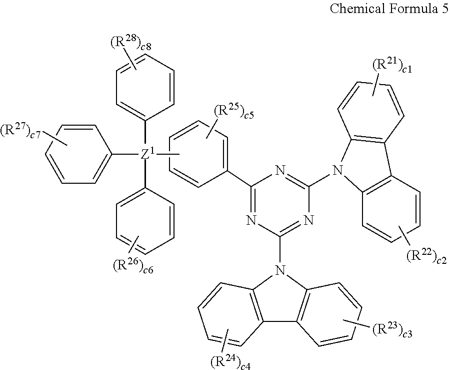

wherein, in Chemical Formula 5,
Z¹ is C, Si or Ge;
each of R²¹ to R²⁸ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, an unsubstituted or substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group or an unsubstituted or substituted C₂-C₃₀ tri-hetero aryl methyl group, where each R²¹ is identical to or different from each other when c1 is 2, 3 or 4, each R²² is identical to or different from each other when c2 is 2, 3 or 4, each R²³ is identical to or different from each other when c3 is 2, 3 or 4, each R²⁴ is identical to or different from each other when c4 is 2, 3 or 4, each R²⁵ is identical to different from each other when c5 is 2, 3 or 4, each R²⁶ is identical to or different from each other when c6 is 2, 3, 4 or 5, each R²⁷ is identical to or different from each other when c7 is 2, 3, 4 or 5, and each R²⁸ is identical to or different from each other when c8 is 2, 3, 4 or 5;
each of c1, c2, c3, c4 and c5 is independently 0, 1, 2, 3 or 4; and
each of c6, c7 and c8 is independently 0, 1, 2, 3, 4 or 5.

As an example, the second compound 354 having the structure of Chemical Formula 5 can be at least one of or selected from, but is not limited to, the following organic compounds of Chemical Formula 6:

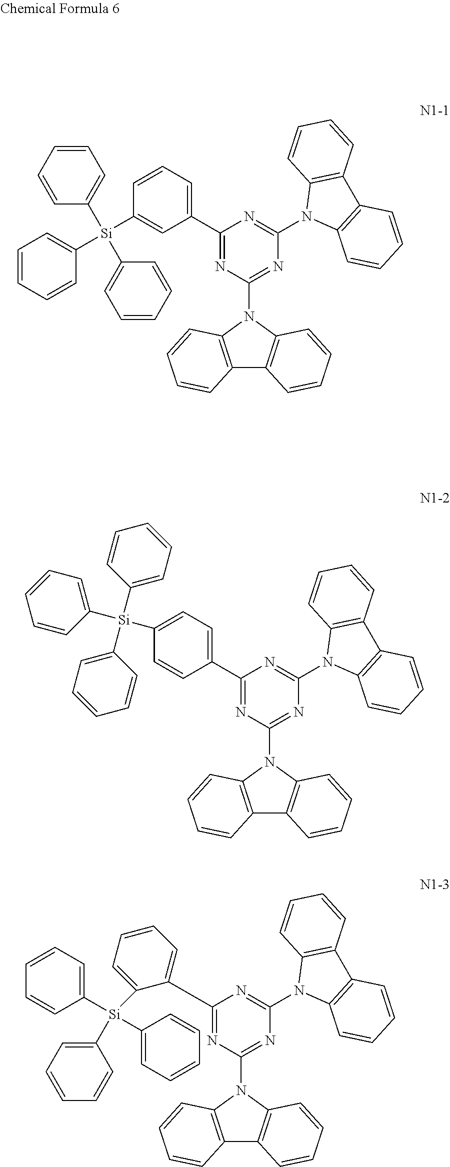 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1 ; c1ccc([Si](c2ccccc2)(c2ccccc2)c2ccccc2-c2nc(-n3c4ccccc4c4ccccc43)nc(-n3c4ccccc4c4ccccc43)n2)cc1]

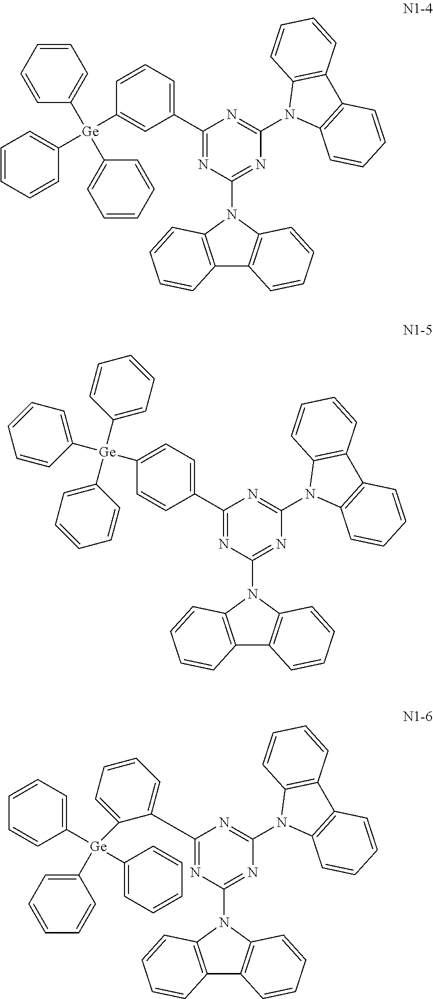

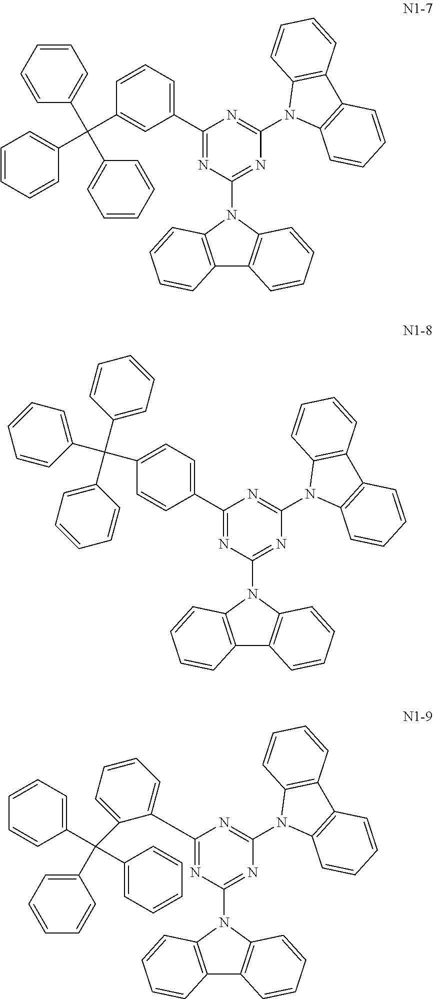 [SMILES: c1ccc(C(c2ccccc2)(c2ccccc2)c2cccc(-c3nc(-n4c5ccccc5c5ccccc54)nc(-n4c5ccccc5c5ccccc54)n3)c2)cc1 ; c1ccc(C(c2ccccc2)(c2ccccc2)c2ccc(-c3nc(-n4c5ccccc5c5ccccc54)nc(-n4c5ccccc5c5ccccc54)n3)cc2)cc1 ; c1ccc(C(c2ccccc2)(c2ccccc2)c2ccccc2-c2nc(-n3c4ccccc4c4ccccc43)nc(-n3c4ccccc4c4ccccc43)n2)cc1]

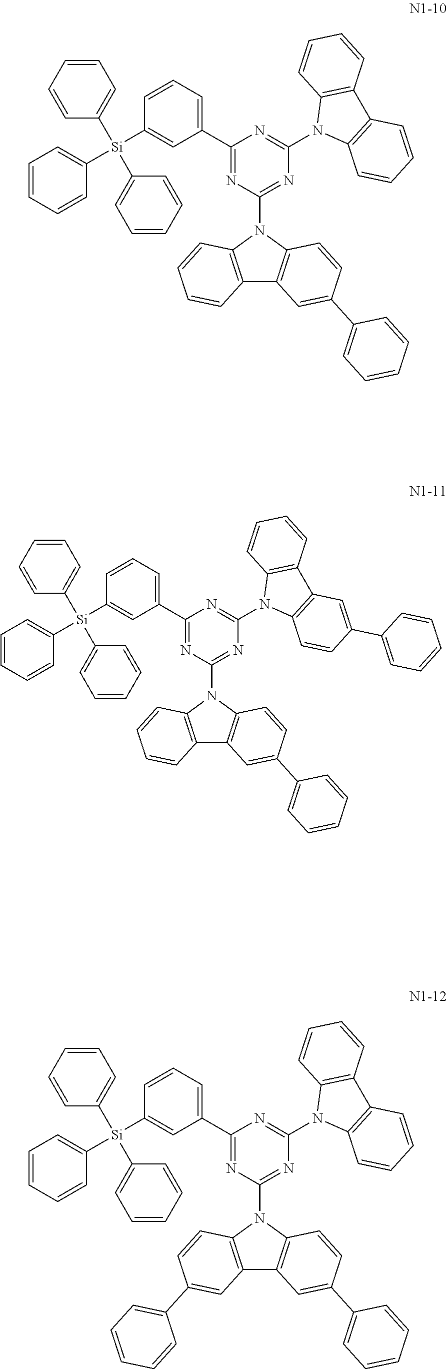 [SMILES: c1ccc(-c2ccc3c(c2)c2ccccc2n3-c2nc(-c3cccc([Si](c4ccccc4)(c4ccccc4)c4ccccc4)c3)nc(-n3c4ccccc4c4ccccc43)n2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4cc(-c5ccccc5)ccc43)n2)cc1 ; c1ccc(-c2ccc3c(c2)c2cc(-c4ccccc4)ccc2n3-c2nc(-c3cccc([Si](c4ccccc4)(c4ccccc4)c4ccccc4)c3)nc(-n3c4ccccc4c4ccccc43)n2)cc1]

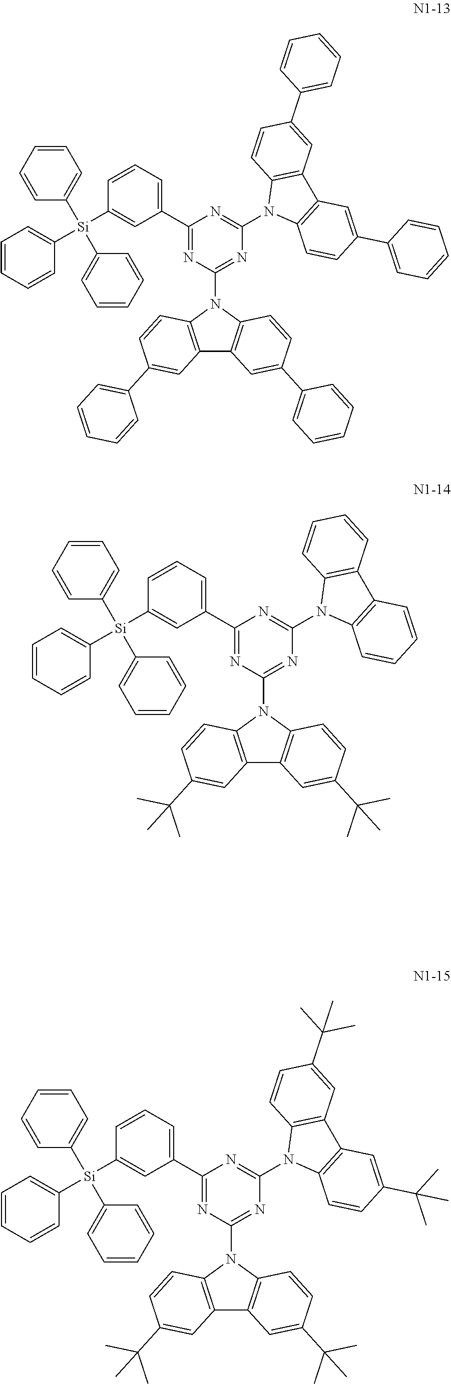 [SMILES: c1ccc(-c2ccc3c(c2)c2cc(-c4ccccc4)ccc2n3-c2nc(-c3cccc([Si](c4ccccc4)(c4ccccc4)c4ccccc4)c3)nc(-n3c4ccc(-c5ccccc5)cc4c4cc(-c5ccccc5)ccc43)n2)cc1 ; CC(C)(C)c1ccc2c(c1)c1cc(C(C)(C)C)ccc1n2-c1nc(-c2cccc([Si](c3ccccc3)(c3ccccc3)c3ccccc3)c2)nc(-n2c3ccccc3c3ccccc32)n1 ; CC(C)(C)c1ccc2c(c1)c1cc(C(C)(C)C)ccc1n2-c1nc(-c2cccc([Si](c3ccccc3)(c3ccccc3)c3ccccc3)c2)nc(-n2c3ccc(C(C)(C)C)cc3c3cc(C(C)(C)C)ccc32)n1]

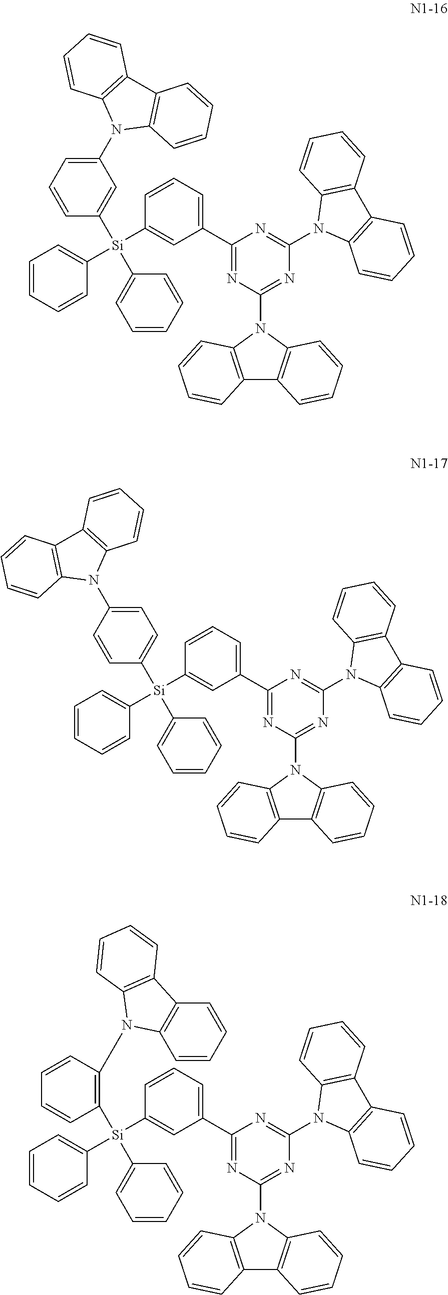 [SMILES: c1ccc([Si](c2ccccc2)(c2cccc(-c3nc(-n4c5ccccc5c5ccccc54)nc(-n4c5ccccc5c5ccccc54)n3)c2)c2cccc(-n3c4ccccc4c4ccccc43)c2)cc1 ; c1ccc([Si](c2ccccc2)(c2ccc(-n3c4ccccc4c4ccccc43)cc2)c2cccc(-c3nc(-n4c5ccccc5c5ccccc54)nc(-n4c5ccccc5c5ccccc54)n3)c2)cc1 ; c1ccc([Si](c2ccccc2)(c2cccc(-c3nc(-n4c5ccccc5c5ccccc54)nc(-n4c5ccccc5c5ccccc54)n3)c2)c2ccccc2-n2c3ccccc3c3ccccc32)cc1]

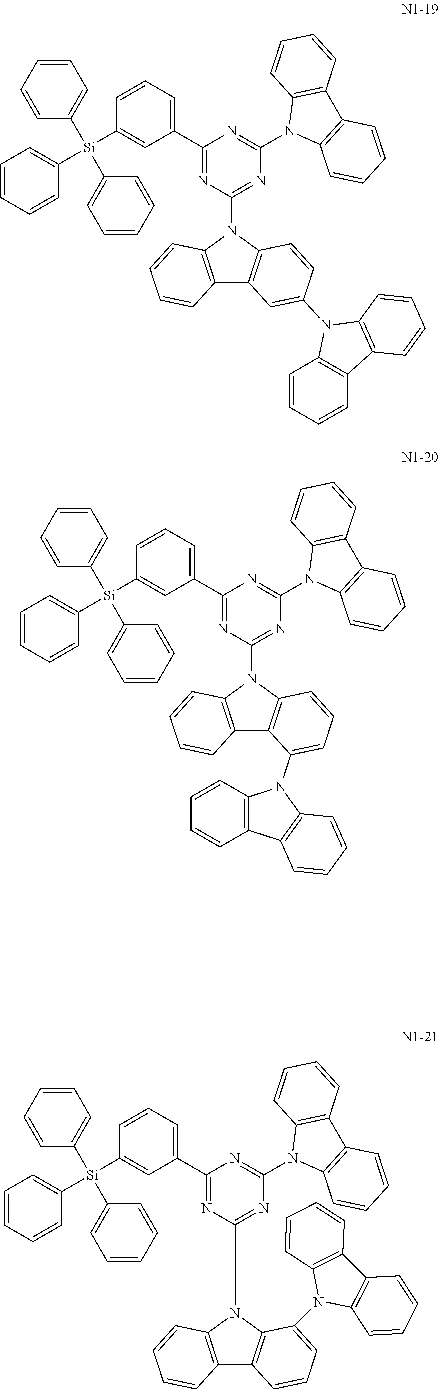 [SMILES: c1ccc([Si](c2ccccc2)(c2ccccc2)c2cccc(-c3nc(-n4c5ccccc5c5ccccc54)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5ccccc54)nc(-n4c5ccccc5c5c(-n6c7ccccc7c7ccccc76)cccc54)n3)c2)cc1 ; c1ccc([Si](c2ccccc2)(c2ccccc2)c2cccc(-c3nc(-n4c5ccccc5c5ccccc54)nc(-n4c5ccccc5c5cccc(-n6c7ccccc7c7ccccc76)c54)n3)c2)cc1]

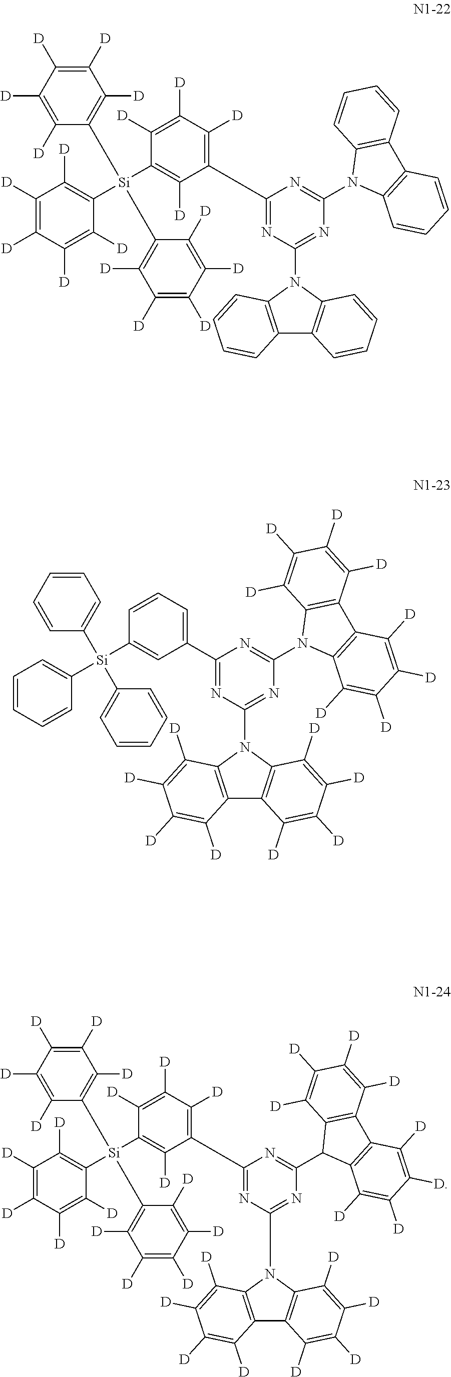

In one embodiment, the first compound 352 and the second compound 354 in the EGL 350 can be mixed with a weight ratio of about 4:1 to about 1:4, for example, about 3:1 to about 1:1, but is not limited thereto.

The first host 342 can be a P-type host with beneficial hole affinity property and/or hole transporting property. The first host 342 can comprise the carbazole-containing organic compound having the structure of Chemical Formulae 1 to 4. The first host 342 can be identical to or different form the first compound 352.

The second host 344 can comprise an N-type host with beneficial electron affinity property and/or electron transporting property. The second host 344 can have delayed fluorescent property and can comprise an organic compound having the following structure of Chemical Formula 7:

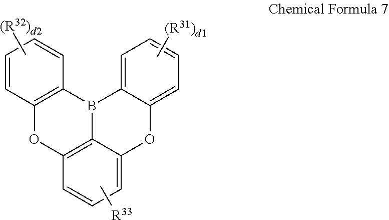

wherein, in Chemical Formula 7,
each of R³¹ to R³³ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, an unsubstituted or substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, an unsubstituted or substituted C₂-C₃₀ tri-hetero aryl methyl group, or has the following structure of Chemical Formula 8, where each R³¹ is identical to or different from each other when d1 is 2, 3 or 4, and each R³² is identical to or different from each other when d2 is 2, 3 or 4, where a polycyclic ring comprising boron and oxygen has at least one hetero aryl group having the following structure of Chemical Formula 9:

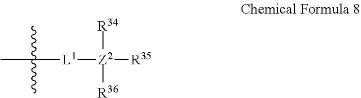

wherein, in Chemical Formula 8,
Z² is C, Si or Ge;
Each of R³⁴ to R³⁶ is independently an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group or an unsubstituted or substituted C₂-C₃₀ hetero aryloxy group;
L¹ is an unsubstituted or substituted C₆-C₃₀ arylene group or an unsubstituted or substituted C₂-C₃₀ hetero arylene group; and
wavy line indicates a link position,

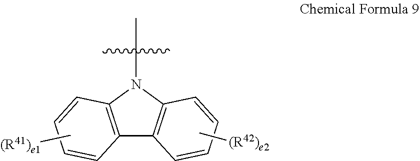

wherein, in Chemical Formula 9,
each of R⁴¹ and R⁴² is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, or an unsubstituted or substituted C₂-C₃₀ tri-hetero aryl methyl group, where each R⁴¹ is identical to or different from each other when e1 is 2, 3 or 4, and each R⁴² is identical to or different from each other when e2 is 2, 3 or 4, or
optionally,
two adjacent R⁴¹ and/or two adjacent R⁴² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring; and
wavy line indicates a link position.

As an example, the fused ring that can be formed by two adjacent R⁴¹ and/or two adjacent R⁴² in Chemical Formula 9 can comprise, but is not limited to, an indene ring, an indole ring, a benzofuran ring and/or benzothiophene ring, each of which can be independently unsubstituted or substituted.

The polycyclic ring comprising boron and oxygen in the second host 344 having the structure of Chemical Formula 7 acts as electron acceptor moiety or electron withdrawing moiety. The hetero aryl group having the structure of Chemical Formula 9 acts as electron donor moiety. As the electron donor moiety of plural fused rings has bulky volume, steric hindrances among those moieties are induced, and thus the second compound 354 having the structure of Chemical Formula 7 has delayed fluorescent property. For example, The second host 344 can have a narrow difference or energy bandgap ΔE_{ST} between its lowest excited state singlet energy level S₁ and its lowest excited triplet energy level T₁ such as about 0.3 eV, for example, about 0.01 eV to about 0.3 eV.

Since the second host 344 having the structure of Chemical Formula 7 has very narrow difference or energy bandgap ΔE_{ST} between its lowest excited state singlet energy level S₁ and its lowest excited triplet energy level T₁, spin-orbital coupling (SOC) within the molecule can be enhanced. Accordingly, reverse intersystem crossing (RISC), up-conversion from the lowest excited state triplet energy level T₁ to the lowest excited state singlet energy level S₁, within the molecule can be occurred rapidly.

In one embodiment, the second host 344 having the structure of Chemical Formula 7 can comprise one to three hetero aryl groups having the structure of Chemical Formula 9 substituted to the polycyclic ring with boron and oxygen. For example, one to three of R³¹ to R³³ in Chemical Formula 7 can be substituted to the hetero aryl group having the structure of Chemical Formula 9. In another embodiment, the hetero aryl group having the structure of Chemical Formula 9 can be unsubstituted or substituted with one to five, for example, one to three, or one or two, carbazolyl groups.

As an example, the second host 344 having the structure of Chemical Formula 7 can be at least one of or selected from, but is not limited to, the following organic compounds of Chemical Formula 10:

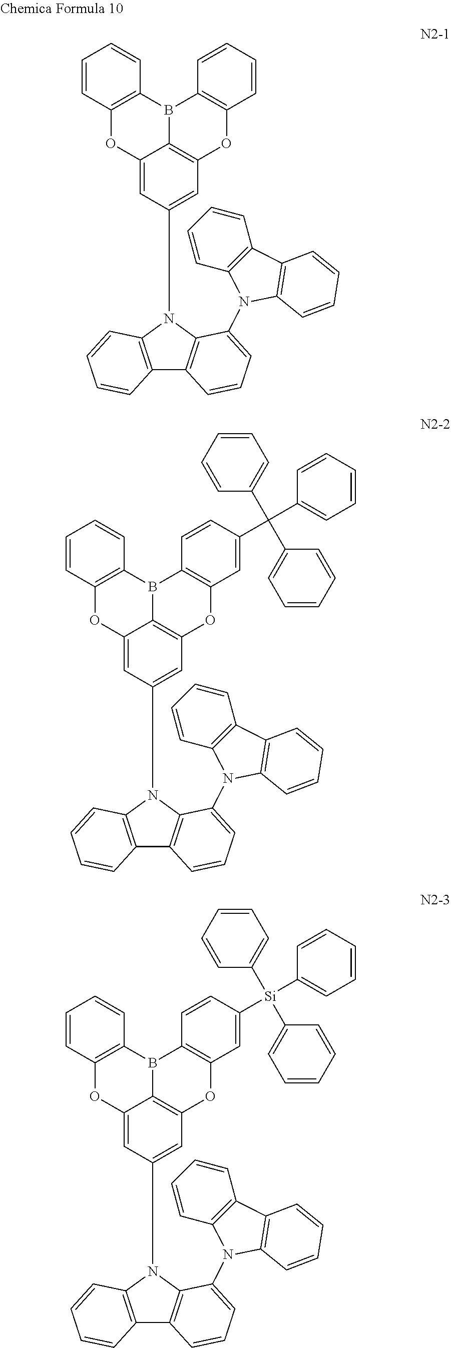

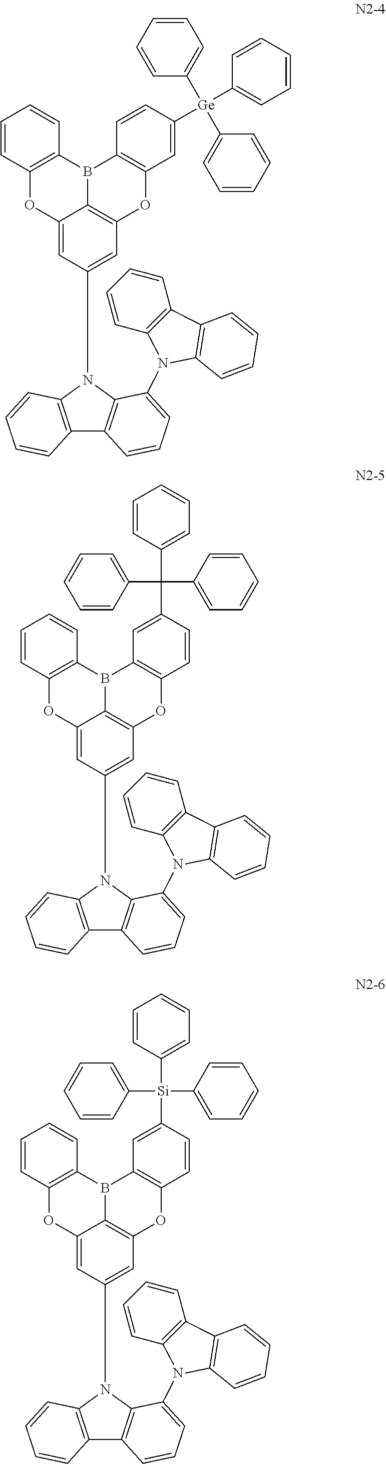

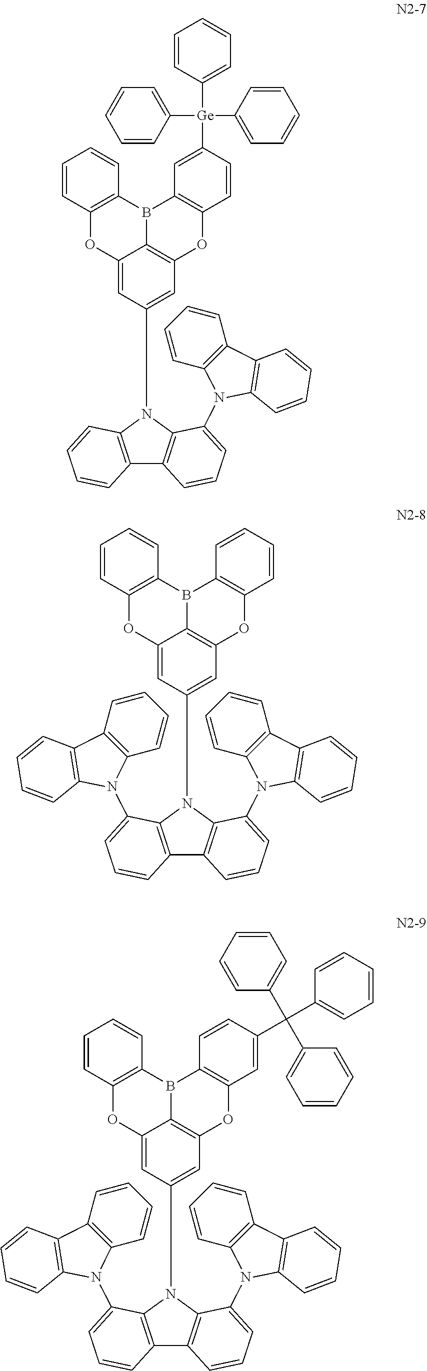

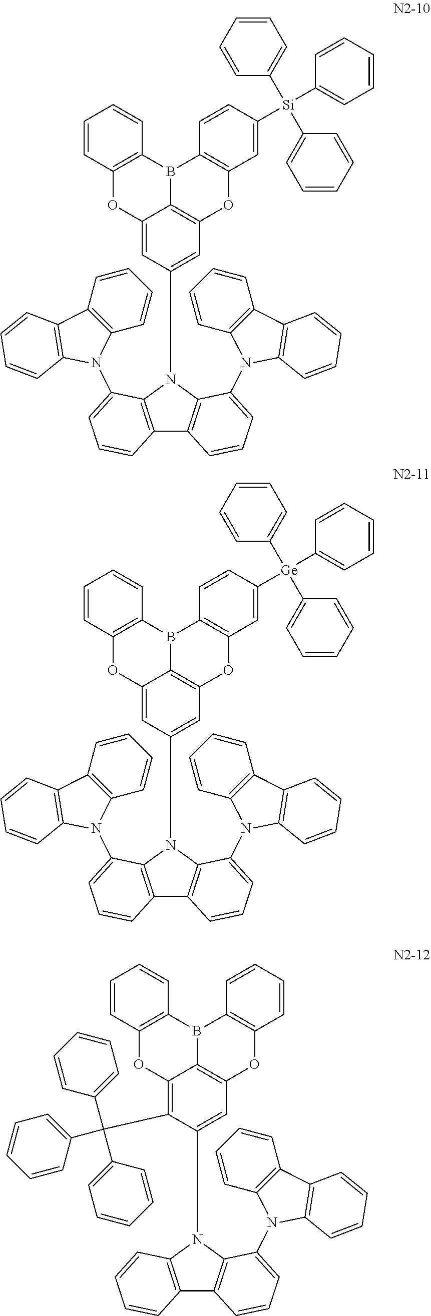

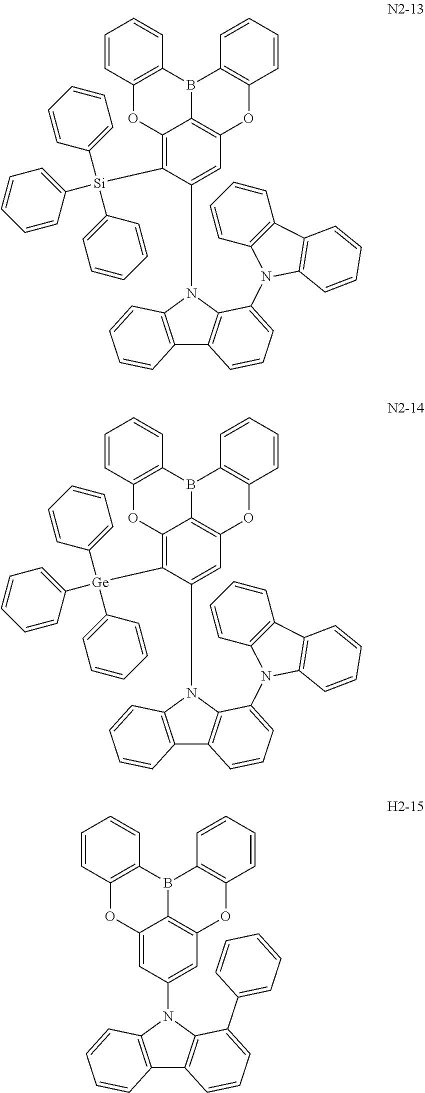

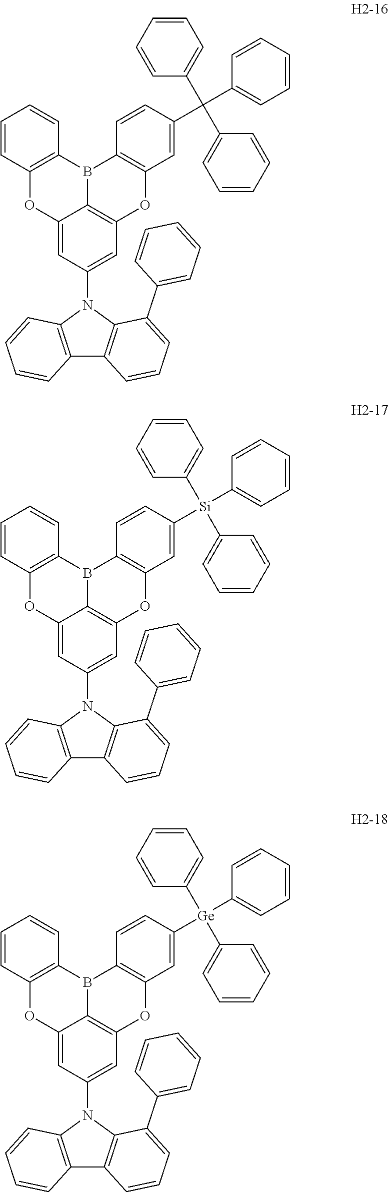

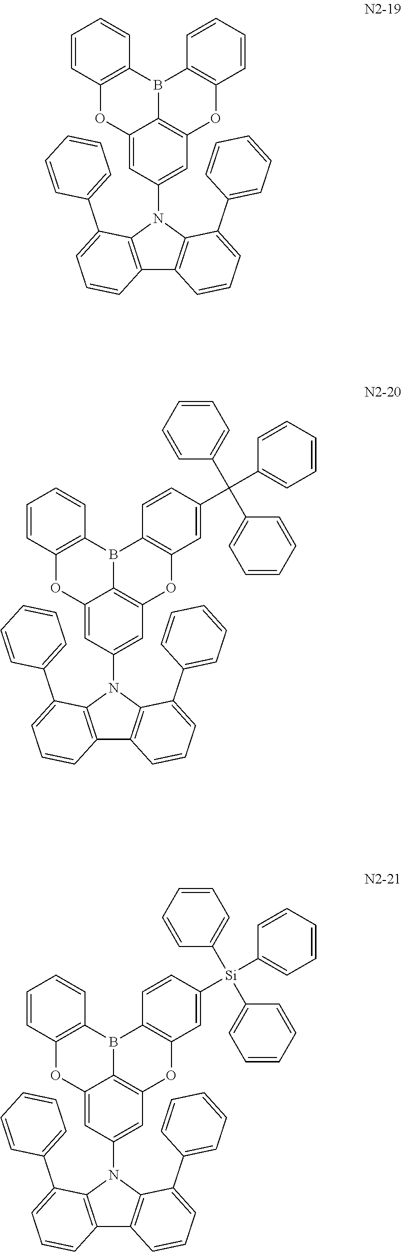 [SMILES: c1ccc(-c2cccc3c4cccc(-c5ccccc5)c4n(-c4cc5c6c(c4)Oc4ccccc4B6c4ccccc4O5)c23)cc1 ; c1ccc(-c2cccc3c4cccc(-c5ccccc5)c4n(-c4cc5c6c(c4)Oc4cc(C(c7ccccc7)(c7ccccc7)c7ccccc7)ccc4B6c4ccccc4O5)c23)cc1 ; c1ccc(-c2cccc3c4cccc(-c5ccccc5)c4n(-c4cc5c6c(c4)Oc4cc([Si](c7ccccc7)(c7ccccc7)c7ccccc7)ccc4B6c4ccccc4O5)c23)cc1]

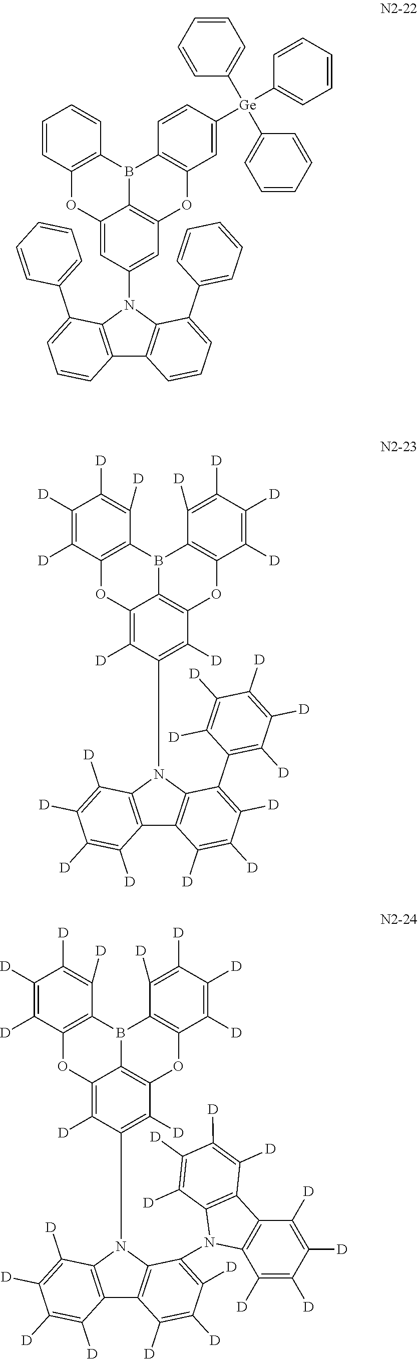

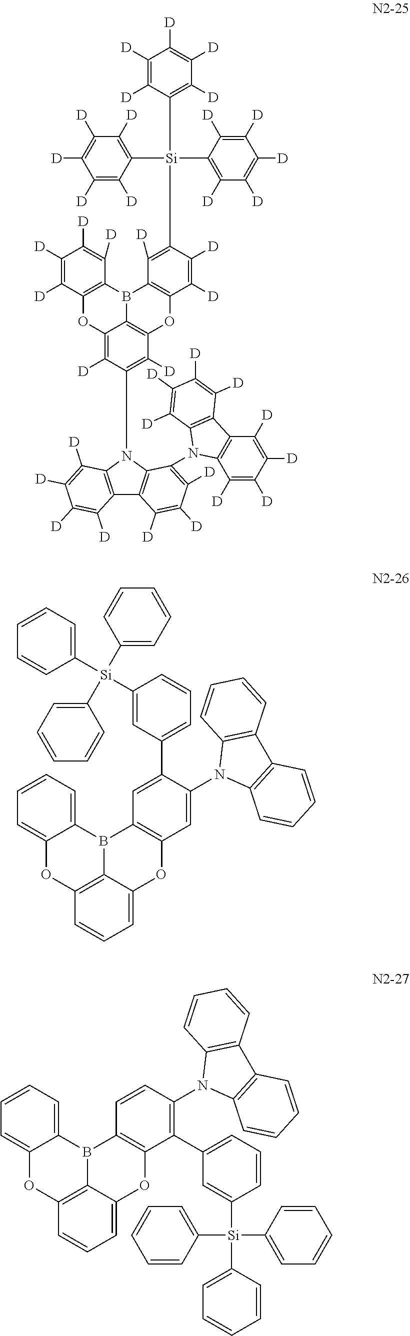

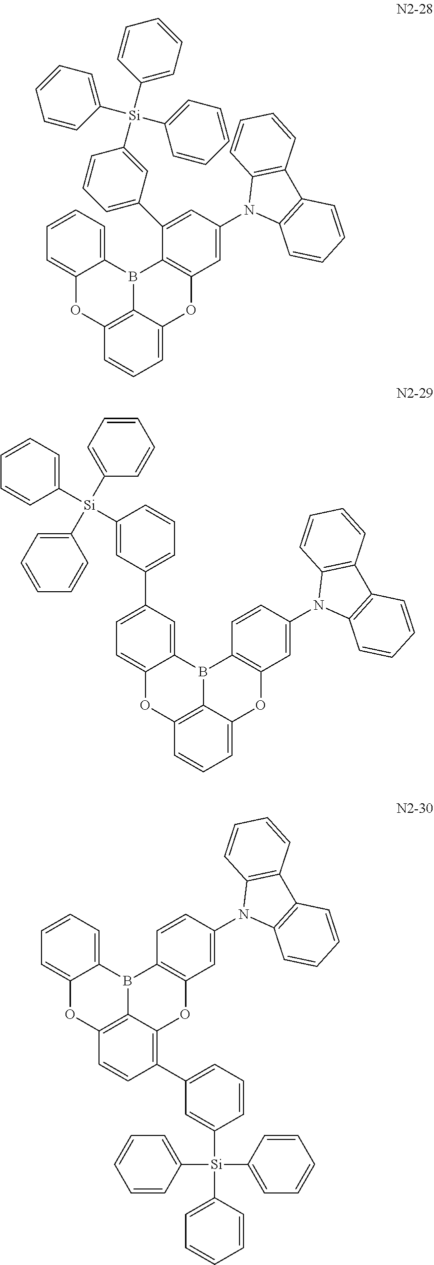

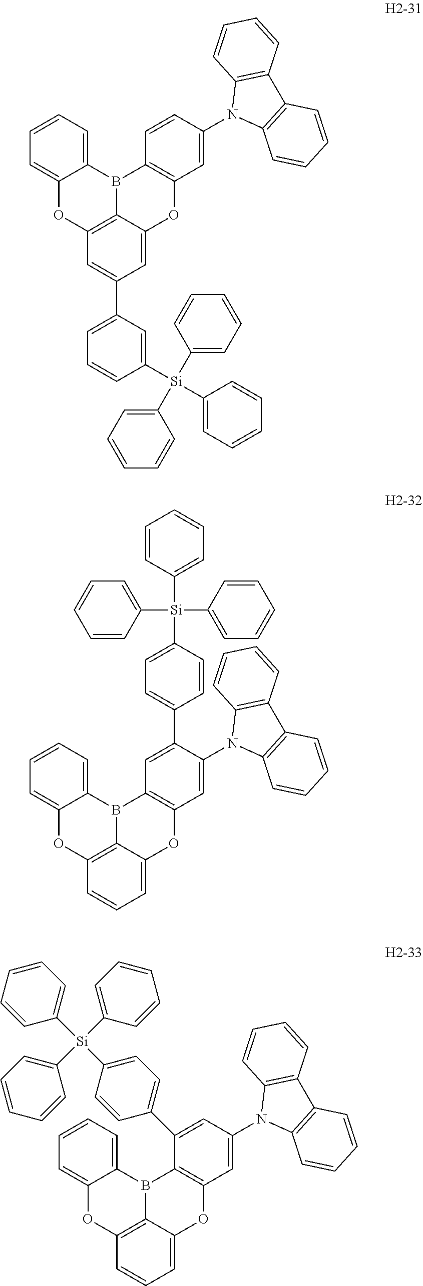

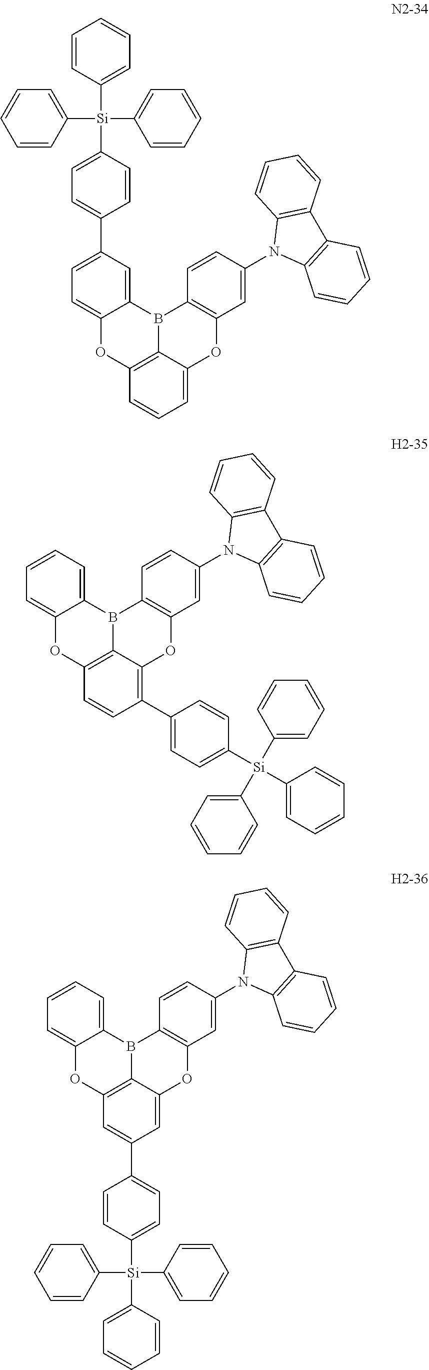

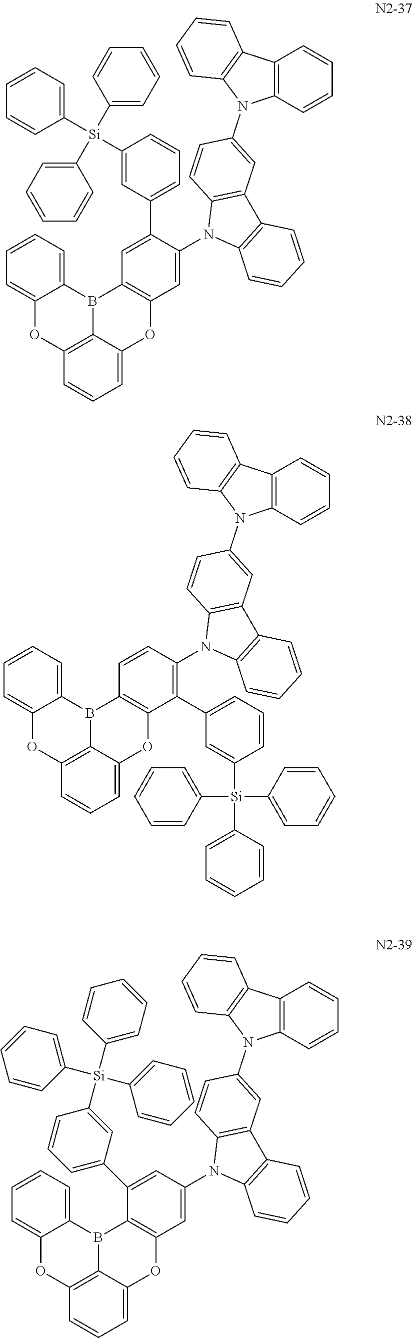 [SMILES: c1ccc([Si](c2ccccc2)(c2ccccc2)c2cccc(-c3cc4c(cc3-n3c5ccccc5c5cc(-n6c7ccccc7c7ccccc76)ccc53)Oc3cccc5c3B4c3ccccc3O5)c2)cc1 ; c1ccc([Si](c2ccccc2)(c2ccccc2)c2cccc(-c3c(-n4c5ccccc5c5cc(-n6c7ccccc7c7ccccc76)ccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5cc(-n6c7ccccc7c7ccccc76)ccc54)cc4c3B3c5ccccc5Oc5cccc(c53)O4)c2)cc1]

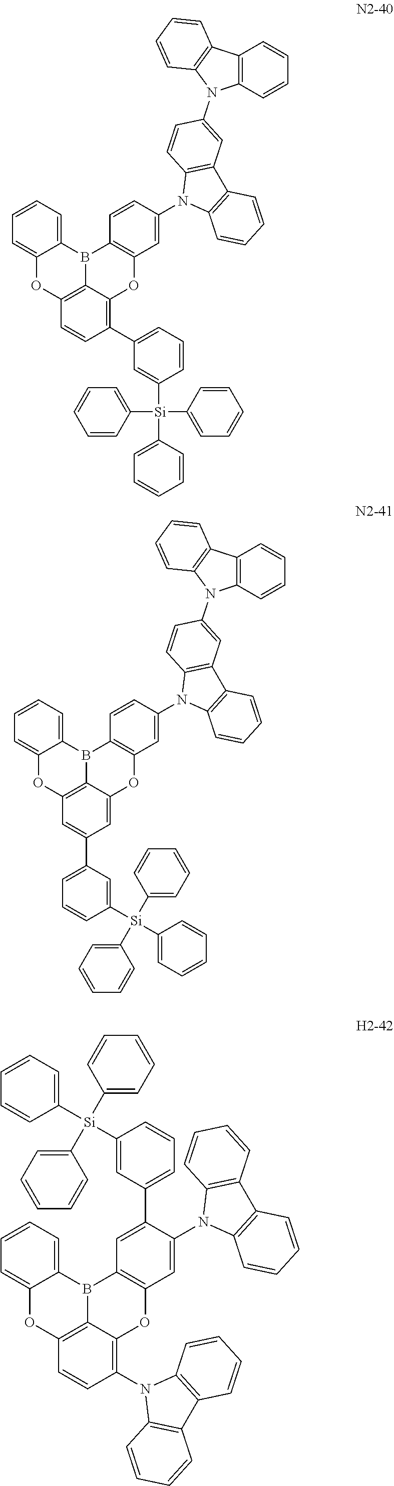

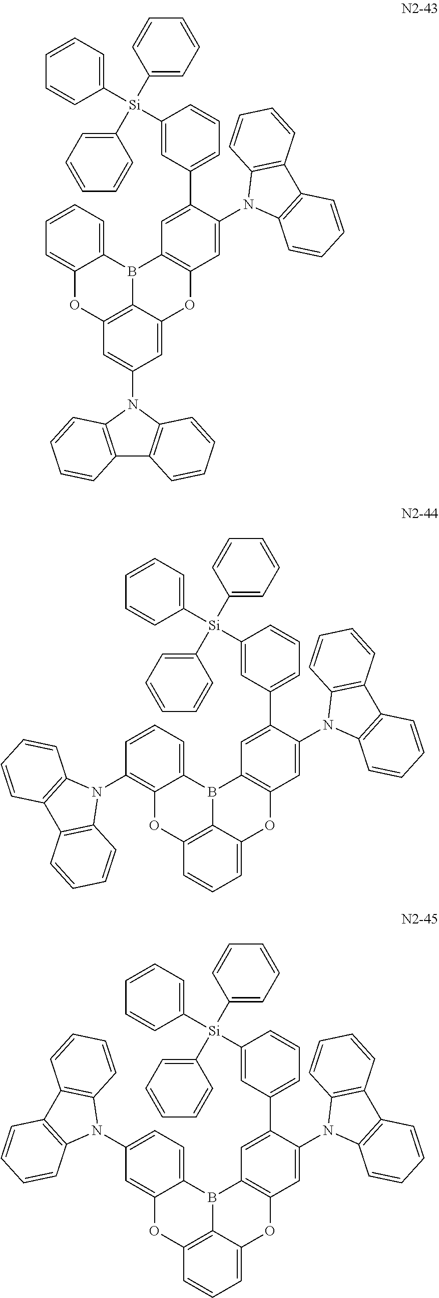 [SMILES: c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1 ; c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1]

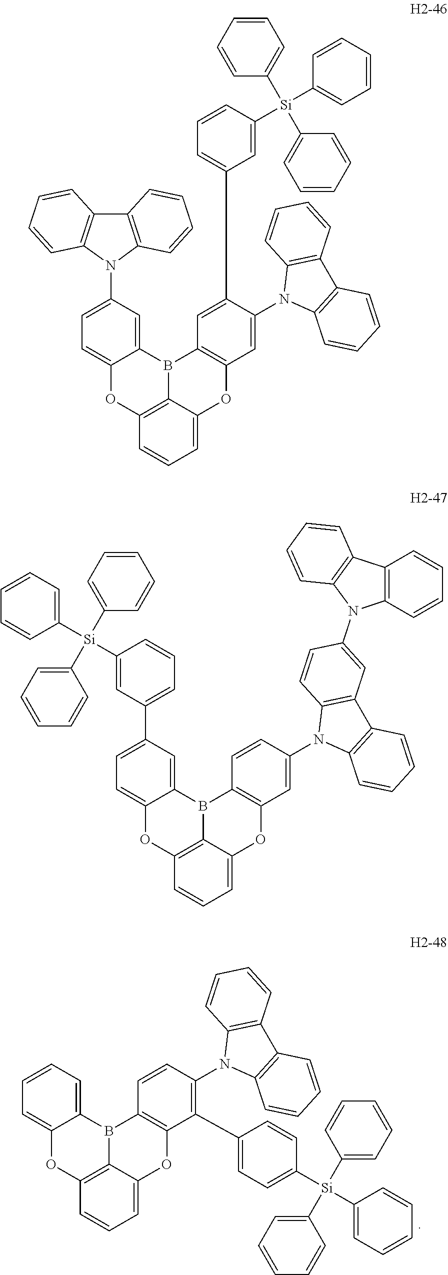 [SMILES: c1ccc([Si](c2ccccc2)(c2ccccc2)c2cccc(-c3cc4c(cc3-n3c5ccccc5c5ccccc53)Oc3cccc5c3B4c3cc(-n4c6ccccc6c6ccccc64)ccc3O5)c2)cc1 ; c1ccc([Si](c2ccccc2)(c2ccccc2)c2cccc(-c3ccc4c(c3)B3c5ccc(-n6c7ccccc7c7cc(-n8c9ccccc9c9ccccc98)ccc76)cc5Oc5cccc(c53)O4)c2)cc1 ; c1ccc([Si](c2ccccc2)(c2ccccc2)c2ccc(-c3c(-n4c5ccccc5c5ccccc54)ccc4c3Oc3cccc5c3B4c3ccccc3O5)cc2)cc1]

In one embodiment, the emitter 346 can comprise at least one of blue phosphorescent material, blue fluorescent material and blue delayed fluorescent material. As an example, the emitter 346 can comprise blue phosphorescent material. For example, the emitter 346 can comprise an organometallic compound having the following structure of Chemical Formula 11:

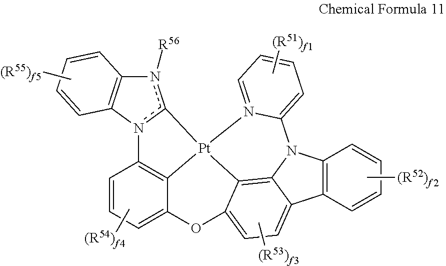

wherein, in Chemical Formula 11,
each of R⁵¹ and R⁵⁶ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, or an unsubstituted or substituted C₂-C₃₀ tri-hetero aryl methyl group, where each R⁵¹ is identical to or different from each other when f1 is 2, 3 or 4, and each R⁵² is identical to or different from each other when f2 is 2, 3 or 4, each R⁵³ is identical to or different from each other when f3 is 2, each R⁵⁴ is identical to or different from each other when f4 is 2 or 3, and each R⁵⁵ is identical to or different from each other when f5 is 2, 3 or 4;
each of f1, f2 and f5 is independently 0, 1, 2, 3 or 4;
f3 is 0, 1 or 2; and
f4 is 0, 1, 2 or 3.

As an example, the emitter 346 having the structure of Chemical Formula 11 can be at least one of or selected from, but is not limited to, the following organometallic compounds of Chemical Formula 12:

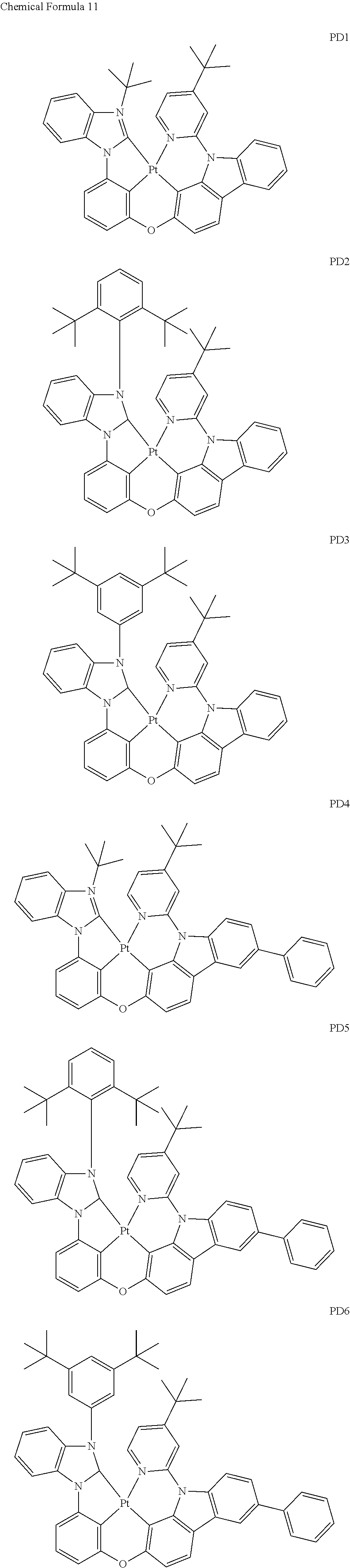

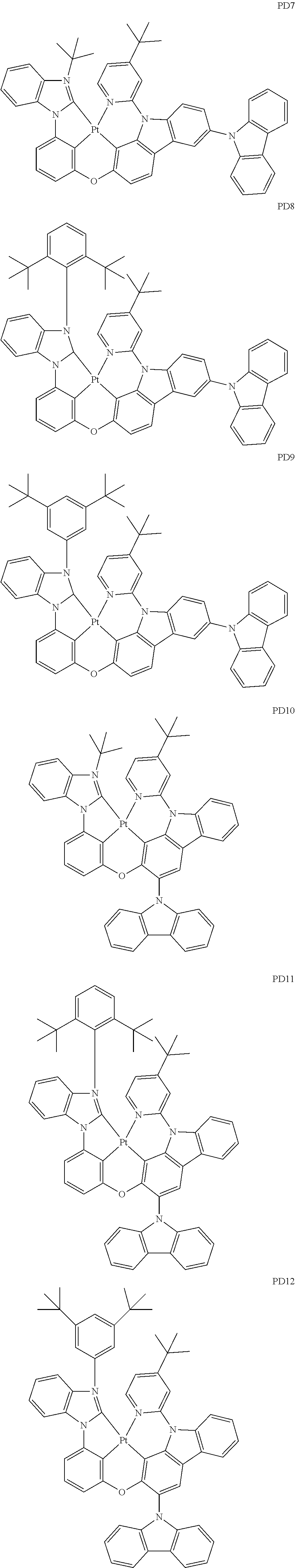

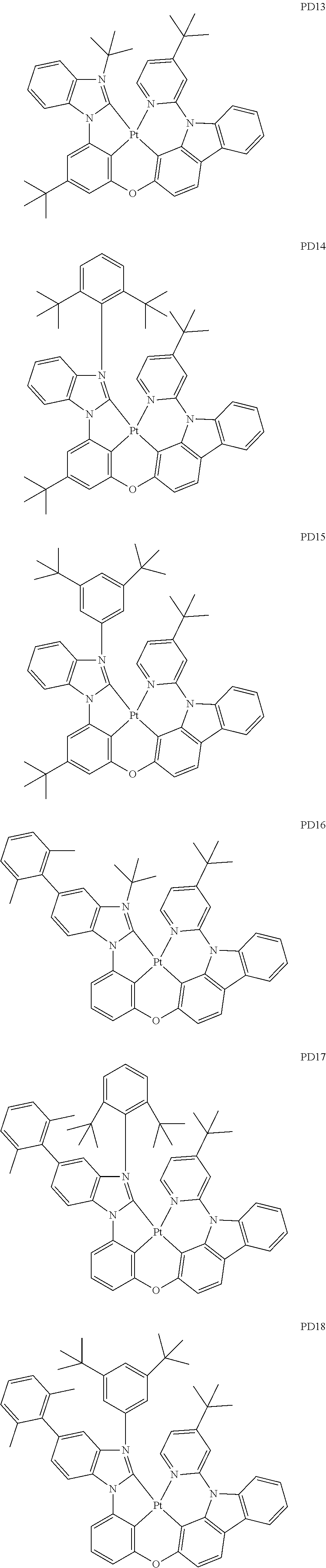

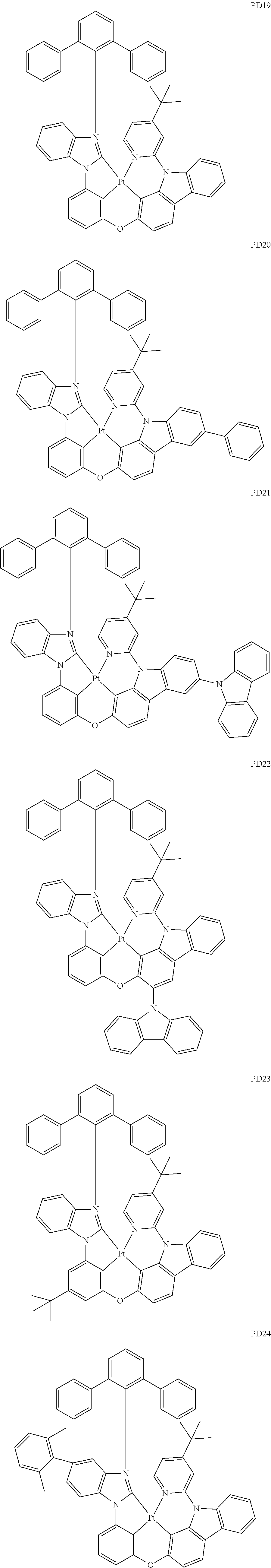

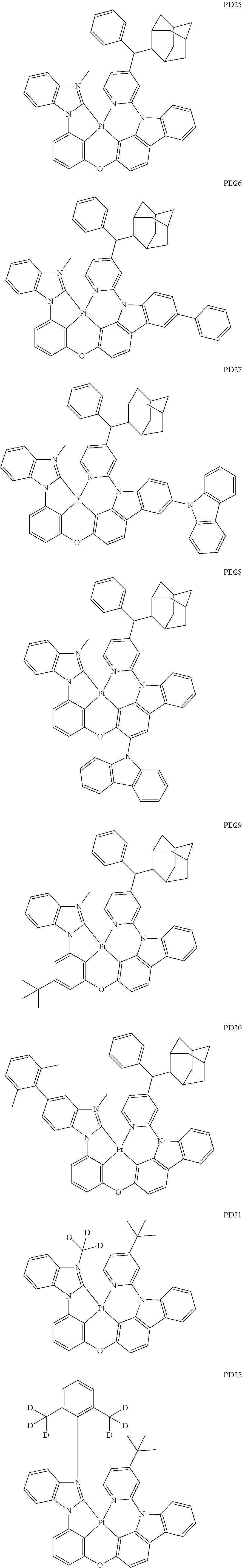

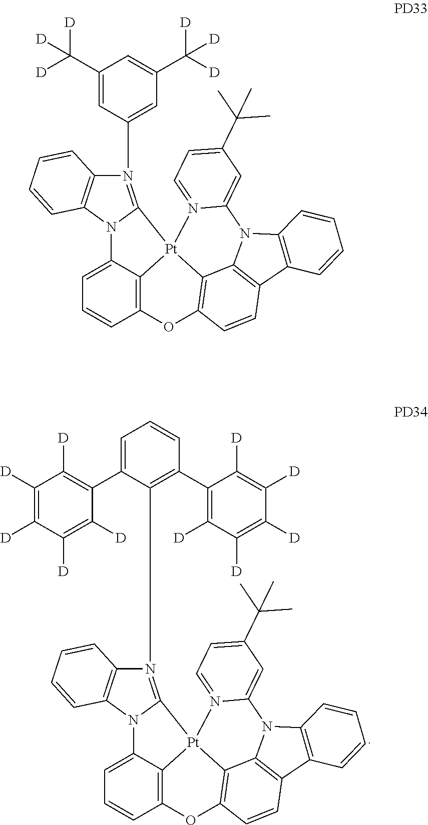

The contents of the host comprising the first host 342 and the second host 344 in the EML 340 can be about 50 wt. % to about 99 wt. %, for example, about 50 wt. % to about 90 wt. % or about 60 wt. % to about 90 wt. %, the contents of the emitter 346 in the EML 340 can be about 1 wt. % to about 50 wt. %, for example, about 10 wt. % to about 50 wt. % or about 10 wt. % to about 40 wt. %, but is not limited thereto. The first host 342 and the second host 344 in the EML 340 can be mixed, but is not limited to, with a weight ratio of about 4:1 to about 1:4, for example about 3:1 to about 1:3.

The HIL 310 is disposed between the first electrode 210 and the HTL 320 and can improve an interface property between the inorganic first electrode 210 and the organic HTL 320. In one embodiment, hole injecting material in the HIL 310 can include, but is not limited to, 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-diphenyl-N,N′-bis(1-naphthyl)-1,1′-biphenyl-4,4″-diamine (NPB; NPD), N,N′-bis{4-[bis(3-methylphenyl)amino]phenyl}-N,N′-diphenyl-4,4′-biphenyldiamine (DNTPD), 1,4,5,8,9,11-hexaazatriphenylenehexacarbonitrile (dipyrazino[2,3-f:2′3′-h]quinoxaline-2,3,6,7,10,11-hexacarbonitrile; HAT-CN), 2,3,5,6-tetrafluoro-7,7,8,8-tetracyanoquinodimethane (F4-TCNQ), 1,3,4,5,7,8-hexafluorotetracaynonaphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB) and/or combinations thereof.

In another embodiment, the HIL 310 can include hole injection host of the following hole transporting material and hole injection dopant of the above hole injecting material (e.g., HAT-CN, F4-TCNQ and/or F6-TCNNQ). In this case, the contents of the hole injection dopant in the HIL 310 can be, but is not limited to, about 1 wt. % to about 10 wt. %. In certain embodiments, the HIL 310 can be omitted in compliance of the OLED D1 property.

The HTL 320 is disposed adjacently to the EML 340 between the first electrode 210 and the EML 340. In one embodiment, hole transporting material in the HTL 320 can include, but is not limited to, N,N′-diphenyl-N,N′-bis(3-methylphenyl)-1,1′-biphenyl-4,4′-diamine (TPD), NPB(NPD), DNTPD, 4,4′-bis(N-carbazolyl)-1,1′-biphenyl (CBP), Poly[N,N′-bis(4-butylphenyl)-N,N′-bis(phenyl)-benzidine](Poly-TPD), Poly[(9,9-dioctylfluorenyl-2,7-diyl)-co-(4,4′-(N-(4-sec-butylphenyl)diphenylamine))](TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine), N-([1,1′-biphenyl]-4-yl)-9,9-dimethyl-N-(4-(9-phenyl-9H-carbazol-3-yl)phenyl)-9H-fluoren-2-amine and/or combinations thereof.

The ETL 370 and the EIL 380 can be laminated sequentially between the EML 340 and the second electrode 220. An electron transporting material included in the ETL 370 has high electron mobility so as to provide electrons stably with the EML 340 by fast electron transportation.

The electron transporting material in the ETL 370 can include at least one of oxadiazole-containing compounds, triazole-containing compounds, phenanthroline-containing compounds, benzoxazole-containing compounds, benzothiazole-containing compounds, benzimidazole-containing compounds and triazine-containing compounds.

For example, the electron transporting material in the ETL 370 can include, but is not limited to, tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,O8)-(1,1′-biphenyl-4-olato)aluminum (BAlq), 4,7-diphenyl-1,10-phenanthroline (Bphen), 2,9-bis(naphthalene-2-yl) 4,7-diphenyl-1,10-phenanthroline (NBphen), 2,9-dimethyl-4,7-diphenyl-1,10-phenathroline (BCP), 2-phenyl-9-(3-(2-phenyl-1,10-phenanthrolin-9-yl)phenyl)-1,10-phenanthroline, 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)](PFNBr), tris(phenylquinoxaline) (TPQ), TSPO1, 2-[4-(9,10-Di-2-naphthalen2-yl-2-anthracen-2-yl)phenyl]-1-phenyl-1H-benzimidazole (ZADN) and/or combinations thereof.

The EIL 380 is disposed between the second electrode 220 and the ETL 370, and can improve physical properties of the second electrode 220 and therefore, can enhance the lifespan of the OLED D1. In one embodiment, electron injecting material in the EIL 380 can include, but is not limited to, an alkali metal halide or an alkaline earth metal halide such as LiF, CsF, NaF, BaF₂ and the like, and/or an organometallic compound such as Liq, lithium benzoate, sodium stearate, and the like. In certain embodiments, the EIL 380 can be omitted.

In another embodiment, the ETL 370 and the EIL 380 can have a single layered structure. In this case, the above electron transporting material and/or the electron injecting material can be mixed with each other. As an example, the ETL/EIL with a single layered structure can include two or more different electron transporting materials. For example, two electron transporting materials in the ETL/EIL are mixed with a weight ratio of about 3:7 to about 7:3, but is not limited thereto.

When holes are transferred to the second electrode 220 via the EML 340 and/or electrons are transferred to the first electrode 210 via the EML 340, the OLED D1 can have short lifespan and reduced luminous efficiency. In order to prevent those phenomena, the OLED D1 in accordance with this aspect of the present disclosure can have at least one exciton blocking layer adjacent to the EML 340.

As an example, the OLED D1 can include the EBL 330 between the HTL 320 and the EML 340 so as to control and prevent electron transfers. In one embodiment, electron blocking material in the EBL 330 can include, but is not limited to, TCTA, tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof. In another embodiment, the electron blocking material in the EBL 330 can comprise the carbazole-containing organic compound having the structure of Chemical Formulae 1 to 4.

In addition, the OLED D1 can further include the HBL 360 as a second exciton blocking layer between the EML 340 and the ETL 360 so that holes cannot be transferred from the EML 340 to the ETL 360. In one embodiment, hole blocking material in the HBL 350 can include, but is not limited to, at least one of oxadiazole-containing compounds, triazole-containing compounds, phenanthroline-containing compounds, benzoxazole-containing compounds, benzothiazole-containing compounds, benzimidazole-containing compounds, and triazine-containing compounds.

As an example, the hole blocking material in the HBL 350 can include material having a relatively low HOMO energy level compared to the luminescent materials in EML 340. For example, the hole blocking material in the HBL 350 can include, but is not limited to, BCP, BAlq, Alq₃, PBD, spiro-PBD, Liq, bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof. In another embodiment, hole blocking material in the HBL 360 can comprise the organic compound having the structure of Chemical Formulae 7 to 10. In certain embodiments, the EBL 330 and/or the HBL 360 can be omitted in compliance with the OLED D1.

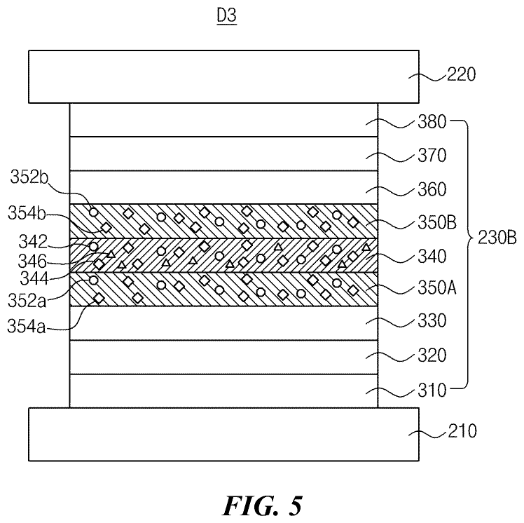

The EGL 350 is disposed between the first electrode 210 and the EML 340 in the first embodiment illustrated in FIG. 3. Alternatively, exciton generation layer can be disposed between an emitting material layer and a second electrode. FIG. 4 illustrates a cross-sectional view of an organic light emitting diode having a single emitting part in accordance with another embodiment of the present disclosure.

As illustrated in FIG. 4, the organic light emitting diode D2 (OLED D2) in accordance with another embodiment comprise a first electrode 210, a second electrode 220 facing the first electrode 210, and an emissive layer 230A disposed between the first and second electrodes 210 and 220. The organic light emitting display device 100 comprises a red pixel region, a green pixel region and a blue pixel region, and the OLED D2 can be disposed in the red pixel region, the green pixel region and/or the blue pixel region. As an example, the OLED D2 can be disposed in the blue pixel region.

In one embodiment, the emissive layer 230A comprises an emitting material layer (EML) 340 disposed between the first and second electrodes 210 and 220, and an exciton generation layer (EGL) 350 disposed between the EML 340 and the second electrode 220, for example, between the EML 340 and a hole blocking layer 360 or an electron transport layer 370. The emissive layer 230A can comprise at least one of a hole transport layer (HTL) 320 disposed between the first electrode 210 and the EML 340 and an electron transport layer (ETL) 370 disposed between the second electrode 230 and the EML 340. In certain embodiments, the emissive layer 230A can further comprise at least one of a hole injection layer (HIL) 310 disposed between the first electrode 210 and the HTL 320 and an electron injection layer (EIL) 380 disposed between the second electrode 230 and the ETL 370. Alternatively or additionally, the emissive layer 230A can further comprise an electron blocking layer (EBL) 330 disposed between the HTL 320 and the EML 340, and/or a hole blocking layer (HBL) 360 disposed between the EML 340 and the ETL 370, for example, the EGL 350 and the ETL 370.

The configurations of the first electrode 210, the second electrode 220 and the emissive layer 230A except the EGL 350 disposed between the EML 340 and the second electrode 210 can be identical to the configurations illustrated in FIG. 3. The EGL 350 comprises a first compound 352 and a second compound 354. The first compound 352 can comprise the carbazole-containing organic compound having the structure of Chemical Formulae 1 to 4. The second compound 354 can comprise the triazine-containing organic compound having the structure of Chemical Formulae 5 to 6.

The EML 340 comprises a first host 342, a second host 344 and an emitter 346. The first host 342 can comprise the carbazole-containing organic compound having the structure of Chemical Formulae 1 to 4. The second host 344 can comprise the organic compound having the structure of Chemical Formulae 7 to 10 and having delayed fluorescent property. The emitter 346 can comprise the organometallic compound having the structure of Chemical Formulae 11 to 12.

The contents of the first compound 352 and the second compound 354 in the EGL 350 and/or the contents of the first host 342, the second host 344 and the emitter 346 in the EML 340 can be identical to the corresponding contents with referring to FIG. 3.

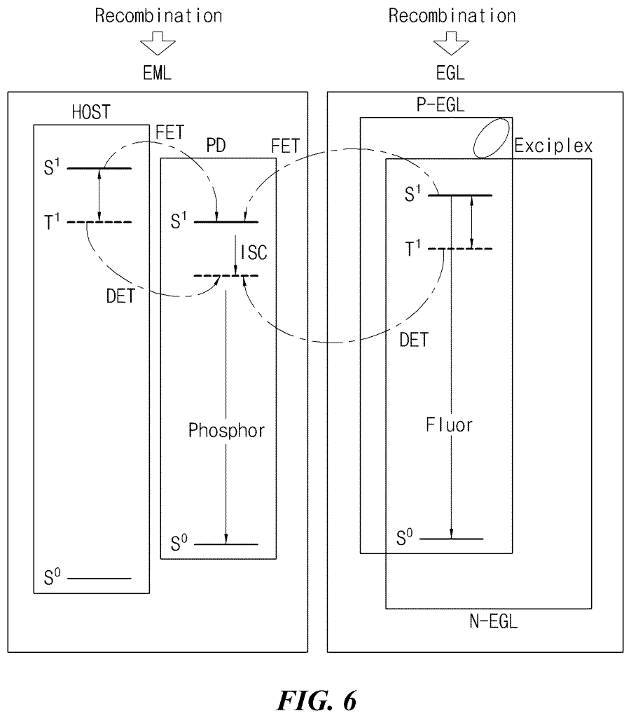

In another embodiment, an exciton generation layer can be disposed between a first electrode and an emitting material layer and between an emitting material layer and a second electrode. FIG. 5 illustrates a cross-sectional view of an organic light emitting diode having a single emitting part in accordance with another embodiment of the present disclosure.

As illustrated in FIG. 5, the organic light emitting diode D3 (OLED D3) in accordance with another embodiment comprise a first electrode 210, a second electrode 220 facing the first electrode 210, and an emissive layer 230B disposed between the first and second electrodes 210 and 220. The organic light emitting display device 100 comprises a red pixel region, a green pixel region and a blue pixel region, and the OLED D2 can be disposed in the red pixel region, the green pixel region and/or the blue pixel region. As an example, the OLED D3 can be disposed in the blue pixel region.

In one embodiment, the emissive layer 230B comprises an emitting material layer (EML) 340 disposed between the first and second electrodes 210 and 220, and a first exciton generation layer (EGL1) 350A disposed between the first electrode 210 and the EML 340, for example, between the a hole transport layer 320 or an electron blocking layer 330 and the EML 340. The emissive layer 230B comprise a second exciton generation layer (EGL2) 350B disposed between the EML 340 and the second electrode 220, for example, the EML 340 and a hole blocking layer 360 or an electron transport layer 370. The emissive layer 230B can comprise at least one of a hole transport layer (HTL) 320 disposed between the first electrode 210 and the EML 340 and an electron transport layer (ETL) 370 disposed between the second electrode 230 and the EML 340. In certain embodiments, the emissive layer 230B can further comprise at least one of a hole injection layer (HIL) 310 disposed between the first electrode 210 and the HTL 320 and an electron injection layer (EIL) 380 disposed between the second electrode 230 and the ETL 370. Alternatively or additionally, the emissive layer 230B can further comprise a first exciton blocking layer, i.e., an electron blocking layer (EBL) 330 disposed between the HTL 320 and the EML 340, for example, the HTL 320 and the EGL1 350A and/or a hole blocking layer (HBL) 360 disposed between the EML 340 and the ETL 370, for example, the EGL2 350B and the ETL 370.

The configurations of the first electrode 210, the second electrode 220 and the emissive layer 230B except the EGL2 350B further disposed between the EML 340 and the second electrode 210 can be identical to the configurations illustrated in FIG. 3. The EGL1 350A comprises a first compound 352a and a second compound 354a, and the EGL2 350B comprises a third compound 352b and a fourth compound 345b. Each of the first compound 352a and the third compound 352b can independently comprise the carbazole-containing organic compound having the structure of Chemical Formulae 1 to 4. Each of the second compound 354a and the fourth compound 354b can independently comprise the triazine-containing organic compound having the structure of Chemical Formulae 5 to 6.

The first compound 352a can be identical to or different from the third compound 352b. The second compound 352b can be identical to or different from the fourth compound 354b. In one embodiment, the first compound 352a and the second compound 354a in the EGL1 350A can be mixed with a weight ratio, but is not limited to, about 4:1 to about 1:4, for example, about 3:1 to about 1:3. In another embodiment, the third compound 352b and the fourth compound 354b in the EGL2 350B can be mixed with a weight ratio, but is not limited to, about 4:1 to about 1:4, for example, about 3:1 to about 1:3.

The materials or the contents of the first host 342, the second host 344 and the emitter 346 in the EML 340 can be identical to the corresponding materials and contents with referring to FIG. 3.

An organic light emitting diode can lower its driving voltage and can maximize its luminous lifespan by applying at least one exciton generation layer where exciplex can be generated adjacently to an emitting material layer comprising delayed fluorescent host.

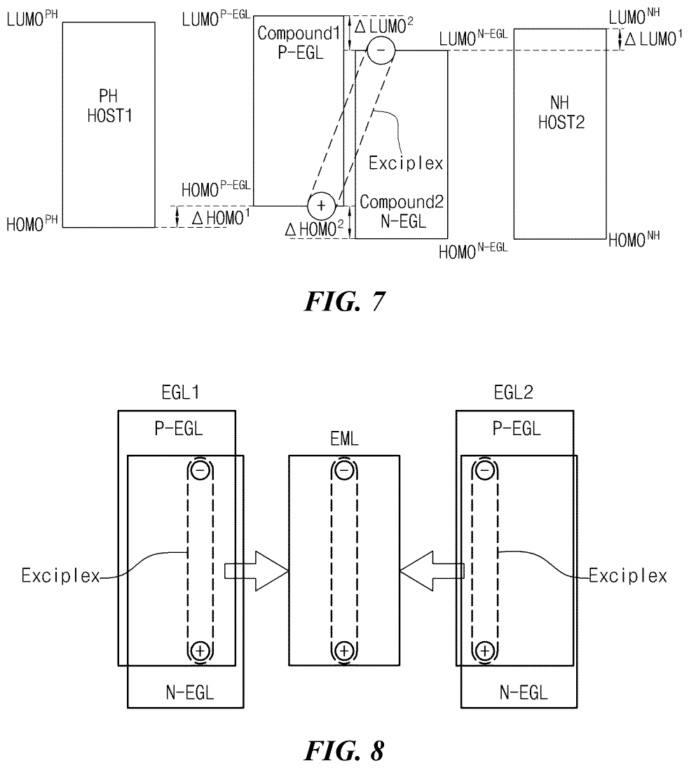

FIG. 6 is a schematic diagram of luminous mechanism in case an exciton generation layer is formed adjacently to an emitting material layer in accordance with an embodiment of the present disclosure.

As illustrated in FIGS. 3 to 6, the EML 340 includes the second host 344 with delayed fluorescent property. The second host 344 can utilize both the singlet exciton energy and the triplet exciton energy through intersystem crossing (ISC) and reverse intercrossing system (RISC) mechanism. When the EML 340 includes the emitter 346 that has proper energy levels compared to the first host 342 and/or the second host 344, the emitter 346 can absorb the exciton energies released from the first host 342 and the second host 344 so that the emitter 346 can maximize its luminous efficiency using the absorbed exciton energies.

For example, when the emitter 346 is phosphorescent material, the triplet exciton energy of the first host 342 and the second host 344 with delayed fluorescent property can be transferred to the emitter 346 through Dexter energy transfer (DET) mechanism, and the singlet exciton energy of the first host 342 and the second host 344 can be transferred to the emitter 346 through Forster resonance energy transfer (FRET) mechanism.

In addition, exciplex between the first compound 352 (352a or P-EGL) and the second compound 354 (354a or N-EGL), or between the third compound 352b (P-EGL) and the fourth compound 354b (N-EGL) are generated within the EGL (350, 350A, 350B) disposed adjacently to the EML 340. The triplet exciton energy of the exciplex generated in the EGL (350, 350A, 350B) can be transferred to the emitter 346 of the EML, which is an organic layer disposed adjacently to the EGL (350, 350A, 350B), through DET mechanism, and the singlet exciton energy of the exciplex generated in the EGL (350, 350A, 350B) can be transferred to the emitter 346 through FRET mechanism. The emitter 346 of phosphorescent material can emit utilizing both the singlet exciton and triplet exciton transferred from the host 342 and/or 344 and the exciplex.

In one embodiment, the photoluminescence wavelengths and absorbance wavelengths of the first compound 352 or 352a and/or the third compound 352b of the P-type exciton generating compound P-EGL, and the second compound 354 or 354a and/or the fourth compound 354b of the N-type exciton generating compound N-EGL can be controlled so that the EGL 350, 350A or 350B can generate exciplex and can transfer exciton energies to the EML 340 from the generated exciplex. As an example, the maximum photoluminescence wavelength of the exciton generating compound P-EGL or N-EGL can be longer wavelength than the maximum photoluminescence wavelength of the N-type generating compound N-EGL. In other words, the maximum photoluminescence wavelength of the exciton generating compound EGL and the maximum photoluminescence wavelength of the N-type exciton generating compound N-EGL can satisfy the following condition in Equation (1):

$$λmax ( EGL ) > λmax ( N - EGL ) \qquad ( 1 )$$

wherein, in Equation (1), λmax (EGL) indicates a maximum photoluminescence wavelength of exciton generating compound where P-type exciton generating compound and N-type exciton generating compouund are mixed, and λmax (N-EGL) indicates a maximum photoluminescence wavelength of N-type exciton generating compound.

In another embodiment, a difference between an onset wavelength in the absorbance (Abs) spectra of the emitter 346 and an onset wavelength in the photoluminescence (PL) spectra of the exciplex should be more than about 10 nm. As used herein, the onset wavelength is the wavelength value of the point where the X-axis (wavelength) intersects the extrapolation line in the linear region of the short-wavelength region in the Abs spectrum or PL spectrum of an organic compound. As an example, the onset wavelength can be defined as the wavelength corresponding to the shorter of two wavelengths in the Abs spectrum or PL spectrum, where the emission intensity is ⅕ to 1/15 (e.g., 1/10) of the maximum emission intensity. That is, the difference between the onset wavelength at the Abs spectrum of the emitter 346 and the onset wavelength at the PL spectrum of the exciplex can satisfy the following condition in equation (2).

$${λonset}_{A b s} ( emitter ) - {λonset}_{P L} ( E GL ) > 10 nm \qquad ( 2 )$$

wherein, in Equation (2), λonset_{Abs} (emitter) indicates an onset wavelength in the absorbance spectrum of the emitter, and λonset_{PL} (EGL) indicates an onset wavelength in the phosphorescence spectrum of the exciton generating compound where P-type exciton generating compound and N-type exciton generating compound are mixed.

In another embodiment, the emitter 346 can maximize its internal quantum efficiency by preventing the exciton energy from reversely transferring to the exciplex from the emitter 346. As an example, the onset wavelength in the PL spectrum of the emitter 346 can be longer than the onset wavelength of the PL spectrum of the exciplex. That is, the onset wavelength in the PL spectrum of the emitter 346 and the onset wavelength in the PL spectrum of the exciplex can satisfy the following condition in Equation (3).

$${λonset}_{P L} ( emitter ) > {λonset}_{P L} ( EGL ) \qquad ( 3 )$$

wherein, in Equation (3), λonset_{PL} (emitter) indicates an onset wavelength in the photoluminescence spectrum of the emitter, and λonset_{PL} (EGL) indicates an onset wavelength in the phosphorescence spectrum of the exciton generating compound where P-type exciton generating compound and N-type exciton generating compound are mixed.

In another embodiment, the lowest excited state triplet energy levels of the first compound 352 or 352a and/or the third compound 352b, the second compound 354 or 354a, and the fourth compound 354b can satisfy the following condition in Equation (4).

$${T}_{1} ( P - EGL ) > {T}_{1} ( N - EGL ) > {T}_{1} ( h ost 2 ) > {T}^{1} ( emitter ) \qquad ( 4 )$$

wherein, in Equation (4), T₁ (P-EGL) indicates a lowest excited state triplet energy level of the first compound and/or the third compound, T₁ (N-EGL) indicates a lowest excited state triplet energy level of the second compound and/or the fourth compound, T₁ (host2) indicates a lowest excited state triple energy level of the second host, and T₁ (emitter) indicates a lowest excited state triplet energy level of the emitter.

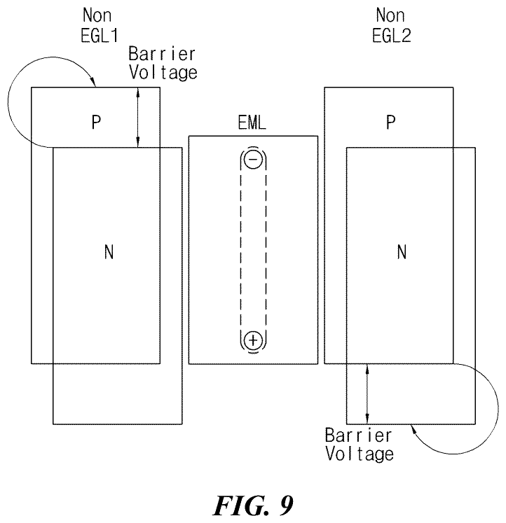

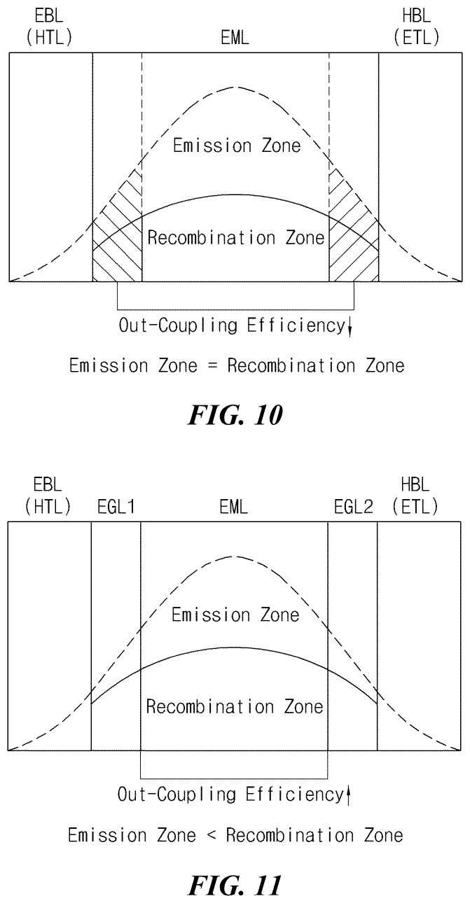

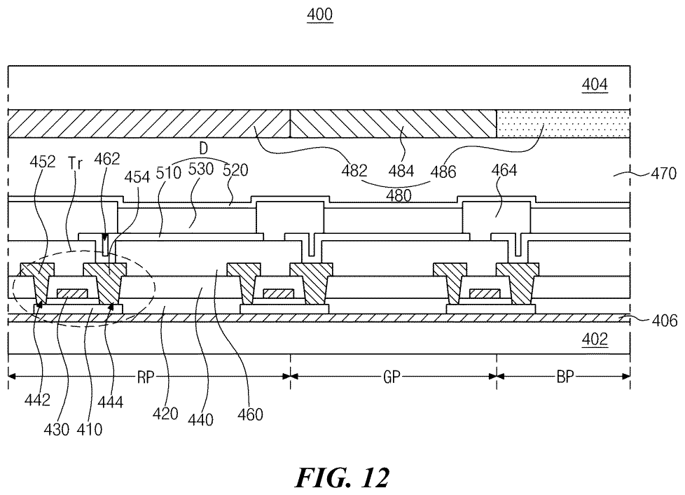

In another embodiment, HOMO energy levels and/or LUMO energy levels of the first host 342, the second host 344 and the emitter 346 in the EML 340, and the first compound 352 or 352a, the second compound 354 or 345a, the third compound 352b and the fourth compound 344b in the EGL 350, 350A or 350B are adjusted so that holes and electrons can be injected rapidly into the EML 340. FIG. 7 is a schematic diagram of HOMO energy levels and LUMO energy levels of a first compound and a second compound in an exciton generation layer as well as a first host and a second host in an emitting material layer. FIG. 8 is a schematic diagram of charge injection into an emitting material layer in case an exciton generation layer generates exciplex in accordance with an embodiment of the present disclosure. FIG. 9 is a schematic diagram of non-efficient charge injection into an emitting material layer owing to barrier voltage incase an organic layer disposed adjacently to an emitting material layer cannot generate exciplex.

As illustrated in FIG. 7, a difference or energy bandgap ΔHOMO¹ between a HOMO energy level of the first compound and/or the third compound of the P-type exciton generating compound P-EGL, and higher HOMO energy level among a HOMO energy level HOMO^{PH} of the first host PH and a HOMO energy level HOMO^{NH} of the second host NH, for example, the HOMO energy level HOMO^{PH} of the first host PH can be about 0.3 eV or less. In this case, holes can be injected rapidly into the EML from the EGL. That is, the HOMO energy level of the first compound and/or the third compound of the P-type compound P-EGL in the EGL, and the HOMO energy level of the host PH or NH in the EML can satisfy the following condition in Equation (5).

$$\vert {HOMO}^{Host - H} - H O M {O}^{P - E G L} \vert \leq 0.3 eV \qquad ( 5 )$$

wherein, in Equation (5), HOMO^{Host-H} indicates a higher HOMO energy level of a HOMO energy level of the first host and a HOMO energy level of the second host. For example, in case that HOMO energy level of the first host is higher than HOMO energy level of the second host, HOMO^{Host-H} can be the HOMO energy level of the first host, and in case that HOMO energy level of the second host is higher than HOMO energy level of the first host, HOMO^{Host-H} can be the HOMO energy level of the second host, HOMO^{PEGL} indicates a HOMO energy level of the P-type exciton generating compound.

In another embodiment, a difference of energy bandgap ΔHOMO² between a HOMO energy level HOMO^{P-EGL} of the P-type exciton generating compound P-EGL, and a HOMO energy level HOMO^{N-EGL} of the N-type exciton generating compound N-EGL in the EGL can be about 0.2 eV or more and about 0.8 eV or less. In this case, exciplex can be generated between the P-type exciton generating compound P-EGL and the N-type exciton generating compound N-EGL. That is, the HOMO energy level HOMO^{P-EGL} of the P-type exciton generating compound P-EGL and the HOMO energy level HOMO^{N-EGL} of the N-type exciton generating compound N-EGL can satisfy the following condition in Equation (6).

$$0.2 eV \leq \vert HOM {O}^{P - E G L} - H O M {O}^{N - E G L} \vert \leq 0.8 eV \qquad ( 6 )$$

In another embodiment, a difference or energy bandgap ΔLUMO¹ between a LUMO energy level of the second compound and/or the fourth compound of the N-type exciton generating compound N-EGL, and lower LUMO energy level among a LUMO energy level LUMO^{PH} of the first host PH and a LUMO energy level HOMO^{NH} of the second host NH, for example, the LUMO energy level LUMO^{NH} of the second host NH can be about 0.3 eV or less. In this case, electrons can be injected rapidly into the EML from the EGL. That is, the LUMO energy level of the second compound and/or the fourth compound of the N-type compound N-EGL in the EGL, and the LUMO energy level of the host PH or NH in the EML can satisfy the following condition in Equation (7).

$$\vert LUM {O}^{Host - L} - L U M {O}^{N - E G L} \vert \leq 0.3 eV \qquad ( 7 )$$

wherein, in Equation (7), LUMO^{Host-L} indicates a lower LUMO energy level of a LUMO energy level of the first host and a LUMO energy level of the second host. For example, in case that LUMO energy level of the first host is lower than LUMO energy level of the second host, LUMO^{Host-L} can be the LUMO energy level of the first host, and in case that LUMO energy level of the second host is lower than LUMO energy level of the first host, LUMO^{Host-L} can be the LUMO energy level of the second host, LUMO^{NEGL} indicates a LUMO energy level of the N-type exciton generating compound.

In another embodiment, a difference of energy bandgap ΔLUMO² between a LUMO energy level LUMO^{P-EGL} of the P-type exciton generating compound P-EGL, and a LUMO energy level LUMO^{N-EGL} of the N-type exciton generating compound N-EGL in the EGL can be about 0.2 eV or more and about 0.8 eV or less. In this case, exciplex can be generated between the P-type exciton generating compound P-EGL and the N-type exciton generating compound N-EGL. That is, the LUMO energy level LUMO^{P-EGL} of the P-type exciton generating compound P-EGL and the LUMO energy level LUMO^{N-EGL} of the N-type exciton generating compound N-EGL can satisfy the following condition in Equation (8).

$$0.2 eV \leq \vert LUM {O}^{P - E G L} - L U M {O}^{N - E G L} \vert \leq 0.8 eV \qquad ( 6 )$$

As illustrated in FIG. 8, in case that energy levels among the luminous materials in the EML 340, and the P-type exciton generating compounds 352, 352a and/or 354b and the N-type exciton generating compounds 354, 354a and/or 354b are adjusted, and therefore, exciplex is generated in the EGL1, EGL2, 350, 350A and/or 350B, holes and electrons can be injected rapidly into the EML 340 from the EGL1 and/or EGL2.

On the contrary, as illustrated in FIG. 9, in case exciplex is not generated in the organic layer disposed adjacently to the EML, holes and/or electrons cannot be injected efficiently into the EML owing to barrier voltage between the EGL1 and/or EGL2, and the EML.

The voltages required to inject charges to the emitting material layer from the electrode in the organic light emitting diode is proportional to bandgap of the luminous materials and charge transporting materials. The bandgap of the host 342 or 344 in the EML 340 is proportional to the lowers excited state singlet energy level of the host 342 or 344.

As described above, the EML 340 comprises the second host 344 with delayed fluorescent property. When the excited state triplet energy level required for the host is determined, the bandgap of the host is reduced as the difference between the excited singlet energy level and the excited triplet energy level becomes small. The second host 344 has very small energy bandgap ΔE_{ST} between its excited state singlet energy level and its excited state triplet energy level, and therefore, energy required for exciton recombination in the second host 344 can be lowered. As the EML 340 comprises the second host 344 with delayed fluorescent property, the voltage required for injecting charges to the EML 340 form the electrode can be lowered.

In addition, exciplex generated in the EGLs 350, 350A and/or 350B can transfer exciton energy to the emitter 346 similar to the hosts 342 and/or 346. As the exciplex can have delayed fluorescent property, energy required for exciton recombination can be reduced, and the voltage required for injecting charge to the EML 340 from the electrode can be further reduced. The OLEDs D1, D2 and/or D3 where the EML 340 comprises the second host 344 with delayed fluorescent property and at least one EGLs 350, 350A and 350B that can generate exciplex disposed adjacently to the EML 340 can lower its driving voltage and reduce its power consumption.

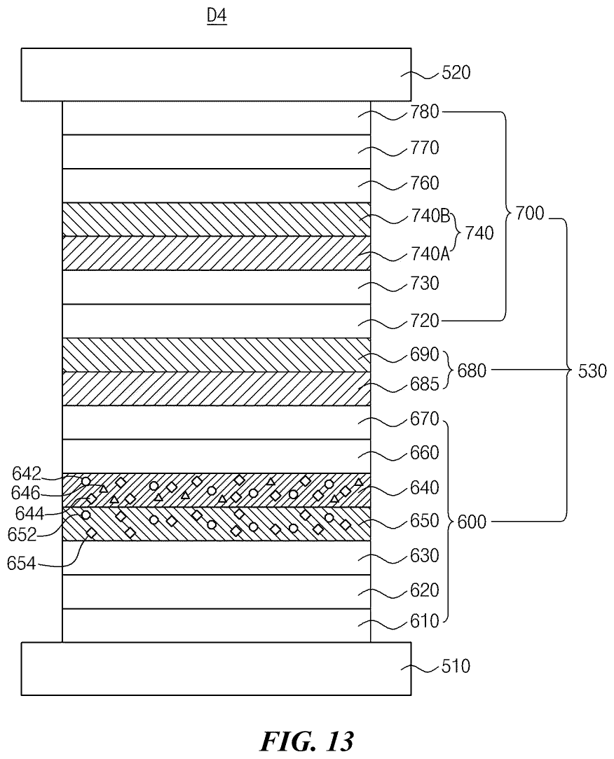

FIG. 10 is a schematic diagram of emission zone and recombination zone in case exciton generation layer is not formed adjacently to an emitting material layer. In case that the EML includes phosphorescent material as an emitter, emission zone and exciton recombination zone can be extended by increasing the thickness of the EML. As the thickness of the EML increases, the exciton recombination zone is extended to an area in the EML with lower out-coupling efficiency, and therefore, outer quantum efficiency (EQE) in the EML is decreased. In addition, as the EML become wider, the using amount of the expensive phosphorous material becomes increase, which causes material cost to be raised.

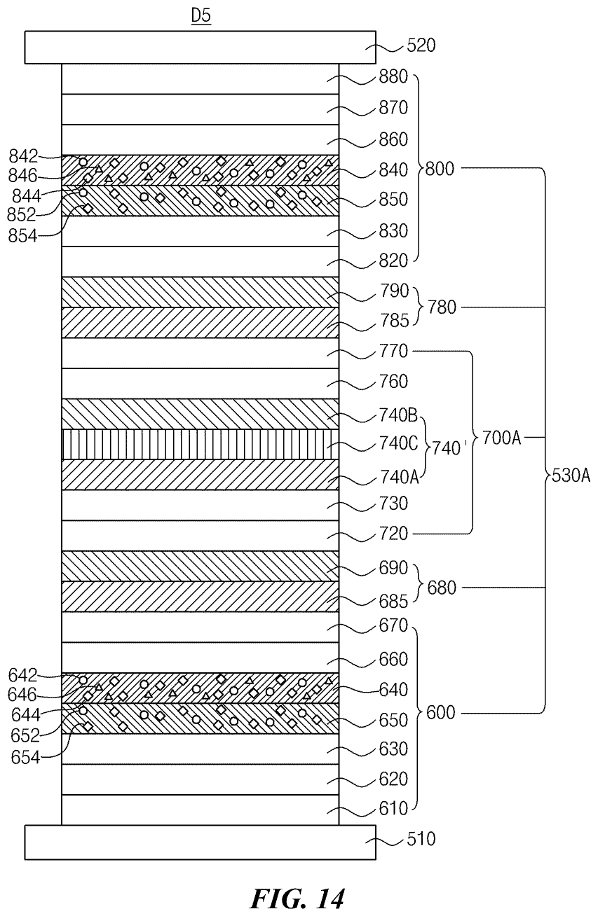

FIG. 11 is a schematic diagram of emission zone and recombination zone in case exciton generation layer is formed adjacently to an emitting material layer in accordance with one embodiment of the present disclosure. As illustrated in FIG. 11, exciton generation layers EGL1 and EGL2 are arranged adjacently to the EML. The exciton generation layers EGL1 and EGL2 are arranged at an area with lower out-coupling efficiency. In this case, the exciton recombination zone is formed within the EML and extended to the exciton generation layers EGL1 and EGL2 disposed adjacently to the EML. As the exciton recombination zone is extended, the exciton concentration or level in the EML can be reduced. As the amount of non-emitting or quenching excitons can be minimized, it is possible to minimize the degradation of the luminous materials and charge transporting materials caused by the non-emitting excitons, and therefore, the luminous lifespan of the OLEDs D1, D2 and D3 can be maximized.

On the contrary, the emissive zone is limited to an area within the EML with beneficial out-coupling efficiency. As the luminous materials emit light within the EML with beneficial out-coupling efficiency, the External quantum efficiency (EQE) of the OLEDs D1, D2 and D3 can be improved. As there is no need to extend the EML area, the using amount of phosphorous material can be reduced, and therefore, it is possible to reduce material costs.

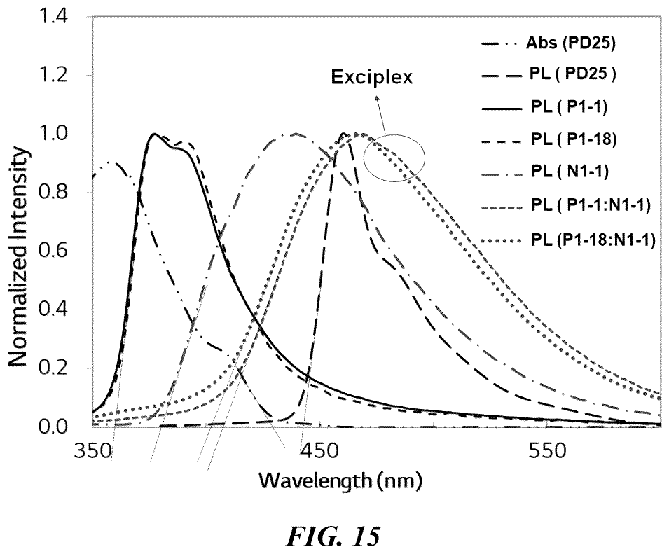

The organic light emitting device and the OLEDs D1, D2 and D3 with a single emitting part and emitting blue color light is shown in FIGS. 2 to 11. In another embodiment, an organic light emitting display device can implement full-color comprising white color. FIG. 12 illustrates a schematic cross-sectional view of an organic light emitting display device in accordance with another embodiment of the present disclosure.

As illustrated in FIG. 12, the organic light emitting display device 400 includes a first substrate 402 that defines each of a red pixel region RP, a green pixel region GP and a blue pixel region BP, a second substrate 404 facing the first substrate 402, a thin film transistor Tr on the first substrate 402, an OLED D disposed between the first and second substrates 402 and 404 and emitting white (W) light and a color filter layer 480 disposed between the OLED D and the second substrate 404.

Each of the first and second substrates 402 and 404 can include, but is not limited to, glass, flexible material and/or polymer plastics. For example, each of the first and second substrates 402 and 404 can be made of PI, PES, PEN, PET, PC and/or combinations thereof. In certain embodiments, the second substrate 404 can be omitted. The first substrate 402, on which a thin film transistor Tr and the OLED D are arranged, forms an array substrate.

A buffer layer 406 can be disposed on the first substrate 402. The thin film transistor Tr is disposed on the buffer layer 406 correspondingly to each of the red pixel region RP, the green pixel region GP and the blue pixel region BP. In certain embodiments, the buffer layer 406 can be omitted.

A semiconductor layer 410 is disposed on the buffer layer 406. The semiconductor layer 410 can be made of or include oxide semiconductor material or polycrystalline silicon.

A gate insulating layer 420 comprising an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center of the semiconductor layer 410. An interlayer insulating layer 440 comprising an insulating material, for example, inorganic insulating material such as SiOₓ (wherein 0<x≤2) or SiNₓ (wherein 0<x≤2), or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or include a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

Although not shown in FIG. 12, the gate line GL and the data line DL, which cross each other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further include the storage capacitor Cst configured to constantly keep a voltage of the gate electrode 430 for one frame.

A passivation layer 460 is disposed on the source electrode 452 and the drain electrode 454 and covers the thin film transistor Tr over the entire first substrate 402. The passivation layer 460 has a drain contact hole 462 that exposes or does not cover the drain electrode 454 of the thin film transistor Tr.

The OLED D is located on the passivation layer 460. The OLED D includes a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region RP, GP or BP can be an anode and can include a conductive material having relatively high work function value. Alternatively, a reflective electrode or a reflective layer can be disposed under the first electrode 510. For example, the reflective electrode or the reflective layer can include, but is not limited to, Ag or APC alloy.

A bank layer 464 is disposed on the passivation layer 460 in order to cover edges of the first electrode 510. The bank layer 464 exposes or does not cover a center of the first electrode 510 corresponding to each of the red pixel RP, the green pixel GP and the blue pixel BP. In certain embodiments, the bank layer 464 can be omitted.

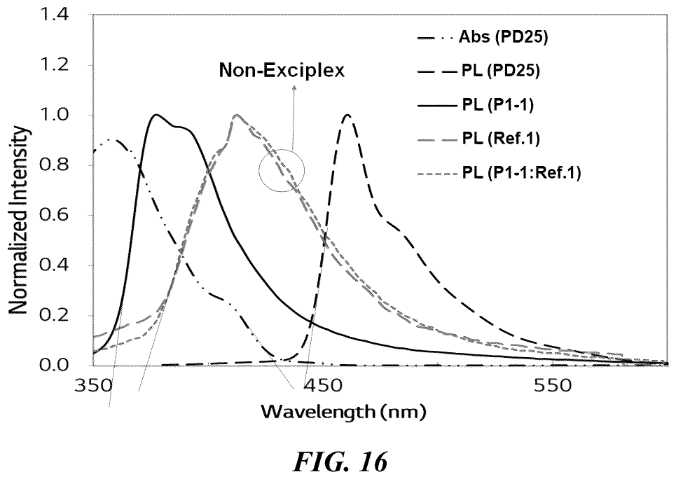

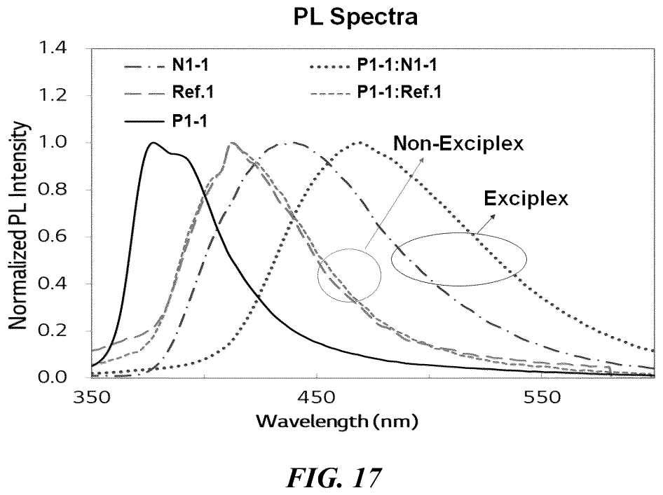

An emissive layer 530 that can include multiple emitting parts is disposed on the first electrode 510. As illustrated in FIGS. 13 and 14, the emissive layer 530 can include multiple emitting parts 600, 700, 700A, and 800 and at least one charge generation layer 680 and 780. Each of the emitting parts 600, 700, 700A and 800 includes at least one emitting material layer and can further include an HIL, an HTL, an EBL, an HBL, an ETL and/or an EIL.

The second electrode 520 can be disposed on the first substrate 402 above which the emissive layer 530 can be disposed. The second electrode 520 can be disposed over an entire display area, can include a conductive material with a relatively low work function value compared to the first electrode 510, and can be a cathode. Since the light emitted from the emissive layer 530 is incident to the color filter layer 480 through the second electrode 520 in the organic light emitting display device 400 in accordance with the second embodiment of the present disclosure, the second electrode 520 has a thin thickness so that the light can be transmitted.

The color filter layer 480 is disposed on the OLED D and includes a red color filter pattern 482, a green color filter pattern 484 and a blue color filter pattern 486 each of which is disposed correspondingly to the red pixel RP, the green pixel GP and the blue pixel BP, respectively. Although not shown in FIG. 12, the color filter layer 480 can be attached to the OLED D through an adhesive layer. Alternatively, the color filter layer 480 can be disposed directly on the OLED D.

In addition, an encapsulation film 470 can be disposed on the second electrode 520 in order to prevent or reduce outer moisture from penetrating into the OLED D. The encapsulation film 470 can have, but is not limited to, a laminated structure comprising a first inorganic insulating film, an organic insulating film and a second inorganic insulating film (170 in FIG. 5). In addition, a polarizing plate can be attached onto the second substrate 404 to reduce reflection of external light. For example, the polarizing plate can be a circular polarizing plate.

In FIG. 12, the light emitted from the OLED D is transmitted through the second electrode 520 and the color filter layer 480 is disposed on the OLED D. In this case, the organic light emitting display device 400 can be a top-emission type. Alternatively, when the organic light emitting display device 400 is a bottom-emission type, the light emitted from the OLED D is transmitted through the first electrode 510 and the color filter layer 480 can be disposed between the OLED D and the first substrate 402.

In addition, a color conversion layer may be formed or disposed between the OLED D and the color filter layer 480. The color conversion layer may include a red color conversion layer, a green color conversion layer and a blue color conversion layer each of which is disposed correspondingly to each pixel (RP, GP and BP), respectively, so as to convert the white (W) color light to each of a red, green and blue color lights, respectively. Alternatively, the organic light emitting display device 400 can comprise the color conversion layer instead of the color filter layer 480.

As described above, the white (W) color light emitted from the OLED D is transmitted through the red color filter pattern 482, the green color filter pattern 484 and the blue color filter pattern 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that can be applied into the organic light emitting display device will be described in more detail. FIG. 13 illustrates a schematic cross-sectional view of an organic light emitting diode having a tandem structure of two emitting parts.

As illustrated in FIG. 13, the organic light emitting device D4 (OLED D4) in accordance with the embodiment of the present disclosure includes first and second electrodes 510 and 520 facing each other and an emissive layer 530 disposed between the first and second electrodes 510 and 520. The emissive layer 530 includes a first emitting part 600 disposed between the first and second electrodes 510 and 520, a second emitting part 700 disposed between the first emitting part 600 and the second electrode 520 and a charge generation layer (CGL) 680 disposed between the first and second emitting parts 600 and 700.

One of the first emitting part 600 and the second emitting part 700 emits blue color light, and the other of the first emitting part emits red to green color light, so that the OLED D4 can realize white (W) emission. At least one exciton generation layer can be disposed adjacently to a blue emitting material layer of the first emitting part 600 and the second emitting part. Hereinafter, the OLED D4 where the EML1 640 emits blue color light and the EML2 740 emits red to green color light will be described in detail.

The first electrode 510 can be an anode and can include a conductive material having relatively high work function value such as TCO. For example, the first electrode 510 can include, but is not limited to, ITO, IZO, ITZO, SnO, ZnO, ICO, AZO, and/or the like. The second electrode 520 can be a cathode and can include a conductive material with a relatively low work function value. For example, the second electrode 520 can include, but is not limited to, highly reflective material such as Al, Mg, Ca, Ag, alloy thereof and/or combination thereof such as Al—Mg.

The first emitting part 600 includes a first EML (EML1) 640, and an exciton generation layer (EGL) 650 disposed between the first electrode 510 and the EML1 640, for example, between a first hole transport layer 620 or a first electron blocking layer 630 and the EML1 640. The first emitting part 600 can further include at least one of a hole injection layer (HIL) 610 disposed between the first electrode 510 and the EML1 640, a first hole transport layer (HTL1) 620 disposed between the HIL 610 and the EML1 640, and a first electron transport layer (ETL1) 670 disposed between the EML1 640 and the CGL 680. Alternatively or additionally, the first emitting part 600 can further include a first electron blocking layer (EBL1) 630 disposed between the HTL1 620 and the EML1 640 and/or a first hole blocking layer (HBL1) 660 disposed between the EML1 640 and the ETL1 670.

The second emitting part 700 includes a second EML (EML2) 740. The second emitting part 700 can further include at least one of a second hole transport layer (HTL2) 720 disposed between the CGL 680 and the EML2 740, an second electron transport layer (ETL2) 770 disposed between the second electrode 520 and the EML2 740 and an electron injection layer (EIL) 780 disposed between the second electrode 520 and the ETL2 770. Alternatively or additionally, the second emitting part 700 can further include a second electron blocking layer (EBL2) 730 disposed between the HTL2 720 and the EML2 740 and/or a second hole blocking layer (HBL2) 760 disposed between the EML2 740 and the ETL2 770.

The HIL 610 is disposed between the first electrode 510 and the HTL1 620 and improves an interface property between the inorganic first electrode 510 and the organic HTL1 620. In one exemplary embodiment, hole injecting material in the HIL 610 can include, but is not limited to, MTDATA, NATA, 1T-NATA, 2T-NATA, CuPc, TCTA, NPB (NPD), DNDPT, HAT-CN, F4-TCNQ, F6-TCNNQ, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB and/or combinations thereof. In another embodiment, the HIL 610 can include hole injection host of hole transporting material and hole injection dopant of the hole injecting material. In certain embodiments, the HIL 610 can be omitted in compliance of the OLED D2 property.

In one embodiment, hole transporting material in each of the HTL1 620 and the HTL2 720 can independently include, but is not limited to, TPD, NPB (NPD), DNTPD, CBP, poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl) biphenyl-4-amine, N-([1,1′-biphenyl]-4-yl)-9,9-dimethyl-N-(4-(9-phenyl-9H-carbazol-3-yl)phenyl)-9H-fluoren-2-amine and/or combinations thereof.

Each of the ETL1 670 and the ETL2 770 facilitates electron transportation in each of the first emitting part 600 and the second emitting part 700, respectively. As an example, each of electron transporting materials in the ETL1 670 and the ETL2 770 can independently include at least one of oxadiazole-containing compounds, triazole-containing compounds, phenanthroline-containing compounds, benzoxazole-containing compounds, benzothiazole-containing compounds, benzimidazole-containing compound and triazine-containing compounds. For example, each of the electron transporting materials in the ETL1 670 and the ETL2 770 can include, but is not limited to, Alq₃, PBD, spiro-PBD, Liq, TPBi, BAlq, Bphen, NBphen, BCP, 2-phenyl-9-(3-(2-phenyl-1,10-phenanthrolin-9-yl)phenyl)-1,10-phenanthroline, TAZ, NTAZ, TpPyPB, TmPPPyTz, PFNBr, TPQ, TSPO1, ZADN and/or combinations thereof.

The EIL 780 is disposed between the second electrode 520 and the ETL2 770, and can improve physical properties of the second electrode 520 and therefore, can enhance the lifespan of the OLED D4. In one embodiment, electron injecting material in the EIL 780 can include, but is not limited to, an alkali metal halide or an alkaline earth metal halide such as LiF, CsF, NaF, BaF₂ and the like, and/or an organometallic compound such as Liq, lithium benzoate, sodium stearate, and the like.

Each of electron blocking materials in the EBL1 630 and the EBL2 730 can independently include, but is not limited to, TCTA, tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively. In another embodiment, electron blocking material in the EBL1 630 and the EBL2 730 can independently include the carbazole-containing organic compound having the structure of Chemical Formulae 1 to 4.

Each of hole blocking materials in the HBL1 660 and the HBL2 760 can include, but is not limited to, at least one of oxadiazole-containing compounds, triazole-containing compounds, phenanthroline-containing compounds, benzoxazole-containing compounds, benzothiazole-containing compounds, benzimidazole-containing compounds, and triazine-containing compounds. For example, each of the hole blocking materials in the HBL1 660 and the HBL2 760 can independently include, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively. In another embodiment, hole blocking material in the HBL1 660 and the HBL2 760 can independently include the organic compound having the structure of Chemical Formulae 7 to 10.

The CGL 680 is disposed between the first emitting part 600 and the second emitting part 700. The CGL 680 includes an N-type CGL (N-CGL) 685 disposed adjacently to the first emitting part 600 and a P-type CGL (P-CGL) 690 disposed adjacently to the second emitting part 700. The N-CGL 685 injects electrons to the EML1 640 of the first emitting part 600 and the P-CGL 690 injects holes to the EML2 740 of the second emitting part 700.

The N-CGL 685 can be an organic layer doped with an alkali metal such as Li, Na, K and Cs and/or an alkaline earth metal such as Mg, Sr, Ba and Ra. For example, the host in the N-CGL 685 can include, but is not limited to, Bphen and MTDATA. The contents of the alkali metal or the alkaline earth metal in the N-CGL 685 can be, but is not limited to, between about 0.01 wt. % and about 30 wt. %.

The P-CGL 690 can include, but is not limited to, inorganic material selected from the group consisting of tungsten oxide (WOₓ), molybdenum oxide (MoOₓ), beryllium oxide (Be₂O₃), vanadium oxide (V₂O₅) and/or combinations thereof, and/or organic material selected from the group consisting of NPD, DNTPD, HAT-CN, F4-TCNQ, F6-TCNNQ, TPD, N,N,N′,N′-tetra naphthalenyl-benzidine (TNB), TCTA, N,N′-dioctyl-3,4,9,10-perylenedicarboximide (PTCDI-C8) and/or combinations thereof.

The EML1 640 can be a blue EML. In this case, the EML1 640 can be a blue EML, a sky-blue EML or a deep-blue EML. The EML1 640 comprises a first host 642, a second host 644 and an emitter 646. The materials and the contents of the first host 642, the second host 644 and the emitter 646 can be identical to the corresponding materials and the contents with referring to FIGS. 3 to 5.

The EGL 650 can comprise a first compound 652 of the P-type exciton generating compound and a second compound 654 of the N-type exciton generating compound. The materials and the contents of the first compound 652 and the second compound 664 in the EGL 640 can be identical to the corresponding materials and the contents with referring to FIGS. 3 to 5. In another embodiment, the EGL 650 can be disposed between the EML1 640 and the HBL 660 (FIG. 4). In another embodiment, the EGL 640 can comprise a first exciton generation layer disposed between the EBL1 630 and the EML1 640 and a second exciton generation layer disposed between the EML1 640 and the HBL1 660 (FIG. 5).

The EML2 740 can include a lower emitting material layer (lower EML, first layer) 740A disposed between the EBL2 730 and the HBL2 750 and an upper emitting material layer (upper EML, second layer) 740B disposed between the lower EML 740A and the HBL2 750. One of the first layer 740A and the second layer 740B can emit red color light and the other of the first layer 740A and the second layer 740B can emitting green color light. Hereinafter, the EML2 740 where the first layer 740A emits red color light and the second layer 740B emits green color light will be described in detail.

The first layer 740A can include a red host and a red dopant (emitter). For example, the red host can comprise a bipolar red host, or comprise a P-type red host and an N-type red host.

For example, the P-type red host can include, but is not limited to, a biscarbazole-containing organic compound, an aryl amine- or a hetero aryl amine-containing organic compound with at least one fused aromatic and/or fused hetero aromatic moiety, and/or an aryl amine- or a hetero aryl amine-containing organic compound with a spirofluorene moiety. As an example, the N-type red host can include, but is not limited to, an azine-containing organic compound, a benzimidazole-containing organic compound and/or a quinazoline-containing organic compound.

For example, the red host can comprise, but is not limited to, mCP-CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbiphenyl (CDBP), (2,7-bis(carbazole-9-yl)-9,9-dimethylfluorene (DMFL-CBP), 2,2′,7,7′-tetrakis(carbazole-9-yl)-9,9-spirofluorene (Spiro-CBP), 3,6-bis(carbazole-9-yl)-9-(2-ethyl-hexyl)-9H-carbazole (TCz1) and/or combinations thereof.

The red dopant can comprise at least one of red phosphorescent material, red fluorescent material and red delayed fluorescent material. For example, the red dopant can comprise, but is not limited to, bis[2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)₂(acac)), tris[2-(4-n-hexylphenyl)quinoline]iridium(III) (Hex-Ir(phq)₃), tris[2-phenyl-4-methylquinoline]iridium(III) (Ir(Mphq)₃), bis(2-phenylquinoline)(2,2,6,6-tetramethylheptene-3,5-dionate)iridium(III) (Ir(dpm)PQ₂), bis(phenylisoquinoline)(2,2,6,6-tetramethylheptene-3,5-dionate)iridium(III) (Ir(dpm)(piq)₂), bis(1-phenylisoquinoline)(acetylacetonate)iridium(III) (Ir(piq)₂(acac)), bis[(4-n-hexylphenyl)isoquinoline](acetylacetonate)iridium(III) (Hex-Ir(piq)₂ (acac)), tris[2-(4-n-hexylphenyl)quinoline]iridium(III) (Hex-Ir(piq)₃), tris(2-(3-methylphenyl)-7-methyl-quinolato)iridium (Ir(dmpq)₃), bis[2-(2-methylphenyl)-7-methyl-quinoline](acetylacetonate) iridium(III) (Ir(dmpq)₂(acac)), bis[2-(3,5-dimethylphenyl)-4-methyl-quinoline](acetylacetonate) iridium(III) (Ir(mphmq)₂(acac)), tris(dibenzoylmethane)mono(1,10-phenanthroline)europium(III) (Eu(dbm)₃(phen)) and/or combinations thereof.

As an example, the contents of the red host in the first layer 740A can be about 50 wt. % to about 99 wt. %, for example, about 60 wt. % to about 99 wt. % or about 80 wt. % to about 95 wt. %, and the contents of the red dopant in the first layer 740A can be about 1 wt. % to about 50 wt. %, for example, about 1 wt. % to about 40 wt. % or about 5 wt. % to about 20 wt. %, but is not limited thereto. When the first layer 740A includes both the P-type red host and the N-type red host, the P-type red host and the N-type red host can be mixed, but is not limited to, with a weight ratio of about 4:1 to about 1:4, for example about 3:1 to about 1:3.

The second layer 740B can include a green host, and a green dopant (emitter). For example, the green host can comprise a bipolar green host, or comprise a P-type green host and an N-type green host. The green host can be identical to the red host above.

The green dopant can include at least one of green phosphorescent material, green fluorescent material and green delayed fluorescent material. In one embodiment, the green dopant can include, but is not limited to, [bis(2-phenylpyridine)](pyridyl-2-benzofuro[2,3-b]pyridine) iridium, tris[2-phenylpyridine]iridium(III) (Ir(ppy)₃), fac-tris(2-phenylpyridine)iridium(III) (fac-Ir(ppy)₃), bis(2-phenylpyridine)(acetylacetonate)iridium(III) (Ir(ppy)₂(acac)), Tris[2-(p-tolyl)pyridine]iridium(III); Ir(mppy)₃), bis(2-(naphthalene-2-yl)pyridine)(acetylacetonate) iridium(III) (Ir(npy)₂acac), tris(2-phenyl-3-methyl-pyridine)iridium (Ir(3mppy)₃), fac-tris(2-(3-p-xylyl)phenyl)pyridine iridium (III) (TEG) and/or combinations thereof.

In another embodiment, the green dopant with delayed fluorescence property can include, but is not limited to, 10-(4-(4,6-diphenyl-1,3,5-triazin-2-yl)phenyl)-9,9-dimethyl-9,10-dihydroacridine (DMAC-TRZ), 10,10′-(4,4′-sulfonylbis(4,1-phenylene))bis(9,9-dimethyl-9,10-dihydroacridine (DMAC-DPS), 10-phenyl-10H, 10′H-spiro[acridine-9,9′-anthracen]-10′-one (ACRSA), 3,6-dibenzoyl-4,5-di(1-methyl-9-phenyl-9H-carbazoyl)-2-ethynylbenzonitrile (Cz-VPN), 9,9′,9″-(5-(4,6-diphenyl-1,3,5-triazin-2-yl)benzene-1,2,3-triyl)tris(9H-carbazole) (TcZTrz), 9,9′-(5-(4,6-diphenyl-1,3,5-triazin-2-yl)-1,3-phenylene)bis(9H-carbazole) (DcZTrz), 9,9′,9″,9′-((6-phenyl-1,3,5-triazin-2,4-diyl)bis(benzene-5,3,1-triyl))tetrakis(9H-carbazole) (DDczTrz), bis(4-(9H-3,9′-bicarbazol-9-yl)phenyl)methanone (CC2BP), 9′-[4-(4,6-diphenyl-1,3,5-triazin-2-yl)phenyl]-3,3″,6,6″-tetraphenyl-9,3′:6′,9″-ter-9H-carbazole (BDPCC-TPTA), 9′-[4-(4,6-diphenyl-1,3,5-triazin-2-yl)phenyl]-9,3′:6′,9″-ter-9H-carbazole (BCC-TPTA), 9,9′-(4,4′-sulfonylbis(4,1-phenylene)) bis(3,6-dimethoxy-9H-carbazole) (DMOC-DPS), 9-(4-(4,6-diphenyl-1,3,5-triazin-2-yl)phenyl)-3′,6′-diphenyl-9H-3,9′-bicarbazole (DPCC-TPTA), 10-(4,6-diphenyl-1,3,5-triazin-2-yl)-10H-phenoxazine (Phen-TRZ), 9-(4-(4,6-diphenyl-1,3,5-triazin-2-yl)phenyl)-9H-carbazole (Cab-Ph-TRZ), 1,2,3,5-Tetrakis(3,6-carbazol-9-yl)-4,6-dicyanobenzene (4CzIPN), 2,3,4,6-tetra(9H-carbazol-9-yl)-5-fluorobenzonitrile (4CZFCN), 4,5-di(9H-carbazol-9-yl) phthalonitrile (2CzPN), 10-(4-(4,6-diphenyl-1,3,5-triazin-2-yl)phenyl)-10H-spiro[acridine-9,9′-xanthene], 10-(4-(4,6-diphenyl-1,3,5-triazin-2-yl)phenyl)-10H-spiro[acridine-9,9′-fluorene] (spiroAC-TRZ) and/or combinations thereof.

As an example, the contents of the green host in the second layer 740B can be about 50 wt. % to about 99 wt. %, for example, about 60 wt. % to about 99 wt. % or about 80 wt. % to about 95 wt. %, and the contents of the green dopant in the second layer 740B can be about 1 wt. % to about 50 wt. %, for example, about 1 wt. % to about 40 wt. % or about 5 wt. % to about 20 wt. %, but is not limited thereto. When the second layer 740B includes the P-type green host and the N-type green host, the P-type green host and the N-type green host can be mixed, but is not limited to, with a weight ratio of about 4:1 to about 1:4, for example about 3:1 to about 1:3.

Optionally, the EML2 740 can further include a third layer (740C in FIG. 14) that can emit yellow-green color light disposed between the first layer 740A of the red EML and the second layer 740B of the green EML.

The OLED D4 in accordance with this embodiment has a tandem structure and includes the EML1 640 comprising the second host 644 with delayed fluorescent property and at least one EGL 650 disposed adjacently to the EML1 640 for generating exciplex. The driving voltage of the OLED D4 can be lowered and the luminous lifespan of the OLED D4 can be improved.

An OLED can have three or more emitting parts to form a tandem structure. FIG. 14 is a schematic cross-sectional view illustrating an organic light emitting diode in accordance with yet another embodiment of the present disclosure.

As illustrated in FIG. 14, the OLED D5 includes first and second electrodes 510 and 520 facing each other and an emissive layer 530A disposed between the first and second electrodes 510 and 520. The emissive layer 530A includes a first emitting part 600 disposed between the first and second electrodes 510 and 520, a second emitting part 700A disposed between the first emitting part 600 and the second electrode 520, a third emitting part 800 disposed between the second emitting part 700A and the second electrode 520, a first charge generation layer (CGL1) 680 disposed between the first and second emitting parts 600 and 700A, and a second charge generation layer (CGL2) 780 disposed between the second and third emitting parts 700A and 800.

In one embodiment, at least one of the EML1 640, the EML2 740′ and the EML3 840 can emit blue color light, and the other of the EML1 640, the EML2 740′ and the EML3 840 can emit red to green color light so that the OLED D5 can realize white (W) emission. In addition, at least one exciton generation layer can be disposed adjacently to a blue emitting material layer of the first emitting part 600, the second emitting part 700A and the third emitting part 800. Hereinafter, the OLED D5 where each of the first emitting part 600 and the third emitting part 800 emits blue color light and the second emitting part 700A emits red to color light will be described in detail.

The first emitting part 600 includes a first emitting material layer (EML1) 640, and an exciton generation layer (lower exciton generation layer, L-EGL) 650 disposed between the first electrode 510 and the EML1 640, for example, between a first hole transport layer 620 or a first electron blocking layer 630 and the EML1 640. The first emitting part 600 can further include at least one of a hole injection layer (HIL) 610 disposed between the first electrode 510 and the EML1 640, a first hole transport layer (HTL1) 620 disposed between the HIL 610 and the EML1 640, a first electron transport layer (ETL1) 670 disposed between the EML1 640 and the CGL1 680. Alternatively or additionally, the first emitting part 600 can further comprise a first electron blocking layer (EBL1) 630 disposed between the HTL1 620 and the EML1 640 and/or a first hole blocking layer (HBL1) 660 disposed between the EML1 640 and the ETL1 670.

The second emitting part 700A includes a second emitting material layer (EML2) 740′. The second emitting part 700A can further include at least one of a second hole transport layer (HTL2) 720 disposed between the CGL1 680 and the EML2 740′ and a second electron transport layer (ETL2) 770 disposed between the EML2 740′ and the CGL2 780. Alternatively or additionally, the second emitting part 700A can further include a second electron blocking layer (EBL2) 730 disposed between the HTL2 720 and the EML2 740′ and/or a second hole blocking layer (HBL2) 760 disposed between the EML2 740′ and the ETL2 770.

The third emitting part 800 includes a third emitting material layer (EML3) 840, and an exciton generation layer (upper exciton generation layer, U-EGL) 850 disposed between the CGL2 780 and the EML3 840, for example, between a third hole transport layer 820 or a third electron blocking layer 830 and the EML3 840. The third emitting part 800 can further include at least one of a third hole transport layer (HTL3) 820 disposed between the CGL2 780 and the EML3 840, a third electron transport layer (ETL3) 870 disposed between the second electrode 520 and the EML3 840 and an electron injection layer (EIL) 880 disposed between the second electrode 520 and the ETL3 870. Alternatively or additionally, the third emitting part 800 can further comprise a third electron blocking layer (EBL3) 830 disposed between the HTL3 820 and the EML3 840 and/or a third hole blocking layer (HBL3) 860 disposed between the EML3 840 and the ETL3 870.

The CGL1 680 is disposed between the first emitting part 600 and the second emitting part 700A and the CGL2 780 is disposed between the second emitting part 700A and the third emitting part 800. The CGL1 680 includes a first N-type charge generation layer (N-CGL1) 685 disposed adjacently to the first emitting part 600 and a first P-type charge generation layer (P-CGL1) 690 disposed adjacently to the second emitting part 700A. The CGL2 780 includes a second N-type charge generation layer (N-CGL2) 785 disposed adjacently to the second emitting part 700A and a second P-type charge generation layer (P-CGL2) 790 disposed adjacently to the third emitting part 800. Each of the N-CGL1 685 and the N-CGL2 785 injects electrons to the EML1 640 of the first emitting part 600 and the EML2 740′ of the second emitting part 700A, respectively, and each of the P-CGL1 690 and the P-CGL2 790 injects holes to the EML2 740′ of the second emitting part 700A and the EML3 840 of the third emitting part 800, respectively.

The materials included in the HIL 610, the HTL1 to the HTL3 620, 720 and 820, the EBL1 to the EBL3 630, 730 and 830, the HBL1 to the HBL3 650, 750 and 850, the ETL1 to the ETL3 660, 760 and 860, the EIL 870, the CGL1 680, and the CGL2 780 can be identical to the materials with referring to FIGS. 3 and 8.

Each of the EML1 640 and the EML3 840 can be independently a blue EML. In this case, each of the EML1 640 and the EML3 840 can be independently a blue EML, a sky-blue EML or a deep-blue EML. Each of the EML1 640 and the EML3 840 can independently include a first host 642 or 842, a second host 644 or 844 and an emitter 646 or 846 where ultimate light emission occurs. The materials and contents of the first host 642 or 842, the second host 644 or 844 and the emitter 646 or 846 in each of the EML1 640 and the EML3 840 can be identical to the corresponding materials and contents with referring to FIGS. 3 to 5.

The first host 642 in the EML1 640 can be identical to or different from the first host 842 in the EML3 840. The second host 644 in the EML1 640 can be identical to or different from the second host 844 in the EML3 840. The emitter 646 in the EML 640 can be identical to or different from the emitter 846 in the EML3 840.

Each of the L-EGL 650 and the U-EGL 850 can independently comprise a first compounds 652 and 852 of the P-type exciton generating compound and the second compound 654 and 845 of the N-type exciton generating compound, respectively. The first compound 652 in the L-EGL 650 can be identical to or different from the first compound 852 in the U-EGL 850. The second compound 654 in the L-EGL 650 can be identical to or different from the second compound 854 in the U-EGL 850. The materials and the contents of the first compounds 652 and 852 and the second compounds 654 and 854 in each of the L-EGL 650 and the U-EGL 860 can be identical to the corresponding materials and contents with referring to FIGS. 3 to 5.

In another embodiment, the L-EGL 650 can be disposed between the EML1 640 and the HBL1 660, and/or the U-EGL 850 can be disposed between the EML3 840 and the HBL3 860 (FIG. 4). In another embodiment, the L-EGL 650 can comprise a first exciton generation layer disposed between the EBL1 630 and the EML1 640 and a second exciton generation layer disposed between the EML1 640 and the HBL1 660, and/or the U-EGL 850 can comprise a first exciton generation layer disposed between the EBL3 830 and the EML3 840 and a second exciton generation layer disposed between the EML3 840 and the HBL3 860 (FIG. 5).

The EML2 740′ can include a lower emitting material layer (first layer) 740A disposed between the EBL2 730 and the HBL2 760, an upper emitting material layer (second layer) 740B disposed between the first layer 740A and the HBL2 760, and a middle emitting material layer (third layer) 740C disposed between the first layer 740A and the second layer 740B. One of the first layer 740A and the second layer 740B can emit red color light and the other of the first layer 740A and the second layer 740B can emit green color light. Hereinafter, the EML2 740′ where the first layer 740A emits a red color light and the second layer 740B emits a green color will be described in detail.

The first layer 740A can include a red host and a red dopant. The materials and the contents of the red host and the red dopant in the first layer 740A can be identical with referring to FIG. 13. The second layer 740B can include a green host and a green dopant. The materials and the contents of the green host and the green dopant in the second layer 740B can be identical with referring to FIG. 13.

The third layer 740C can be a yellow green EML. The third layer 740C can include a yellow green host and a yellow green dopant (emitter). For example, the yellow green host can comprise a bipolar yellow green host, or comprise a P-type yellow green host and an N-type yellow green host. For example, the yellow green host can be identical to the red host and/or the green host with referring to FIG. 13.

The yellow green dopant can include at least one of yellow green phosphorescent material, yellow green fluorescent material and yellow green delayed fluorescent material. For example, the yellow green dopant can include, but is not limited to, 5,6,11,12-Tetraphenyl naphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)), Bis(2-(9,9-diethytl-fluoren-2-yl)-1-phenyl-1H-benzo[d]imdiazolato) (acetylacetonate)iridium(III) (Ir(fbi)₂ (acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline) (picolinate)iridium(III) (FPQIrpic), Bis(4-phenylthieno[3,2-c]pyridinato-N,C2′) (acetylacetonate)iridium(III) (PO-01) and/or combinations thereof. In certain embodiments, the third layer 740C can be omitted.

When the third layer 740C includes at least one yellow green host, the contents of the yellow green host in the third layer 740C can be about 50 wt. % to about 99 wt. %, for example, about 60 wt. % to about 99 wt. % or about 80 wt. % to about 95 wt. %, and the contents of the yellow green dopant in the third layer 740C can be about 1 wt. % to about 50 wt. %, for example, about 1 wt. % to about 40 wt. % or about 5 wt. % to about 20 wt. %, but is not limited thereto. When the third layer 740C includes the P-type yellow green host and the N-type yellow green host, the P-type yellow green host and the N-type yellow green host can be mixed, but is not limited to, with a weight ratio of about 4:1 to about 1:4, for example about 3:1 to about 1:3.

The OLED D5 in accordance with this embodiment has a tandem structure and includes the EML1 640 and/or the EML3 840 each of which includes the second host 644 or 844 with delayed fluorescent property, and at least one EGLs 650 and 850 for generating exciplex disposed adjacently to each of the EML1 640 and/or the EML3 840. The OLED D5 enables its driving voltage to be lowered and its luminous lifespan to be improved with white emission.

In FIG. 14, the OLED having three emitting parts is illustrated. If necessary, an organic light emitting diode can have four or more emitting parts. As an example, when the OLED has four emitting parts, two emitting part can emit blue color light, another emitting part can emit red color light, and another emitting part can emit green color light, so that the OLED can implement white (W) emission.

### Experimental Example 1

### Measurements of Emission Spectra and Energy Levels of Compounds

The Absorbance (Abs) spectra and Photoluminescence (PL) spectra as well as HOMO energy level, LUMO energy level, lowest excited state singlet energy level S₁ and lowest excited state triplet energy level T₁ based upon those spectra for organic compounds that can be used in an exciton generation layer and an emitting material layer were measured. Particularly, Abs spectra, PL spectra and energy levels for Compound PD25 of Chemical Formula 12 of phosphorescent material (emitter) in the emitting material layer, Compounds P1-1, P1-7 and P1-18 each of which can be used as a first compound in the exciton generation layer or a first host in the emitting material layer, Compound N1-1 of Chemical Formula 6 or Reference Compound 1 (Ref. 1) below of a second compound in the exciton generation layer, and Compound N2-1 of Chemical 10 or Reference Compound 2 (Ref. 2) below of a second host in the emitting material layer were measure.

### Reference Compound

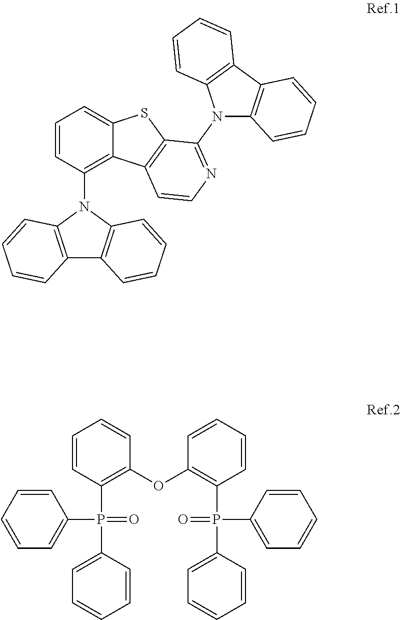 [SMILES: c1cc(-n2c3ccccc3c3ccccc32)c2c(c1)sc1c(-n3c4ccccc4c4ccccc43)nccc12 ; O=P(c1ccccc1)(c1ccccc1)c1ccccc1Oc1ccccc1P(=O)(c1ccccc1)c1ccccc1]

Bandgap was calculated from Abs spectra of each compound dissolved in toluene (10⁻⁵ M) using UV-Vis equipment. HOMO energy level and LUMO energy level were measured using cyclic voltammetry (CV). Measurement material was coated on a Working electrode (glassy carbon electrode), the electrode was immersed in electrolyte solution (0.1 M tetrabutylammonium perchlorate), oxidation potential was measured, and then HOMO energy level was calculated form onset curve obtained from the oxidation potential (reference electrode Ag/AgCl, counter electrode Pt wire). LUMO energy level was calculated from the HOMO energy level obtained by CV measurement and the bandgap measured using UV-Vis equipment (LUMO energy level=bandgap−HOMO energy level).

Lowest excited state singlet energy level S₁ and lowest excited state triplet energy level T₁ of the Compounds were measured photoluminescence (PL) equipment (measurement after photo excitation gn 1 ms delay). Onset wavelength λonset based on the 1^{st} peak in the low temperature (77K) fluorescence (Fl) spectrum for each compound dissolved in toluene solvent (10⁻⁵ M), and the lowest excited state singlet energy level S₁ was calculated by 1240/λonset (onset wavelength of Fl spectrum). Onset wavelength λonset based on the 1^{st} peak in the low temperature (77K) phosphorescence (PL) spectrum for each compound dissolved in toluene solvent (10⁻⁵ M), and the lowest excited state triplet energy level T₁ was calculated by 1240/λonset (onset wavelength of Ph spectrum). ΔE_{ST} was calculated by S₁-T₁. In addition, maximum photoluminescence wavelength (λₘₐₓ, nm), onset wavelength of PL spectrum (λonset_{PL}, nm) and onset wavelength of Abs spectrum (λonset_{Abs}, nm) for each compound were measured. The following Tables 1 and 2, and FIGS. 15 to 17 indicate or illustrate measurement results.

TABLE 1
Energy levels of Compounds

| Compound | LUMO (eV) | HOMO (eV) | S₁ (eV) | T₁ (eV) | ΔE_{ST} (eV) |
|---|---|---|---|---|---|
| PD25 | −2.6 | −5.5 | — | 2.77 | — |
| P1-1 | −2.0 | −5.4 | — | 2.99 | — |
| P1-7 | −2.1 | −5.5 | 3.13 | 2.95 | 0.18 |
| P1-18 | −2.0 | −5.4 | — | 2.99 | — |
| N1-1 | −2.75 | −6.0 | — | 2.98 | — |
| Ref. 1 | −2.4 | −5.7 | 3.20 | 2.95 | 0.35 |
| N2-1 | −2.5 | −5.6 | 3.13 | 2.90 | 0.23 |
| N2-26 | −2.6 | −5.6 | 3.07 | 2.90 | 0.17 |
| Ref. 2 | −2.0 | −6.1 | 4.10 | 3.01 | 1.09 |

TABLE 2
Maximum Photoluminescence Wavelength
and Onset Wavelength of Compounds

| Compound | λmax (nm) | λonset_{PL} (nm) | λonset_{Abs.} (nm) |
|---|---|---|---|
| PD25 | 461 | 442 | 430 |
| P1-1 | 377 | 358 | — |
| P1-18 | 378 | 359 | — |
| N1-1 | 446 | 380 | — |
| Ref. 1 | 412 | 372 | — |
| P1-1:N1-1 | 469 | 408 | — |
| P1-18:N1-1 | 466 | 402 | — |
| P1-1:Ref. 1 | 412 | 375 | — |

As indicated in Tables 1-2 and FIGS. 15-17, as exciplex was generated between Compounds P1-1 and Compound NL-1, and Compound P1-18 and Compound N1-1, new photoluminescence spectra were observed at longer wavelength compared to the photoluminescence wavelengths of Compounds P1-1, P1-18 and N1-1. On the contrary, no exciplex was generated between Compound P1-1 and Reference Compound Ref. 1, no new photoluminescence spectrum was observed at longer wavelength compared to the photoluminescence wavelength of those compounds.

### Example 1 (Ex.1)

### Fabrication of OLED

An organic light emitting diode where an exciton generation layer between an electron blocking layer and an emitting material layer and between an emitting material layer and a hole blocking layer was introduced. A glass substrate onto which ITO (50 nm) was coated as a thin film was ultrasonically washed with isopropyl alcohol, acetone and methanol and dried in oven at 100° C. The prepared ITO transparent electrode was transferred to a vacuum chamber for depositing emissive layer. Subsequently, an emissive layer and a cathode were deposited by evaporation from a heating boat under about 5-7×10⁻⁷ Torr with setting a deposition rate 1 Å/s as the following order:

A hole injection layer (HIL, NPB (95 wt. %), F4-TCNQ (5 wt. %), 10 nm thickness); a hole transport layer (HTL, NPB, 50 nm thickness); an electron blocking layer (EBL, Compound P1-1, 5 nm thickness); a first exciton generation layer (EGL1, Compound P1-1 (50 wt. %), Compound N1-1 (50 wt. %), 5 nm thickness); an emitting material layer (EML, Compound P1-1 (56 wt. %), Compound N2-1 (28 wt. %), Compound PD25 (emitter, 16 wt. %), 20 nm thickness); a second exciton generation layer (EGL2, Compound P1-1 (50 wt. %), Compound N1-1 (50 wt. %), 5 nm thickness); a hole blocking layer (HBL, Compound N2-1, 5 nm thickness); an electron transport layer (ETL, 2-phenyl-9-(3-(2-phenyl-1,10-phenanthrolin-9-yl)phenyl)-1,10-phenanthroline, 30 nm thickness); electron injection layer (EIL, LiF, 1 nm thickness); and cathode (A1, 100 nm thickness).

The fabricated organic light emitting diode was encapsulated with glass and transferred to a dry box from the deposition chamber to form a film, and encapsulated using UV cured epoxy and moisture getter. The structures of materials of hole injecting material, hole transporting material, electron blocking material, hosts, hole blocking material and electron transporting material are illustrated in the following:

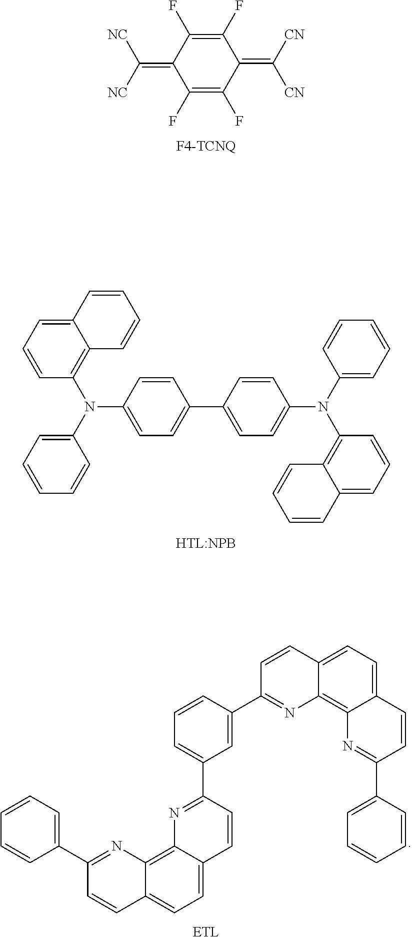 [SMILES: N#CC(C#N)=c1c(F)c(F)c(=C(C#N)C#N)c(F)c1F ; c1ccc(N(c2ccc(-c3ccc(N(c4ccccc4)c4cccc5ccccc45)cc3)cc2)c2cccc3ccccc23)cc1 ; c1ccc(-c2ccc3ccc4ccc(-c5cccc(-c6ccc7ccc8ccc(-c9ccccc9)nc8c7n6)c5)nc4c3n2)cc1]

### Example 2 (Ex. 2)

### Fabrication of OLED

An OLED was fabricated using the same procedure and the same materials as Example 1, except that the second exciton generation layer (EGL2) between the EML and HBL was not formed and the thickness of ETL was modified to 35 nm.

### Example 3 (Ex. 3)

### Fabrication of OLED

An OLED was fabricated using the same procedure and the same materials as Example 1, except that the first exciton generation layer (EGL1) between the EBL and EML was not formed and the thickness of HTL was modified to 55 nm.

### Example 4 (Ex. 4)

### Fabrication of OLED

An OLED was fabricated using the same procedure and the same materials as Example 1, except that an EBL was not formed and the thickness of HTL was modified to 55 nm.

### Example 5 (Ex. 5)

### Fabrication of OLED

An OLED was fabricated using the same procedure and the same materials as Example 1, except that an HBL was not formed and the thickness of ETL was modified to 35 nm.

### Example 6 (Ex. 6)

### Fabrication of OLED

An OLED was fabricated using the same procedure and the same materials as Example 1, except that each of the thickness of the HTL, EML and ETL was modified to 45 nm, 30 nm and 25 nm, respectively.

### Example 7 (Ex. 7)

### Fabrication of OLED

An OLED was fabricated using the same procedure and the same materials as Example 6, except that a second exciton generation layer (EGL2) between the EML and HBL was not formed and the thickness of ETL was modified to 30 nm.

### Example 8 (Ex. 8)

### Fabrication of OLED

An OLED was fabricated using the same procedure and the same materials as Example 6, except that a first exciton generation layer (EGL1) between the EBL and EML was not formed and the thickness of HTL was modified to 50 nm.

### Comparative Example 1 (Ref. 1)

### Fabrication of OLED

An OLED was fabricated using the same procedure and the same materials as Example 1, except that a first exciton generation layer (EGL1) between the EBL and the EML and a second exciton generation layer (EGL2) between the EML and the HLB were not formed, and each of the thicknesses of HTL and ETL was modified to 55 nm and 35 nm, respectively.

### Comparative Example 2 (Ref. 2)

### Fabrication of OLED

An OLED was fabricated using the same procedure and the same materials as Example 6, except that a first exciton generation layer (EGL1) between the EBL and the EML and a second exciton generation layer (EGL2) between the EML and the HLB were not formed, and each of the thicknesses of HTL and ETL was modified to 50 nm and 30 nm, respectively.

### Experimental Example 2

### Measurement of Luminous Properties of OLEDS

Each of the OLEDs, having 9 mm² of emission area, fabricated in Examples 1 to 8 and Comparative Examples 1 to 2 was connected to an external power source and then luminous properties for all the OLEDs were evaluated using a constant current source (KEITHLEY) and a photometer PR650 at room temperature. In particular, driving voltage (V, relative value), external quantum efficiency (EQE, relative value), and time period from initial luminance to 95% luminescence (LT₉₅, %, relative value) as luminous lifespan were measured at a current density 5 mA/cm². The measurement results are illustrated in the following Table 3.

TABLE 3
Luminous Properties of OLED

| | V | EQE | LT₉₅ |
|---|---|---|---|
| Sample | (Relative, %) | (Relative, %) | (Relative, %) |
| Ref. 1^{a} | 100 | 100 | 100 |
| Ex. 1^{a} | 102 | 97 | 152 |
| Ex. 2^{a} | 100 | 98 | 146 |
| Ex. 3^{a} | 102 | 98 | 141 |
| Ex. 4^{a} | 100 | 94 | 122 |
| Ex. 5^{a} | 102 | 91 | 103 |
| Ref. 2^{b} | 107 | 92 | 155 |
| Ex. 6^{b} | 109 | 90 | 188 |
| Ex. 7^{b} | 108 | 91 | 178 |
| Ex. 8^{b} | 110 | 90 | 174 |

^{a}EML thickness 20 nm;
^{b}EML thickness 30 nm

### Example 9 (Ex. 9)

### Fabrication of OLED

An OLED was fabricated using the same procedure and the same materials as Example 1, except that Compound N2-26 of Chemical Formula 10 instead of Compound N2-1 as the second host in the EML and the material in the HBL was used.

### Example 10 (Ex. 10)

### Fabrication of OLED

An OLED was fabricated using the same procedure and the same materials as Example 9, except that the second exciton generation layer (EGL2) between the EML and HBL was not formed and the thickness of ETL was modified to 35 nm.

### Example 11 (Ex. 11)

### Fabrication of OLED

An OLED was fabricated using the same procedure and the same materials as Example 9, except that the first exciton generation layer (EGL1) between the EBL and EML was not formed and the thickness of HTL was modified to 55 nm.

### Comparative Example 3 (Ref. 3)

### Fabrication of OLED

An OLED was fabricated using the same procedure and the same materials as Example 9, except that a first exciton generation layer (EGL1) between the EBL and the EML and a second exciton generation layer (EGL2) between the EML and the HLB were not formed, and each of the thicknesses of HTL and ETL was modified to 55 nm and 35 nm, respectively.

### Experimental Example 3

### Measurement of Luminous Properties of OLEDs

Luminous properties for each of the OLEDs fabricated in Examples 9 to 11 and Comparative Example 3 were measured as Experimental Example 2. The measurement results are illustrated in the following Table 4.

TABLE 3
Luminous Properties of OLED

| | V | EQE | LT₉₅ |
|---|---|---|---|
| Sample | (Relative, %) | (Relative, %) | (Relative, %) |
| Ref. 3 | 100 | 100 | 100 |
| Ex. 9 | 103 | 98 | 143 |
| Ex. 10 | 101 | 99 | 140 |
| Ex. 11 | 102 | 98 | 112 |

### Example 12 (Ex. 12)

### Fabrication of OLED

An OLED was fabricated using the same procedure and the same materials as Example 1, except that the first compound and the second compound in the EGL1 and the EGL2 were modified to Compound P1-18 (67 wt. %) of Chemical Formula 2 and Compound N1-1 (33 wt. %).

### Example 13 (Ex. 13)

### Fabrication of OLED

An OLED was fabricated using the same procedure and the same materials as Example 1, except that the first compound and the second compound in the EGL1 were modified to Compound P1-18 (67 wt. %) of Chemical Formula 2 and Compound N1-1 (33 wt. %).

### Experimental Example 4

### Measurement of Luminous Properties of OLEDs

Luminous properties for each of the OLEDs fabricated in Examples 1 and 12 to 13 and Comparative Example 1 were measured as Experimental Example 2. The measurement results are illustrated in the following Table 5.

TABLE 5
Luminous Properties of OLED

| | V | EQE | LT₉₅ |
|---|---|---|---|
| Sample | (Relative, %) | (Relative, %) | (Relative, %) |
| Ref. 1 | 100 | 100 | 100 |
| Ex. 1 | 102 | 97 | 152 |
| Ex. 12 | 105 | 98 | 157 |
| Ex. 13 | 104 | 98 | 167 |

### Example 14 (Ex. 14)

### Fabrication of OLED

An OLED was fabricated using the same procedure and the same materials as Example 1, except that Compound P1-7 of Chemical Formula 2 instead of Compound P1-1 as the first host in the EML was used.

### Example 15 (Ex. 15)

### Fabrication of OLED

An OLED was fabricated using the same procedure and the same materials as Example 14, except that the second exciton generation layer (EGL2) between the EML and HBL was not formed and the thickness of ETL was modified to 35 nm.

### Example 16 (Ex. 16)

### Fabrication of OLED

An OLED was fabricated using the same procedure and the same materials as Example 14, except that the first exciton generation layer (EGL1) between the EBL and EML was not formed and the thickness of HTL was modified to 55 nm.

### Comparative Example 4 (Ref. 4)

### Fabrication of OLED

An OLED was fabricated using the same procedure and the same materials as Example 14, except that a first exciton generation layer (EGL1) between the EBL and the EML and a second exciton generation layer (EGL2) between the EML and the HLB were not formed, and each of the thicknesses of HTL and ETL was modified to 55 nm and 35 nm, respectively.

### Experimental Example 5

### Measurement of Luminous Properties of OLEDs

Luminous properties for each of the OLEDs fabricated in Examples 14 to 16 and Comparative Example 5 were measured as Experimental Example 2. The measurement results are illustrated in the following Table 6.

TABLE 6
Luminous Properties of OLED

| | V | EQE | LT₉₅ |
|---|---|---|---|
| Sample | (Relative, %) | (Relative, %) | (Relative, %) |
| Ref. 4 | 100 | 100 | 100 |
| Ex. 14 | 103 | 98 | 136 |
| Ex. 15 | 101 | 98 | 137 |
| Ex. 16 | 103 | 97 | 106 |

### Comparative Example 5 (Ref. 5)

### Fabrication of OLED

An OLED was fabricated using the same procedure and the same materials as Example 1, except that Reference Compound Ref. 2 instead of Compound N2-1 as the second host in the EML and the material in the HBL was used.

### Experimental Example 6

### Measurement of Luminous Properties of OLEDs

Luminous properties for each of the OLEDs fabricated in Example 1 and Comparative Examples 1 and 5 was measured as Experimental Example 2. The measurement results are illustrated in the following Table 7.

TABLE 7
Luminous Properties of OLED

| | V | EQE | LT₉₅ |
|---|---|---|---|
| Sample | (Relative, %) | (Relative, %) | (Relative, %) |
| Ref. 1 | 100 | 100 | 100 |
| Ex. 1^{a} | 102 | 97 | 152 |
| Ref. 5^{b} | 172 | 98 | 34 |

^{a}second host has delayed fluorescent property
^{b}second host has no delayed fluorescent property

### Comparative Example 6 (Ref. 6)

### Fabrication of OLED

An OLED was fabricated using the same procedure and the same materials as Example 14, except that Compound P1-1 (50 wt. %) and the Reference Compound Ref. 1 (50 wt. %), that cannot generate exciplex, as the materials in the EGL1 and EGL2 were used.

### Experimental Example 7

### Measurement of Luminous Properties of OLEDs

Luminous properties for each of the OLEDs fabricated in Example 1, and Comparative Examples 1 and 6 was measured as Experimental Example 2. The measurement results are illustrated in the following Table 8.

TABLE 8
Luminous Properties of OLED

| | V | EQE | LT₉₅ |
|---|---|---|---|
| Sample | (Relative, %) | (Relative, %) | (Relative, %) |
| Ref. 1 | 100 | 100 | 100 |
| Ex. 1^{a} | 102 | 97 | 152 |
| Ref. 6^{b} | 107 | 91 | 76 |

^{a}exciplex generation
^{b}exciplex no generation

### Comparative Example 7 (Ref. 7)

### Fabrication of OLED

An OLED was fabricated using the same procedure and the same materials as Example 14, except that Compound P1-1 (50 wt. %) and the Reference Compound Ref. 1 (50 wt. %), that cannot generate exciplex, as the materials in the EGL1 and EGL2, and the Reference Compound Ref. 2, that has no delayed fluorescent property, as the second host in the EML were used.

### Experimental Example 8

### Measurement of Luminous Properties of OLEDs

Luminous properties for each of the OLEDs fabricated in Example 1, and Comparative Examples 1 and 7 was measured as Experimental Example 2. The measurement results are illustrated in the following Table 9.

TABLE 9
Luminous Properties of OLED

| | V | EQE | LT₉₅ |
|---|---|---|---|
| Sample | (Relative, %) | (Relative, %) | (Relative, %) |
| Ref. 1 | 100 | 100 | 100 |
| Ex. 1^{a} | 102 | 97 | 152 |
| Ref. 7^{b} | 188 | 97 | 21 |

^{a}exciplex generation, second host has delayed fluorescent property
^{b}exciplex no generation, second host has no delayed fluorescent property

As indicated in Tables 2 to 9, compared to the OLEDs fabricated in Comparative Examples where exciton generation layer was not formed or non-exciton generation layer consisting of compounds that cannot generate exciplex was formed adjacently to the EML with the same thickness, in the OLEDs fabricated in Examples where exciton generation layer consisting of compounds that generate exciplex was formed adjacently to the EML with the same thickness, the luminous lifespan was improved significantly as the exciton recombination zone was extended. Even in case the thickness of the EML was reduced, the luminous lifespan was kept at equivalent level and luminous efficiency was rather increased. It was possible to implement an OLED with high efficiency and longer lifespan with decrease of the amount of expensive phosphorous material. In addition, compared to the OLEDs fabricated in Comparative Examples where non delayed fluorescent material as the second host in the EML was used, in the OLEDs fabricated in Examples where delayed fluorescent material as the second host in the EML was used, the luminous efficiency was kept at equivalent level, and the driving voltage was reduced significantly and the luminous lifespan was increased significantly.

It was confirmed that an OLED with lowering or maintaining its driving voltage, maintaining its luminous efficiency and improving its luminous lifespan significantly can be fabricated by forming at least one exciton generation layer comprising materials that can generate exciplex disposed adjacently to the emitting material layer.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light emitting diode, comprising:
a first electrode;
a second electrode facing the first electrode; and
an emissive layer disposed between the first electrode and the second electrode,
wherein the emissive layer comprises:
an emitting material layer; and
a first exciton generation layer disposed between the first layer and the emitting material layer or between the emitting material layer and the second electrode,
wherein the first exciton generation layer comprise a first compound and a second compound,
wherein the emitting material layer comprise a first host, a second host and an emitter,
wherein each of the first compound and the first host independently comprises an organic compound having the following structure of Chemical Formula 1 or Chemical Formula 3,
wherein the second compound comprise an organic compound having the following structure of Chemical Formula 5, and
wherein the second host comprise an organic compound having the following structure of Chemical Formula 7: 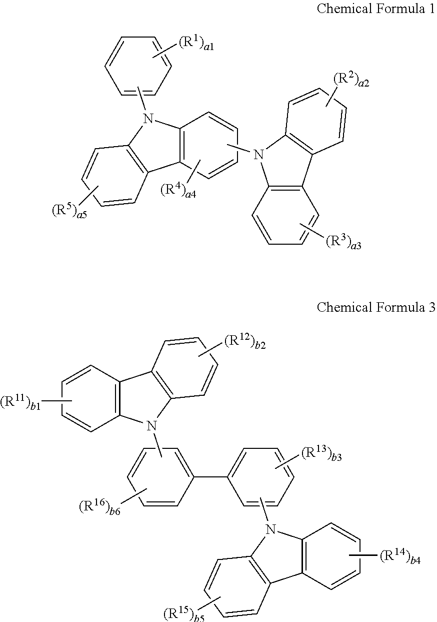
wherein, in Chemical Formulae 1 and 3,
each of R¹ to R⁵ and R¹¹ to R¹⁶ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, an unsubstituted or substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group or an unsubstituted or substituted C₂-C₃₀ tri-hetero aryl methyl group, where each R¹ is identical to or different from each other when a1 is 2, 3, 4 or 5, each R² is identical to or different from each other when a2 is 2, 3 or 4, each R³ is identical to or different from each other when a3 is 2, 3 or 4, each R⁴ is identical to or different from each other when a4 is 2 or 3, each R⁵ is identical to different from each other when a5 is 2, 3 or 4, each R¹¹ is identical to or different from each other when b1 is 2, 3 or 4, each R¹² is identical to or different from each other when b2 is 2, 3 or 4, each R¹³ is identical to or different from each other when b3 is 2, 3 or 4, each R¹⁴ is identical to or different from each other when b4 is 2, 3 or 4, each R¹⁵ is identical to different from each other when b5 is 2, 3 or 4, and each R¹⁶ is identical to different from each other when b6 is 2, 3 or 4;
a1 is 0, 1, 2, 3, 4 or 5;
each of a2, a3, a5, b1, b2, b3, b4, b5 and b6 is independently 0, 1, 2, 3 or 4; and
a4 is 0, 1, 2 or 3, 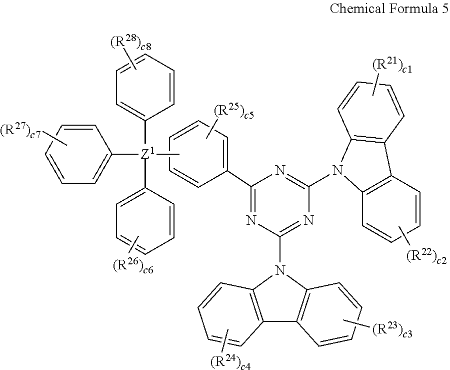
wherein, in Chemical Formula 5,
Z¹ is C, Si or Ge;
each of R²¹ to R²⁸ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group or an unsubstituted or substituted C₂-C₃₀ tri-hetero aryl methyl group, where each R²¹ is identical to or different from each other when c1 is 2, 3 or 4, each R²² is identical to or different from each other when c2 is 2, 3 or 4, each R²³ is identical to or different from each other when c3 is 2, 3 or 4, each R²⁴ is identical to or different from each other when c4 is 2, 3 or 4, each R²⁵ is identical to different from each other when c5 is 2, 3 or 4, each R²⁶ is identical to or different from each other when c6 is 2, 3, 4 or 5, each R²⁷ is identical to or different from each other when c7 is 2, 3, 4 or 5, and each R²⁸ is identical to or different from each other when c8 is 2, 3, 4 or 5;
each of c1, c2, c3, c4 and c5 is independently 0, 1, 2, 3 or 4; and
each of c6, c7 and c8 is independently 0, 1, 2, 3, 4 or 5, 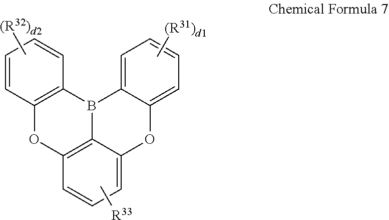
wherein, in Chemical Formula 7,
each of R³¹ to R³³ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, an unsubstituted or substituted C₂-C₃₀ tri-hetero aryl methyl group, or has the following structure of Chemical Formula 8, where each R³¹ is identical to or different from each other when d1 is 2, 3 or 4, and each R³² is identical to or different from each other when d2 is 2, 3 or 4, where a polycyclic ring comprising boron and oxygen has at least one hetero aryl group having the following structure of Chemical Formula 9: 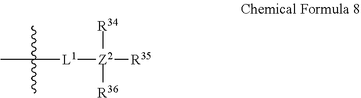
wherein, in Chemical Formula 8,
Z² is C, Si or Ge;
each of R³⁴ to R³⁶ is independently an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group or an unsubstituted or substituted C₂-C₃₀ hetero aryloxy group;
L¹ is an unsubstituted or substituted C₆-C₃₀ arylene group or an unsubstituted or substituted C₂-C₃₀ hetero arylene group; and
wavy line indicates a link position, 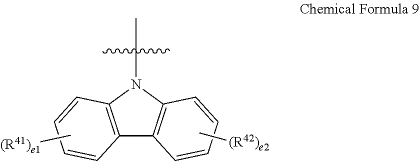
wherein, in Chemical Formula 9,
each of R⁴¹ and R⁴² is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, an unsubstituted or substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, or an unsubstituted or substituted C₂-C₃₀ tri-hetero aryl methyl group, where each R⁴¹ is identical to or different from each other when e1 is 2, 3 or 4, and each R⁴² is identical to or different from each other when e2 is 2, 3 or 4, or
optionally,
two adjacent R⁴¹ and/or two adjacent R⁴² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring; and
wavy line indicates a link position.

2. The organic light emitting diode of claim 1, wherein the emissive layer further comprises a second exciton generation layer disposed oppositely to the first exciton generation layer with respect to the emitting material layer.

3. The organic light emitting diode of claim 2, wherein the second exciton generation layer comprises a third compound and a fourth compound, wherein the third compound comprises the organic compound having the structure of Chemical Formula 1 or Chemical Formula 3, and wherein the fourth compound comprises the organic compound having the structure of Chemical Formula 5.

4. The organic light emitting diode of claim 1, wherein a difference between a highest occupied molecular orbital (HOMO) energy level of the first compound and a HOMO energy level of the second compound is about 0.2 eV or more and about 0.8 eV or less.

5. The organic light emitting diode of claim 1, wherein a difference between a highest occupied molecular orbital (HOMO) energy level of the first compound, and a higher HOMO energy level among a HOMO energy level of the first host and a HOMO energy level of the second host is about 0.3 eV or less.

6. The organic light emitting diode of claim 1, wherein a difference between a lowest unoccupied molecular orbital (LUMO) energy level of the first compound and a LUMO energy level of the second compound is about 0.2 eV or more and about 0.8 eV or less.

7. The organic light emitting diode of claim 1, wherein a difference between a lowest unoccupied molecular orbital (LUMO) energy level of the second compound, and a higher LUMO energy level among a LUMO energy level of the first host and a LUMO energy level of the second host is about 0.3 eV or less.

8. The organic light emitting diode of claim 1, wherein a lowest excited state triplet energy level of the first compound is higher than a lowest excited state triplet energy level of the second compound, and wherein the lowest excited state triplet energy level of the second compound is higher than a lowest excited state triplet energy level of the second host.

9. The organic light emitting diode of claim 1, wherein each of the first compound and the first host having the structure of Chemical Formula 1 is independently at least one of:

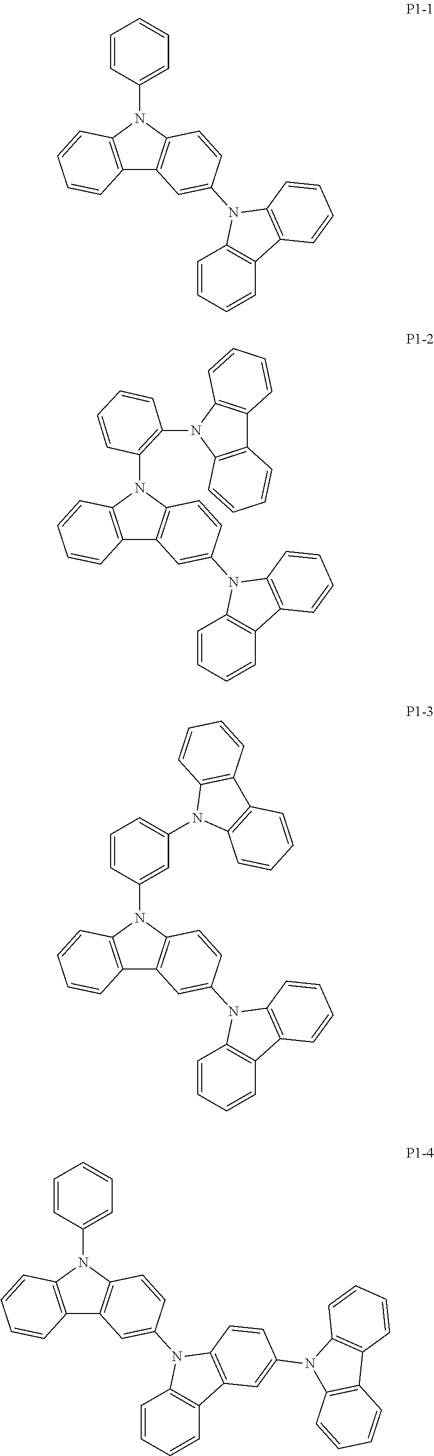

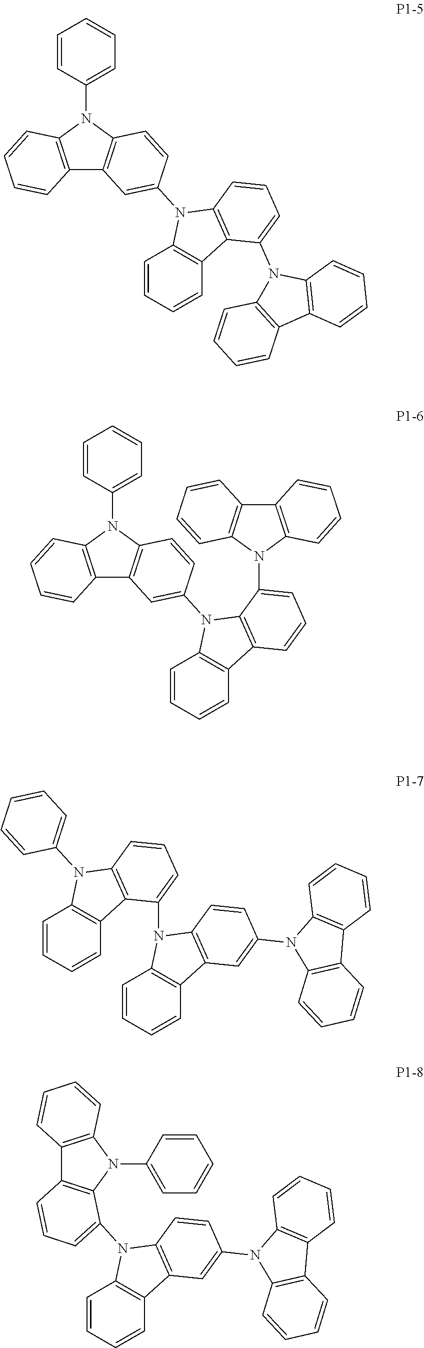 [SMILES: c1ccc(-n2c3ccccc3c3cc(-n4c5ccccc5c5c(-n6c7ccccc7c7ccccc76)cccc54)ccc32)cc1 ; c1ccc(-n2c3ccccc3c3cc(-n4c5ccccc5c5cccc(-n6c7ccccc7c7ccccc76)c54)ccc32)cc1 ; c1ccc(-n2c3ccccc3c3c(-n4c5ccccc5c5cc(-n6c7ccccc7c7ccccc76)ccc54)cccc32)cc1 ; c1ccc(-n2c3ccccc3c3cccc(-n4c5ccccc5c5cc(-n6c7ccccc7c7ccccc76)ccc54)c32)cc1]

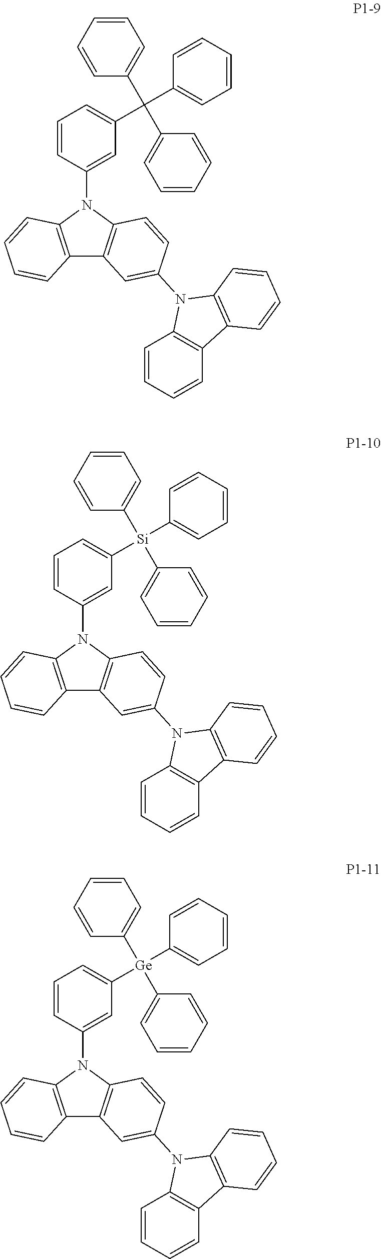

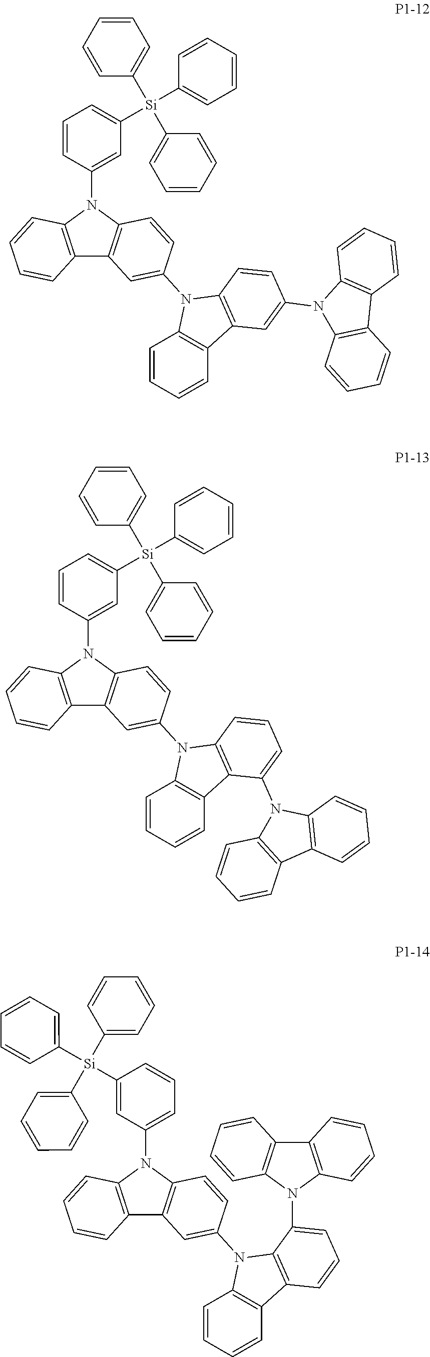 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2cccc(-n3c4ccccc4c4cc(-n5c6ccccc6c6c(-n7c8ccccc8c8ccccc87)cccc65)ccc43)c2)cc1 ; c1ccc([Si](c2ccccc2)(c2ccccc2)c2cccc(-n3c4ccccc4c4cc(-n5c6ccccc6c6cccc(-n7c8ccccc8c8ccccc87)c65)ccc43)c2)cc1]

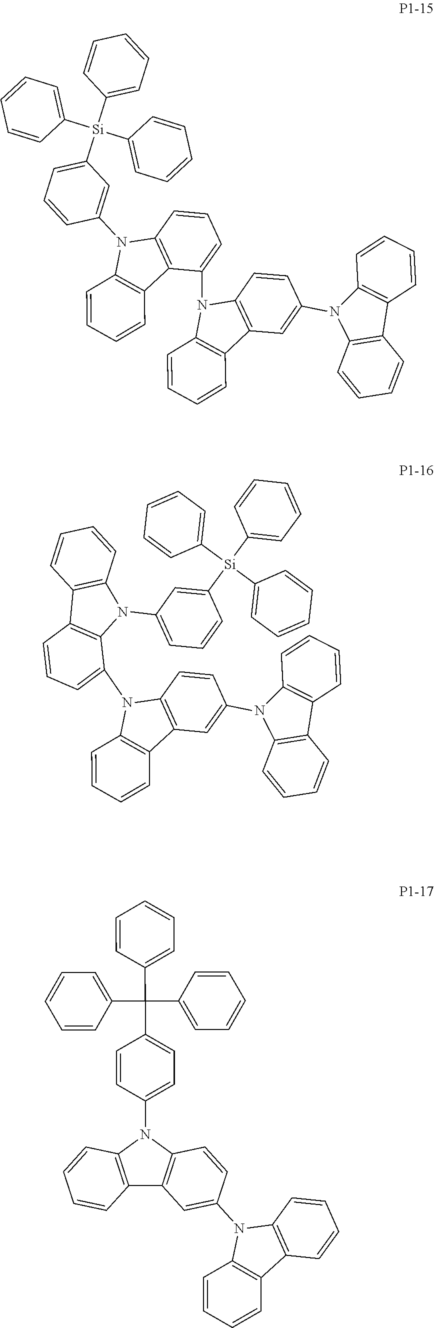 [SMILES: c1ccc([Si](c2ccccc2)(c2ccccc2)c2cccc(-n3c4ccccc4c4c(-n5c6ccccc6c6cc(-n7c8ccccc8c8ccccc87)ccc65)cccc43)c2)cc1 ; c1ccc([Si](c2ccccc2)(c2ccccc2)c2cccc(-n3c4ccccc4c4cccc(-n5c6ccccc6c6cc(-n7c8ccccc8c8ccccc87)ccc65)c43)c2)cc1 ; c1ccc(C(c2ccccc2)(c2ccccc2)c2ccc(-n3c4ccccc4c4cc(-n5c6ccccc6c6ccccc65)ccc43)cc2)cc1]

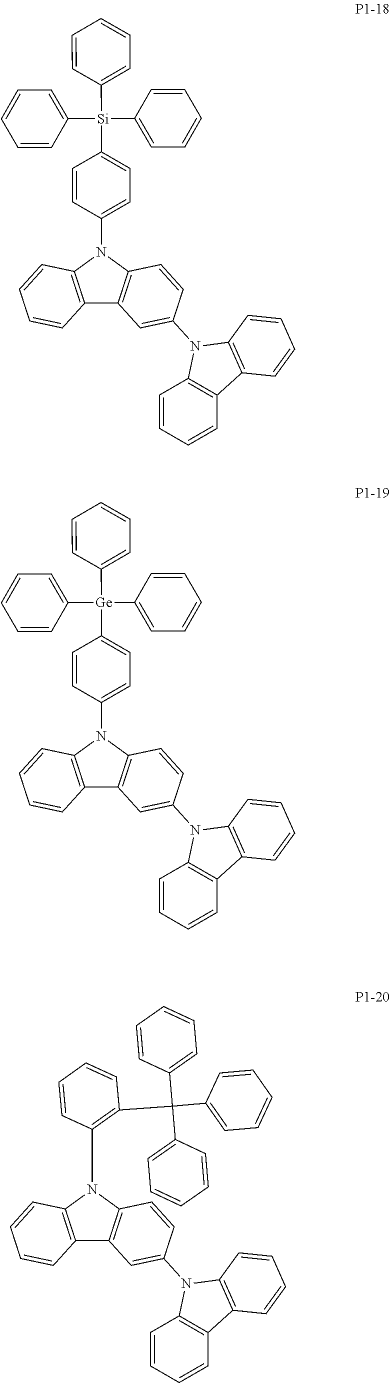

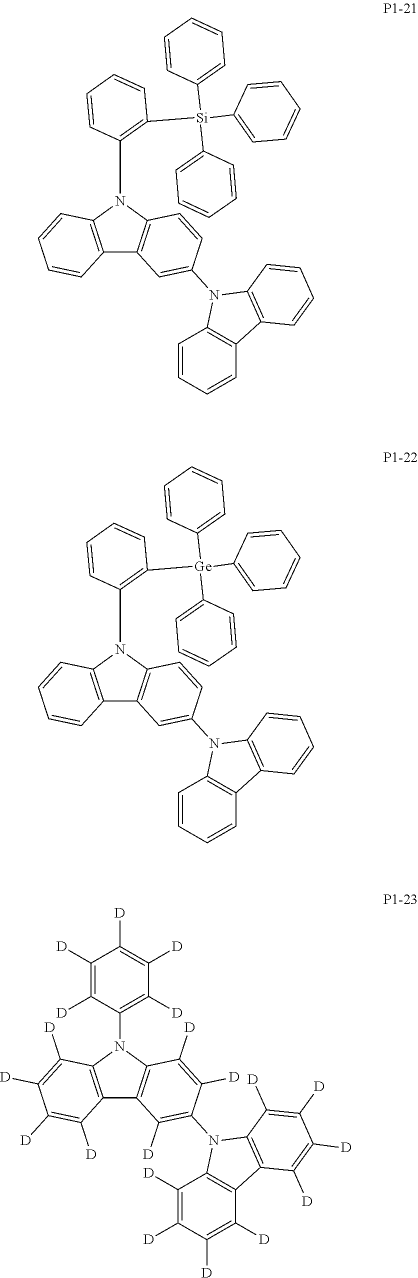

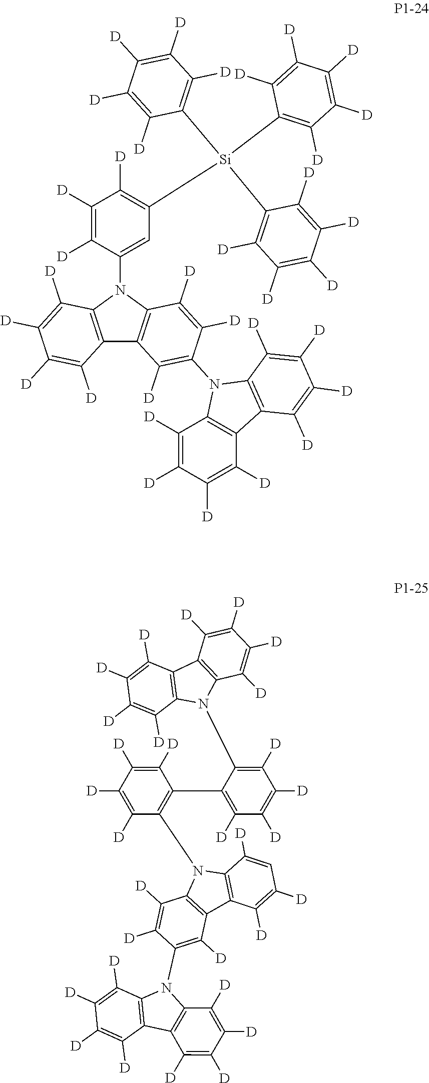

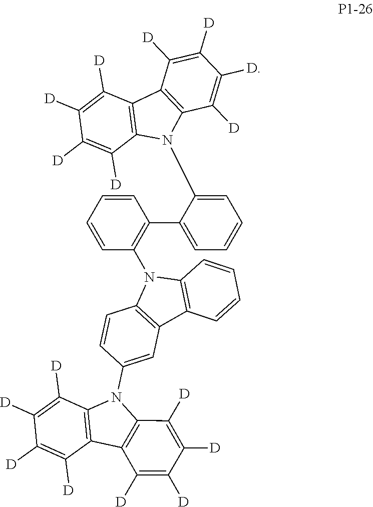

10. The organic light emitting diode of claim 1, wherein each of the first compound and the first host having the structure of Chemical Formula 3 is independently at least one of:

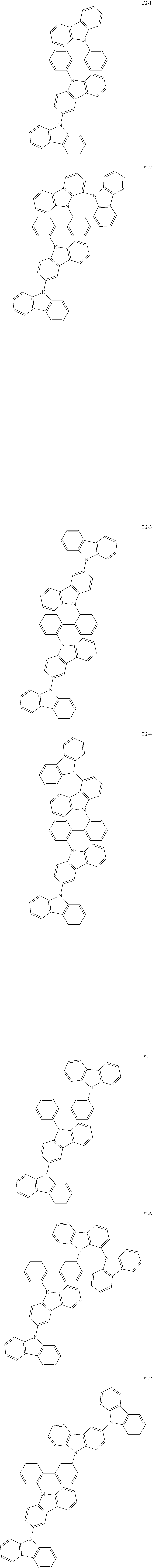

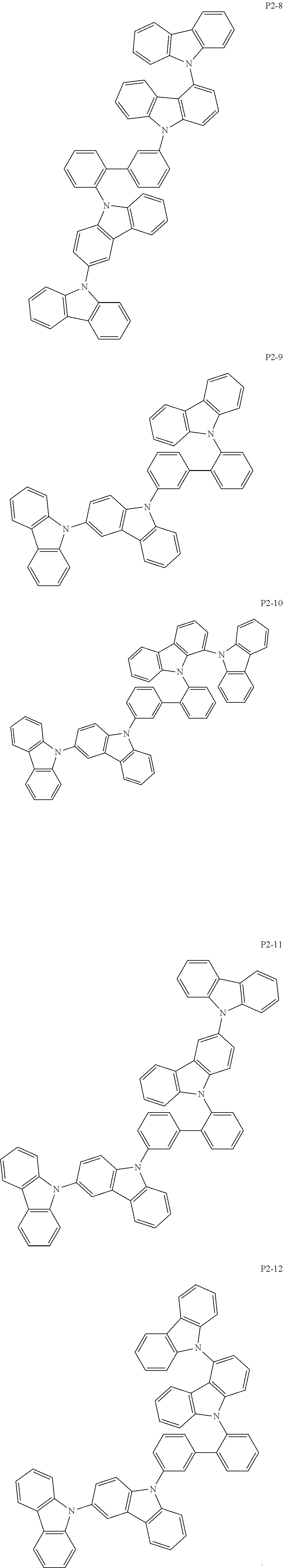

11. The organic light emitting diode of claim 1, wherein the second compound is at least one of:

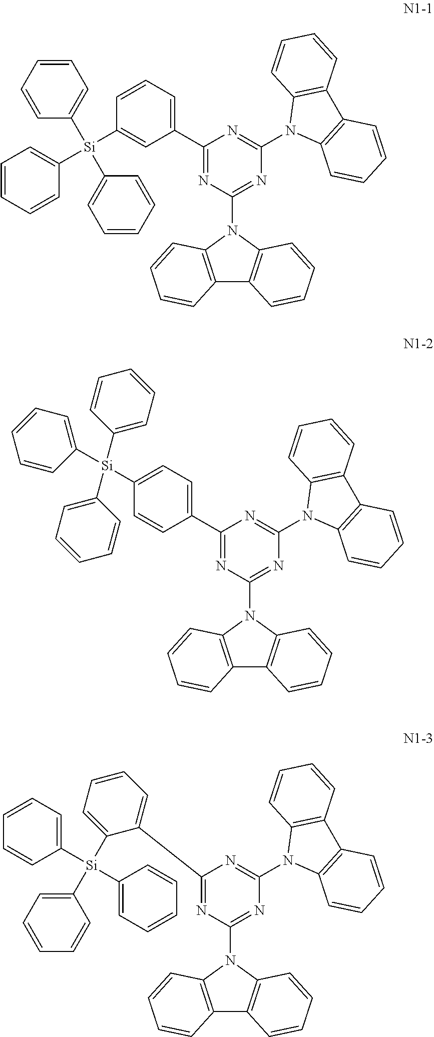 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1 ; c1ccc([Si](c2ccccc2)(c2ccccc2)c2ccccc2-c2nc(-n3c4ccccc4c4ccccc43)nc(-n3c4ccccc4c4ccccc43)n2)cc1]

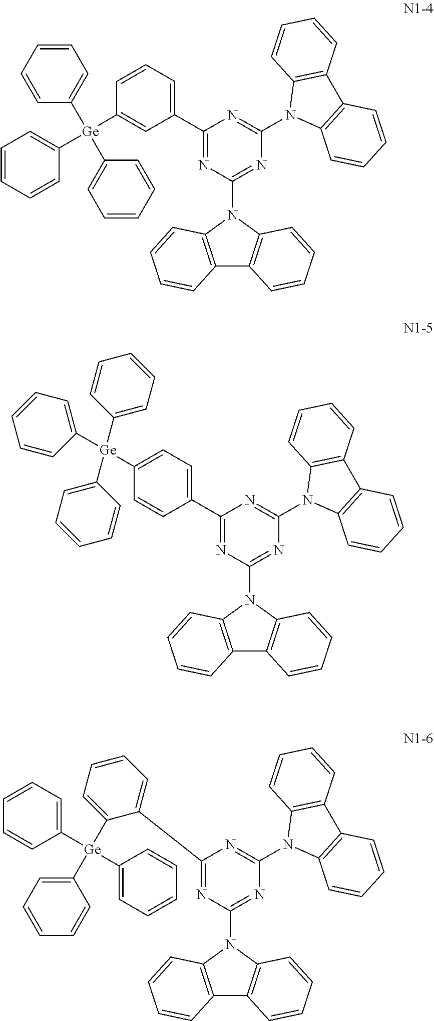

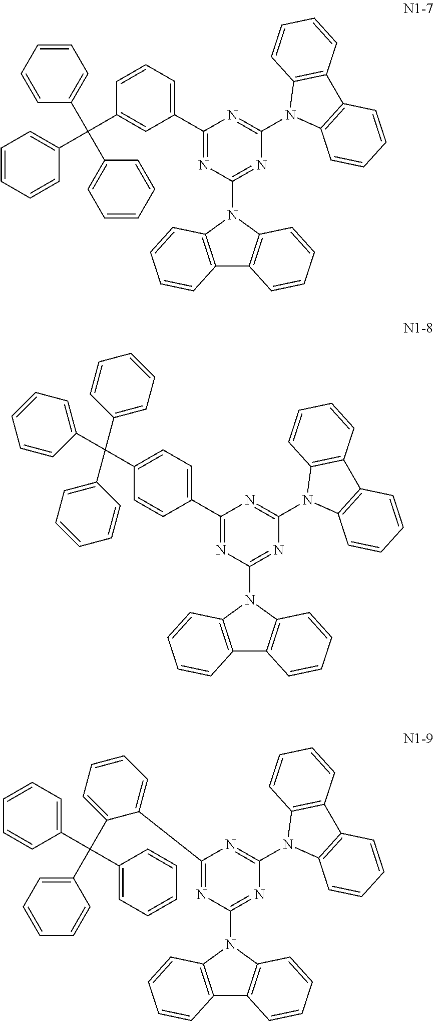 [SMILES: c1ccc(C(c2ccccc2)(c2ccccc2)c2cccc(-c3nc(-n4c5ccccc5c5ccccc54)nc(-n4c5ccccc5c5ccccc54)n3)c2)cc1 ; c1ccc(C(c2ccccc2)(c2ccccc2)c2ccc(-c3nc(-n4c5ccccc5c5ccccc54)nc(-n4c5ccccc5c5ccccc54)n3)cc2)cc1 ; c1ccc(C(c2ccccc2)(c2ccccc2)c2ccccc2-c2nc(-n3c4ccccc4c4ccccc43)nc(-n3c4ccccc4c4ccccc43)n2)cc1]

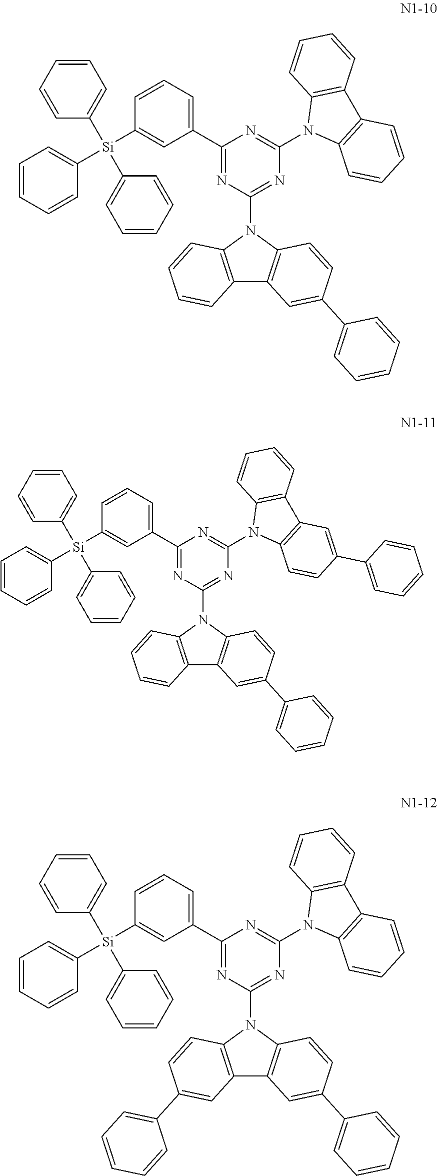 [SMILES: c1ccc(-c2ccc3c(c2)c2ccccc2n3-c2nc(-c3cccc([Si](c4ccccc4)(c4ccccc4)c4ccccc4)c3)nc(-n3c4ccccc4c4ccccc43)n2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4cc(-c5ccccc5)ccc43)n2)cc1 ; c1ccc(-c2ccc3c(c2)c2cc(-c4ccccc4)ccc2n3-c2nc(-c3cccc([Si](c4ccccc4)(c4ccccc4)c4ccccc4)c3)nc(-n3c4ccccc4c4ccccc43)n2)cc1]

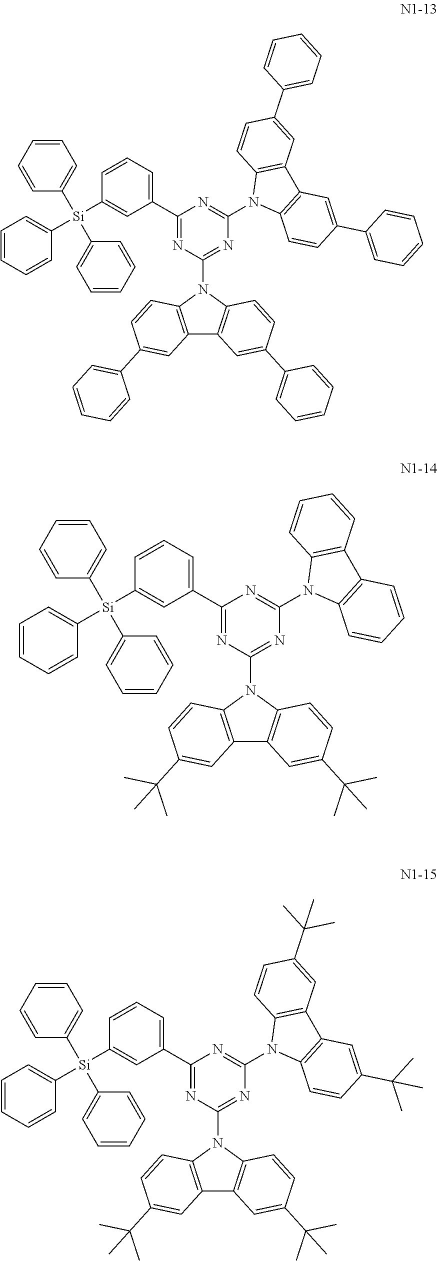 [SMILES: c1ccc(-c2ccc3c(c2)c2cc(-c4ccccc4)ccc2n3-c2nc(-c3cccc([Si](c4ccccc4)(c4ccccc4)c4ccccc4)c3)nc(-n3c4ccc(-c5ccccc5)cc4c4cc(-c5ccccc5)ccc43)n2)cc1 ; CC(C)(C)c1ccc2c(c1)c1cc(C(C)(C)C)ccc1n2-c1nc(-c2cccc([Si](c3ccccc3)(c3ccccc3)c3ccccc3)c2)nc(-n2c3ccccc3c3ccccc32)n1 ; CC(C)(C)c1ccc2c(c1)c1cc(C(C)(C)C)ccc1n2-c1nc(-c2cccc([Si](c3ccccc3)(c3ccccc3)c3ccccc3)c2)nc(-n2c3ccc(C(C)(C)C)cc3c3cc(C(C)(C)C)ccc32)n1]

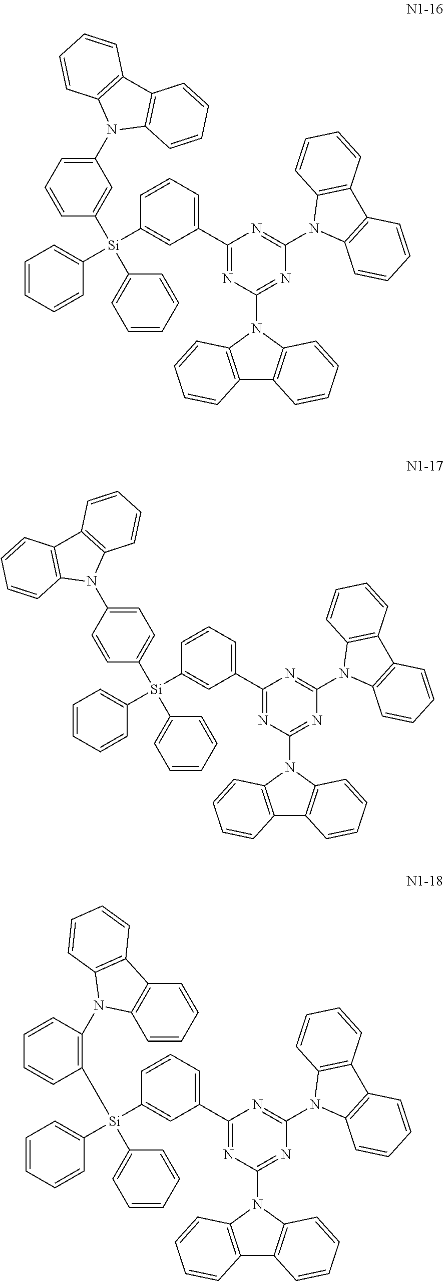 [SMILES: c1ccc([Si](c2ccccc2)(c2cccc(-c3nc(-n4c5ccccc5c5ccccc54)nc(-n4c5ccccc5c5ccccc54)n3)c2)c2cccc(-n3c4ccccc4c4ccccc43)c2)cc1 ; c1ccc([Si](c2ccccc2)(c2ccc(-n3c4ccccc4c4ccccc43)cc2)c2cccc(-c3nc(-n4c5ccccc5c5ccccc54)nc(-n4c5ccccc5c5ccccc54)n3)c2)cc1 ; c1ccc([Si](c2ccccc2)(c2cccc(-c3nc(-n4c5ccccc5c5ccccc54)nc(-n4c5ccccc5c5ccccc54)n3)c2)c2ccccc2-n2c3ccccc3c3ccccc32)cc1]

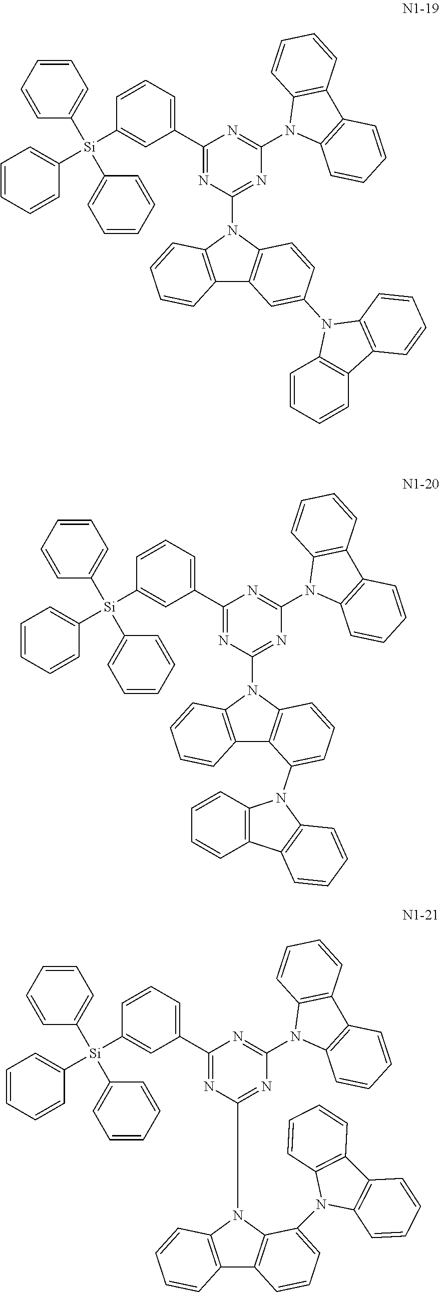 [SMILES: c1ccc([Si](c2ccccc2)(c2ccccc2)c2cccc(-c3nc(-n4c5ccccc5c5ccccc54)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5ccccc54)nc(-n4c5ccccc5c5c(-n6c7ccccc7c7ccccc76)cccc54)n3)c2)cc1 ; c1ccc([Si](c2ccccc2)(c2ccccc2)c2cccc(-c3nc(-n4c5ccccc5c5ccccc54)nc(-n4c5ccccc5c5cccc(-n6c7ccccc7c7ccccc76)c54)n3)c2)cc1]

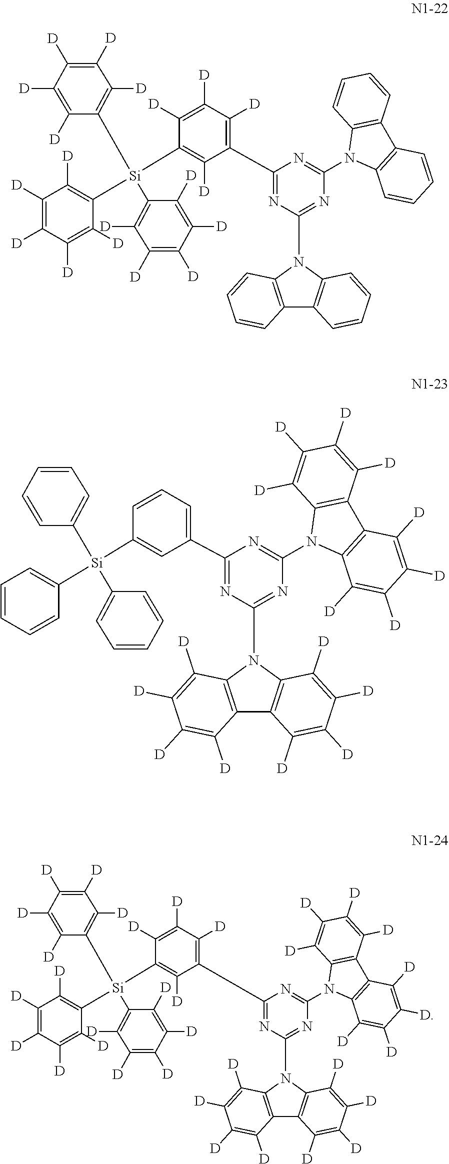

12. The organic light emitting diode of claim 1, wherein the second host is at least one of:

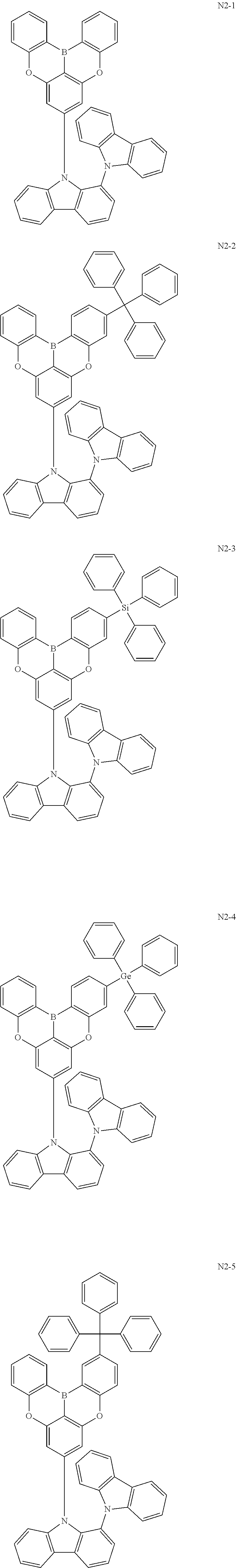

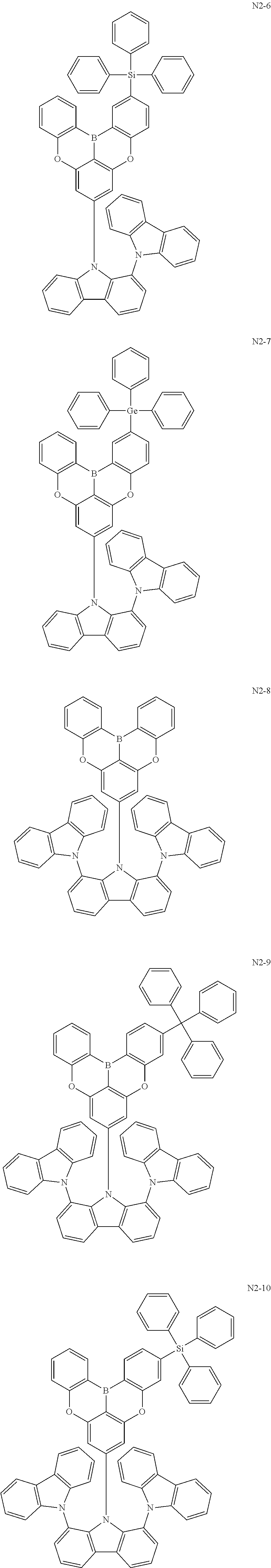

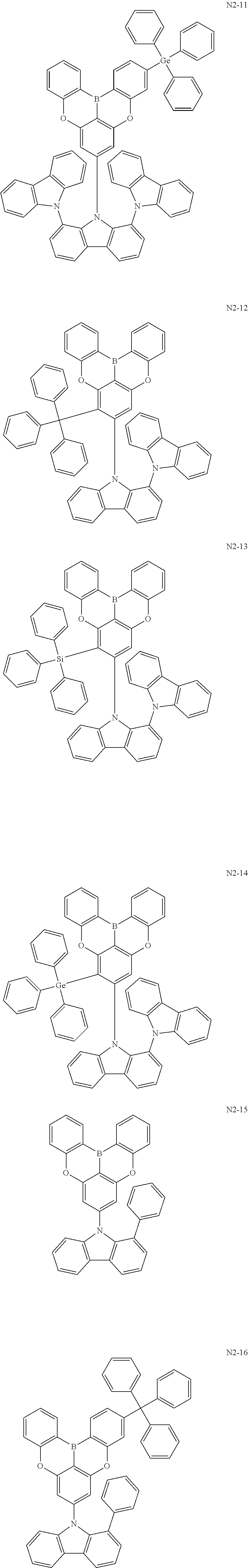

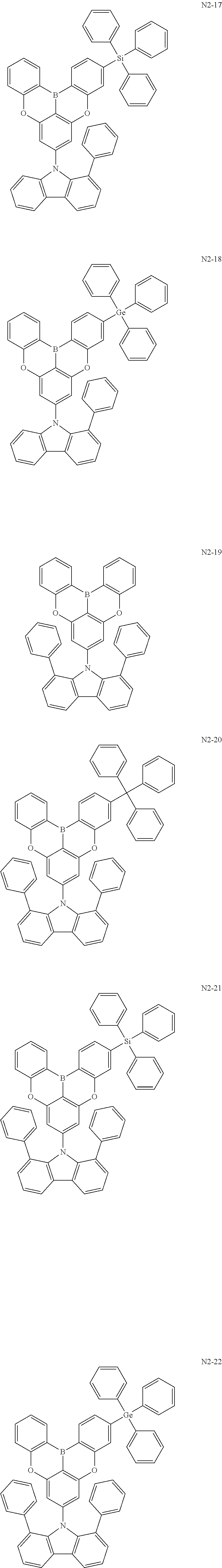

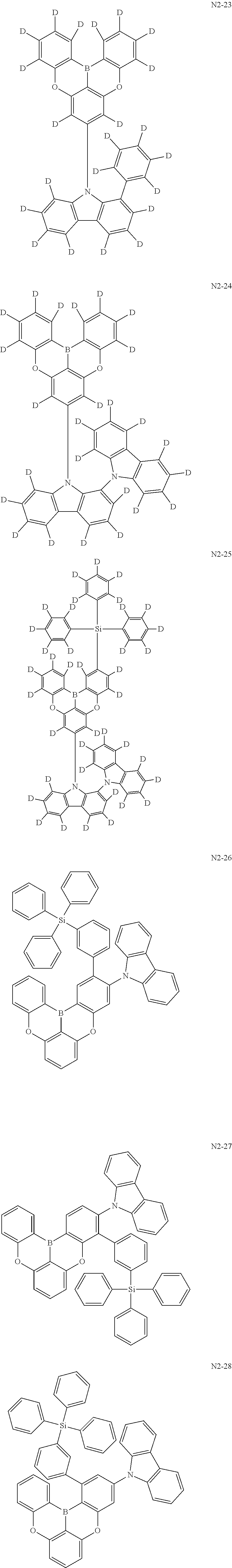

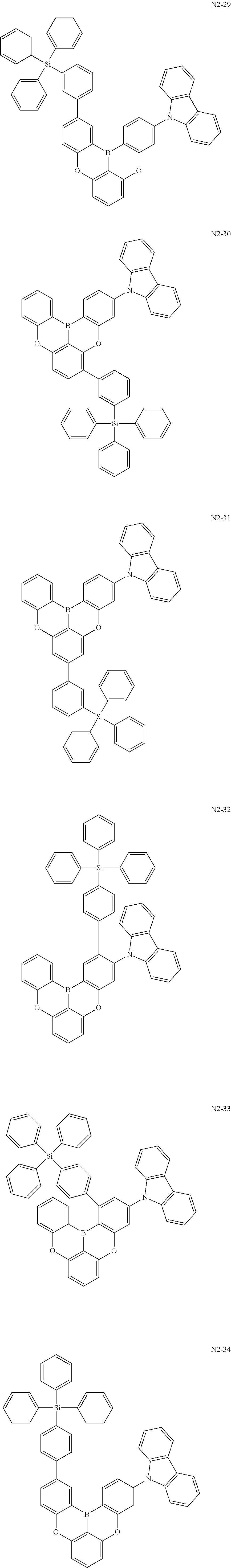

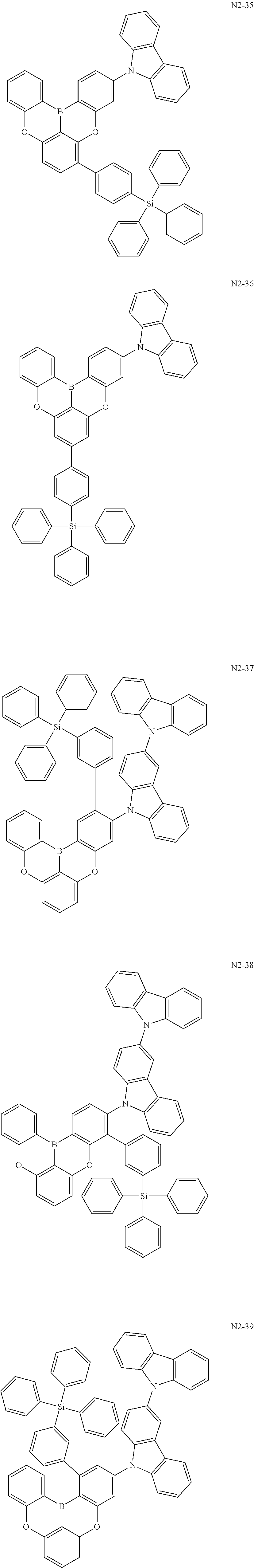

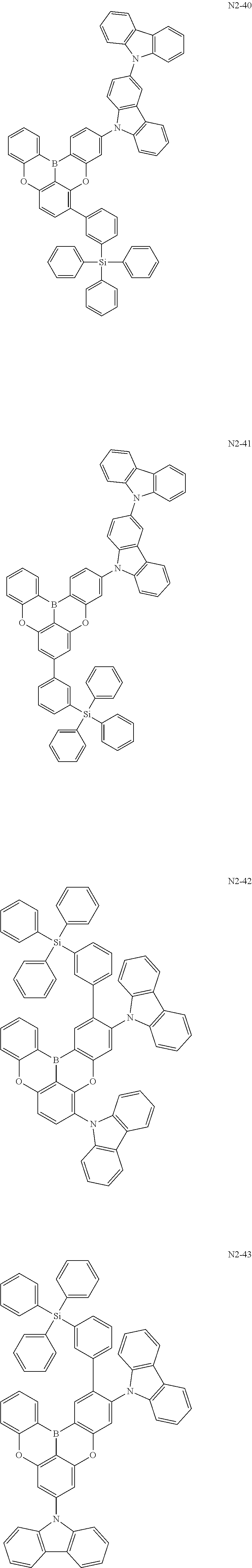 [SMILES: c1ccc([Si](c2ccccc2)(c2ccccc2)c2cccc(-c3ccc4c5c3Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c(cc3-n3c5ccccc5c5ccccc53)Oc3c(-n5c6ccccc6c6ccccc65)ccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1]

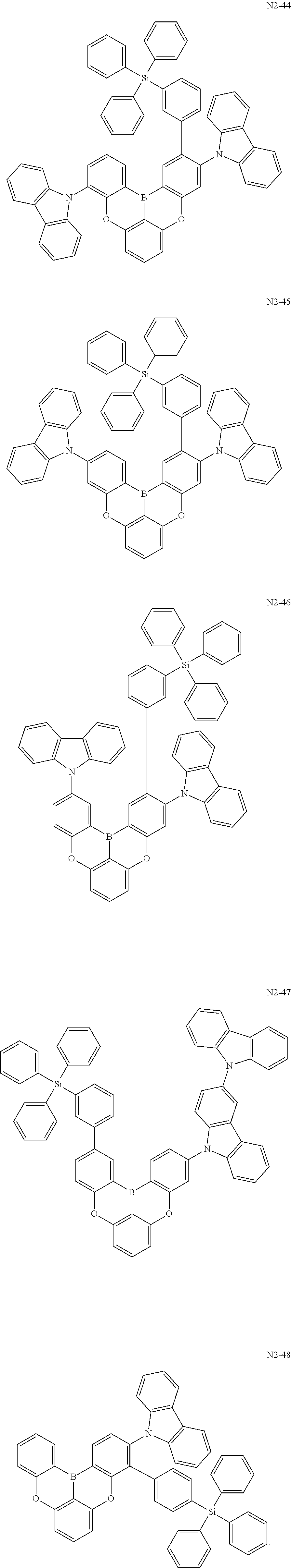

13. The organic light emitting diode of claim 1, wherein the emitter comprises an organometallic compound having the following structure of Chemical Formula 11: 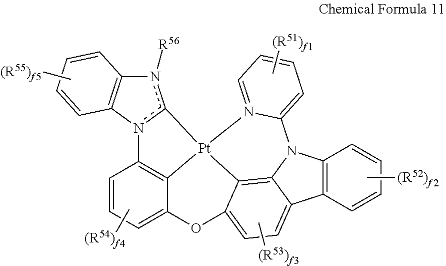
wherein, in Chemical Formula 11,
each of R⁵¹ and R⁵⁶ is independently hydrogen, halogen, a cyan group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an amino group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, an unsubstituted or substituted C₂-C₃₀ hetero aryl silyl group, an unsubstituted or substituted C₁-C₂₀ alkyl germanyl group, an unsubstituted or substituted C₆-C₃₀ aryl germanyl group or an unsubstituted or substituted C₂-C₃₀ hetero aryl germanyl group, an unsubstituted or substituted C₆-C₃₀ tri-aryl methyl group, or an unsubstituted or substituted C₂-C₃₀ tri-hetero aryl methyl group, where each R⁵¹ is identical to or different from each other when f1 is 2, 3 or 4, and each R⁵² is identical to or different from each other when f2 is 2, 3 or 4, each R⁵³ is identical to or different from each other when f3 is 2, each R⁵⁴ is identical to or different from each other when f4 is 2 or 3, and each R⁵⁵ is identical to or different from each other when f5 is 2, 3 or 4;
each of f1, f2 and f5 is independently 0, 1, 2, 3 or 4;
f3 is 0, 1 or 2; and
f4 is 0, 1, 2 or 3.

14. The organic light emitting diode of claim 1, wherein the emitter is at least one of:

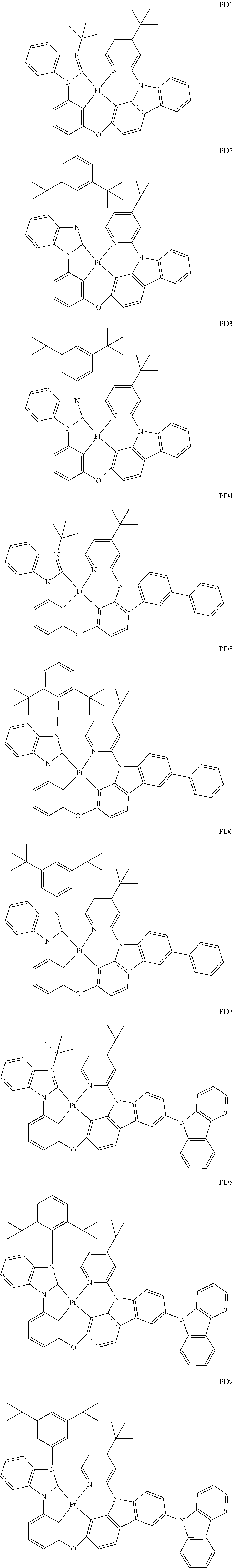

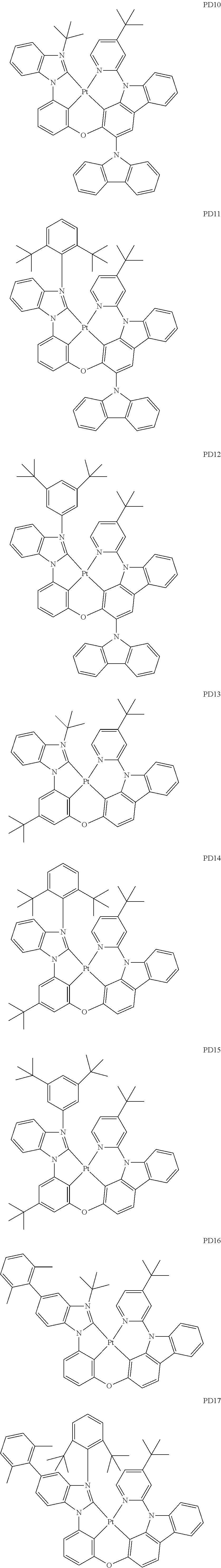

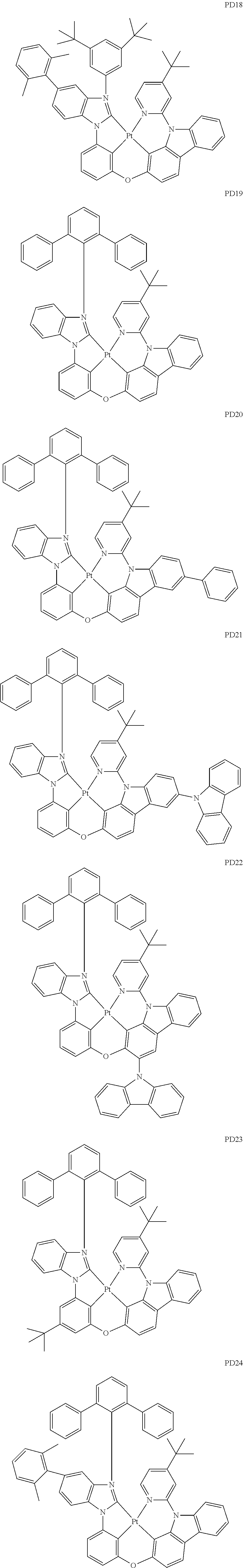

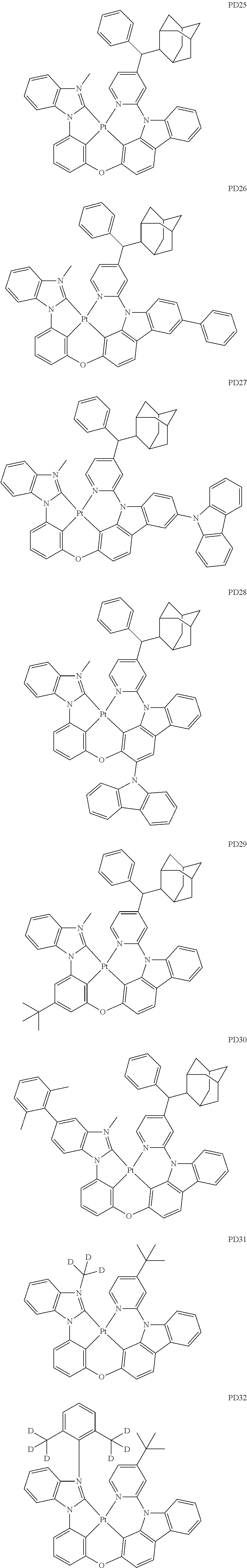

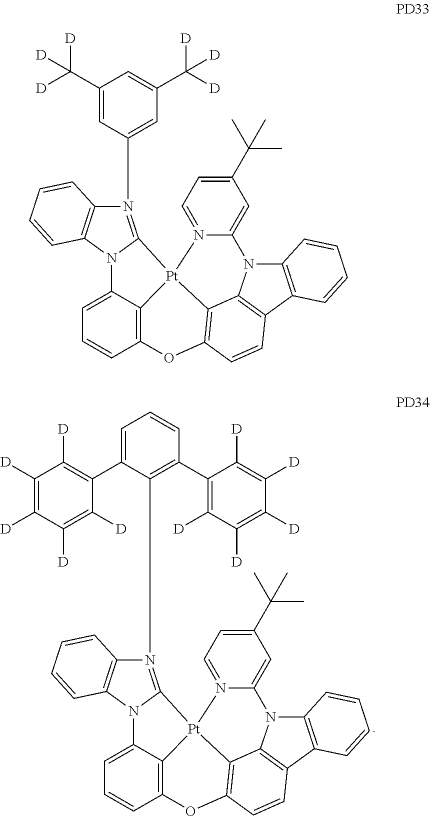

15. The organic light emitting diode of claim 1, wherein the first compound and the second compound in the first exciton generation layer are mixed with a weight ratio between about 4:1 and about 1:4.

16. The organic light emitting diode of claim 1, wherein the emissive layer comprises:
a first emitting part disposed between the first electrode and the second electrode, and comprising a first emitting material layer;
a second emitting part disposed between the first emitting part and the second electrode, and comprising a second emitting material layer; and
a first charge generation layer disposed between the first emitting part and the second emitting part, and
wherein at least one of the first emitting material layer and the second emitting material layer comprises the first host, the second host and the emitter.

17. The organic light emitting diode of claim 16, wherein the first emitting material layer comprises the first host, the second host and the emitter, wherein the first exciton generation layer is disposed between the first electrode and the first emitting material layer or between the first emitting material layer and the first charge generation layer.

18. The organic light emitting diode of claim 17, wherein the first emitting part further comprises a second exciton generation layer disposed oppositely to the first exciton generation layer with respect to the first emitting material layer.

19. The organic light emitting diode of claim 16, wherein the emissive layer further comprises:
a third emitting part disposed between the second emitting part and the second electrode, and comprising a third emitting material layer; and
a second charge generation layer disposed between the second emitting part and the third emitting part.

20. The organic light emitting diode of claim 19, wherein at least one of the first emitting material layer and the third emitting material layer comprises the first host, the second host and the emitter.

21. An organic light emitting device, comprising:
a substrate; and
the organic light emitting diode of claim 1 over the substrate.
